(19) United States
(12) Patent Application Publication
(10) Pub. No.: US 2021/0270769 A1
(43) Pub. Date: Sep. 2, 2021

(54) CHEMICAL SENSOR AND DETECTION APPARATUS

(71) Applicant: ASAHI KASEI MICRODEVICES CORPORATION, Tokyo (JP)

(72) Inventor: Yusuke OKUAKI, Tokyo (JP)

(73) Assignee: ASAHI KASEI MICRODEVICES CORPORATION, Tokyo (JP)

(21) Appl. No.: 17/180,963

(22) Filed: Feb. 22, 2021

(30) Foreign Application Priority Data
Feb. 27, 2020 (JP) 2020-031931
Oct. 16, 2020 (JP) 2020-174590

(51) Int. Cl. G01N 27/414; G01N 27/49

(52) U.S. Cl. CPC G01N 27/4145; G01N 27/49

(57) ABSTRACT

This invention aims at providing a chemical sensor and a detection apparatus each of which can control a threshold voltage and achieve improvement in an electric-charge retention characteristic.

A chemical sensor provides: a sensitive portion having a sensitive membrane sensitive to a chemical substance; a transistor having a floating gate and a gate insulating film; and a first potential controlling portion configured to control a potential of the floating gate in accordance with a voltage applied to the sensitive membrane. The first potential controlling portion has: a P-well region connected to the sensitive portion via a wiring line; a control insulating film formed to make contact with the P-well region; and a control floating portion placed at a position where the control floating portion faces the P-well region across the control insulating film, the control floating portion being conductive with the floating gate. A capacitance of the sensitive membrane is larger than a series combined capacitance of respective capacitances of the gate insulating film and the control insulating film.

### BACKGROUND OF THE INVENTION

### Field of the Invention

The present invention relates to a chemical sensor and a detection apparatus each configured to convert the type of a chemical substance, an ion concentration, and so on into electrical signals.

### Description of the Related Art

An ion sensitive field effect transistor (ISFET) is often used for measurement of ion concentration in solution, measurement of gas concentration, sequence analysis of DNA, and so on.

The ISFET configured to measure an interface potential of a sensitive membrane interface has a problem that a threshold voltage varies when accumulated electric charges are present in a device using the ISFET. Electric charges that cause disturbance in the device are accumulated on floating gates, sensitive membranes, gate oxide films, interfaces of electrodes, and so on. These accumulated electric charges are caused mainly because of a film defect or the like at the time of etching or deposition by plasma during a semiconductor process.

PTL 1 describes that the threshold voltages of the ISFET is offset by about ±10 V due to these accumulated disturbance charges. Large variations in initial offsets of threshold voltages of the ISFET result in measurement errors and an increase in calculation throughput.

Further, the ISFET also has a problem called drift in which its output shifts over time during measurement. Drift is a phenomenon caused such that chemical reactions are caused on an interface of a sensitive membrane provided in the ISFET by application of a voltage to the ISFET, and electric charges are trapped by the interface.

PTL 2 describes a method for controlling a threshold of the ISFET by changing the amount of electric charges in a floating gate provided in the ISFET, in order that such output variations caused in the ISFET are corrected by hardware.

### CITATION LIST

### Patent Literature

PTL 1: JP 2014-115125 A

PTL 2: US 2011/0299337 A1

### SUMMARY OF THE INVENTION

### Problem to be Solved by the Invention

PTL 2 discloses a first structure in which a sensitive portion sensitive to a chemical substance is connected to a floating gate constituted by one layer of polysilicon and configured to accumulate electric charges. The first structure is a structure in which the floating gate configured to accumulate electric charges extends from the polysilicon to a wiring layer, and the volume of an electric-charge storage portion is larger than that before the sensitive portion is connected to the floating gate. Because of this, the first structure has a problem that a parasitic capacitance increases, and leakage current easily occurs. As a result, the first structure has a problem that it is difficult to keep an adjusted threshold voltage for a long time.

Further, in addition to the first structure, PTL 2 discloses a second structure in which an electric-charge accumulation floating gate is divided from a metal plate part by use of a capacitor such as MIM. The sensitive portion as a maximum factor for an increase in volume is removed from the second structure. However, insulating films such as MIM configured to seal electric charges in the floating gate are deposited in a low temperature process, and therefore, leakage current easily occurs in comparison with a thermal oxide film used in a front end of line. On this account, the second structure has a problem that an electric-charge retention characteristic is lower than those of normal memories to which sensitive membranes are not connected.

An object of the present invention is to provide a chemical sensor and a detection apparatus each of which can control a threshold voltage and achieve improvement in an electric-charge retention characteristic.

### Means for Solving the Problem

In order to achieve the above object, a chemical sensor according to one aspect of the present invention provides: a sensitive portion placed on a semiconductor substrate and having a sensitive membrane sensitive to a chemical substance; a transistor having a floating gate and a gate insulating film formed to make contact with the floating gate; and a first potential controlling portion configured to control a potential of the floating gate in accordance with a voltage applied to the sensitive membrane. The first potential controlling portion has: a first impurity diffused region formed in the semiconductor substrate and connected to the sensitive portion via a wiring line; a control insulating film placed on a first surface side of the semiconductor substrate and formed in the semiconductor substrate to make contact with the first impurity diffused region; and a control floating portion placed on the first surface side and placed at a position where the control floating portion faces the first impurity diffused region across the control insulating film, the control floating portion being conductive with the floating gate; and a capacitance of the sensitive membrane is larger than a series combined capacitance of respective capacitances of the gate insulating film and the control insulating film.

Further, in order to achieve the above object, a detection apparatus according to one aspect of the present invention provides: two chemical sensors according to the one aspect of the invention; an electrode structure having a metal electrode made of platinum or gold as a pseudo-reference electrode; and a detecting circuit configured to detect an output difference between the two chemical sensors with respect to the pseudo-reference electrode. The sensitive portion provided in one of the two chemical sensors has a first sensibility, and the sensitive portion provided in the other one of the two chemical sensors has a second sensibility. The sensitive portion provided in the one of the two chemical sensors, the sensitive portion provided in the other of the two chemical sensors, and the pseudo-reference electrode are provided to be immersible in a test sample at the same time.

### Effects of the Invention

With one aspect of the present invention, it is possible to control a threshold voltage and achieve improvement in an electric-charge retention characteristic.

### BRIEF DESCRIPTION OF DRAWINGS

FIG. 1 is a sectional schematic view illustrating a schematic configuration of a chemical sensor according to a first embodiment of the present invention.

FIG. 2 is a view to describe a detection principle to detect an ion concentration of a test sample by use of the chemical sensor according to the first embodiment of the present invention.

FIG. 3 is a view illustrating an equivalent circuit to describe the schematic configuration and an operating state of the chemical sensor according to the first embodiment of the present invention.

FIGS. 4A and 4B is a view to describe the chemical sensor according to the first embodiment of the present invention: FIG. 4A is a view illustrating a state where electric charges are injected into a floating portion provided in the chemical sensor; and FIG. 4B is a view illustrating another state where electric charges are injected into the floating portion included in the chemical sensor.

FIGS. 5A and 5B is a view to describe the chemical sensor according to the first embodiment of the present invention: FIG. 5A is a view illustrating a state where electric charges are discharged from the floating portion provided in the chemical sensor; and FIG. 5B is a view illustrating another state where electric charges are discharged from the floating portion provided in the chemical sensor.

FIG. 6 is a view to describe effects of the chemical sensor according to the first embodiment of the present invention and illustrates measurement results before and after adjustment of threshold voltages of transistors provided in samples of the chemical sensor.

FIG. 7 is a sectional schematic view illustrating a schematic configuration of a chemical sensor according to Modification 1 of the first embodiment of the present invention.

FIG. 8 is a sectional schematic view illustrating a schematic configuration of a chemical sensor according to Modification 2 of the first embodiment of the present invention.

FIG. 9 is a sectional schematic view illustrating a schematic configuration of a chemical sensor according to a second embodiment of the present invention.

FIG. 10 is a view illustrating an equivalent circuit to describe the schematic configuration and an operating state of the chemical sensor according to the second embodiment of the present invention.

FIG. 11 is a view illustrating an equivalent circuit in a state where electric charges are injected into a floating portion provided in the chemical sensor according to the second embodiment of the present invention.

FIG. 12 is a view illustrating an equivalent circuit in a state where electric charges are discharged from the floating portion provided in the chemical sensor according to the second embodiment of the present invention.

FIG. 13 is a sectional schematic view illustrating a schematic configuration of a chemical sensor according to a modification of the second embodiment of the present invention.

FIG. 14 is a sectional schematic view illustrating a schematic configuration of a chemical sensor according to a third embodiment of the present invention.

FIG. 15 is a view illustrating an equivalent circuit to describe the schematic configuration and an operating state of the chemical sensor according to the third embodiment of the present invention.

FIG. 16 is a view illustrating an equivalent circuit in a state where electric charges are injected into a floating portion provided in the chemical sensor according to the third embodiment of the present invention.

FIG. 17 is a view illustrating an equivalent circuit in a state where electric charges are discharged from the floating portion provided in the chemical sensor according to the third embodiment of the present invention.

FIG. 18 is a sectional schematic view illustrating a schematic configuration of a chemical sensor according to Modification 1 of the third embodiment of the present invention.

FIG. 19 is a sectional schematic view illustrating a schematic configuration of a chemical sensor according to Modification 2 of the third embodiment of the present invention.

FIG. 20 is a sectional schematic view illustrating a schematic configuration of a chemical sensor according to a fourth embodiment of the present invention.

FIG. 21 is a view illustrating an equivalent circuit to describe the schematic configuration and an operating state of the chemical sensor according to the fourth embodiment of the present invention.

FIG. 22 is a view illustrating an equivalent circuit in a state where electric charges are injected into a floating portion provided in the chemical sensor according to the fourth embodiment of the present invention.

FIG. 23 is a view illustrating an equivalent circuit in a state where electric charges are discharged from the floating portion provided in the chemical sensor according to the fourth embodiment of the present invention.

FIG. 24 is a sectional schematic view illustrating a schematic configuration of a chemical sensor according to a fifth embodiment of the present invention.

FIG. 25 is a view illustrating an equivalent circuit to describe the schematic configuration and an operating state of the chemical sensor according to the fifth embodiment of the present invention.

FIG. 26 is a view illustrating an equivalent circuit in a state where electric charges are injected into a floating portion provided in the chemical sensor according to the fifth embodiment of the present invention.

FIG. 27 is a view illustrating an equivalent circuit in a state where electric charges are discharged from the floating portion provided in the chemical sensor according to the fifth embodiment of the present invention.

FIG. 28 is a view illustrating an equivalent circuit to describe a schematic configuration and an operating state of a detection apparatus according to a sixth embodiment of the present invention.

FIG. 29 is a flowchart illustrating one example of an operation of the detection apparatus according to the sixth embodiment of the present invention.

### DESCRIPTION OF THE PREFERRED EMBODIMENTS

### First Embodiment

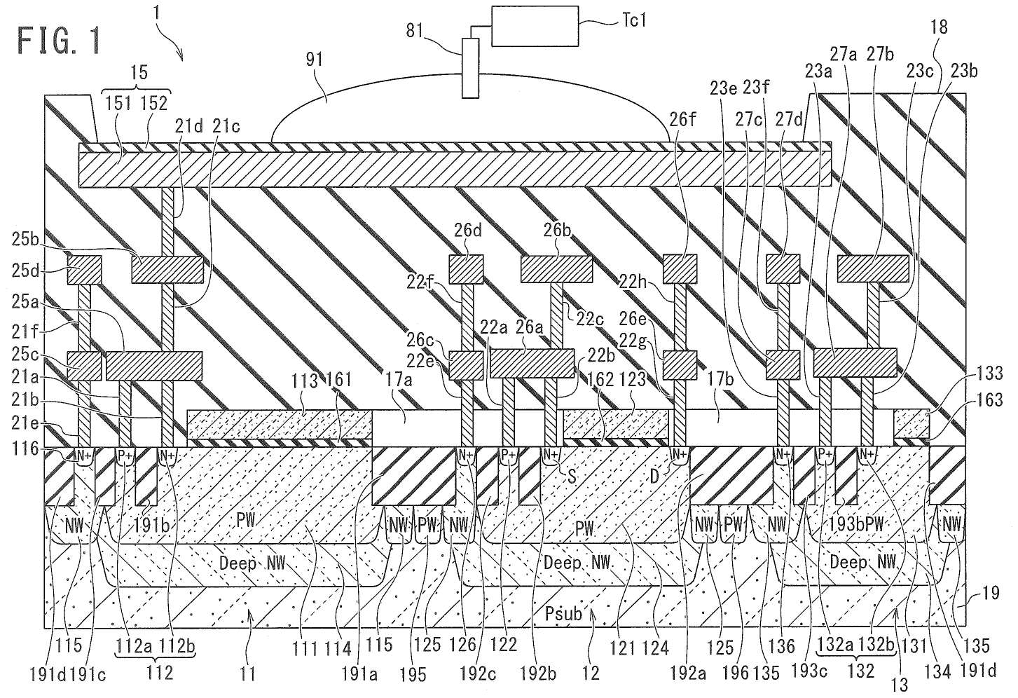

The following describes a chemical sensor according to a first embodiment of the present invention with reference to FIGS. 1 to 6. First described is a schematic configuration of a chemical sensor 1 according to the present embodiment with reference to FIG. 1.

<Configuration of Chemical Sensor>

As illustrated in FIG. 1, the chemical sensor 1 according to the present embodiment provides a semiconductor substrate 19 constituted by a P-type silicone substrate, for example, and a sensitive portion 15 placed on the semiconductor substrate 19 and having a sensitive membrane 152 sensitive to a chemical substance. Further, the chemical sensor 1 provides a transistor 12 having a floating gate 123 and a gate insulating film 162 formed to make contact with the floating gate 123. The floating gate 123 is placed on a first surface side of the semiconductor substrate 19 in an electrically floating state. The first surface side of the semiconductor substrate 19 is a side of a surface (an element forming surface) where an element is formed by laminating a predetermined insulating film, metal film, and so on and injecting impurities to form the transistor 12 and so on. In the present embodiment, the sensitive portion 15 is placed on the same surface side as the surface side where the floating gate 123 is formed. The transistor 12 functions as an ISFET in the chemical sensor 1. Further, the chemical sensor 1 provides a first potential controlling portion 11 configured to control a potential of the floating gate 123 in accordance with a voltage applied to the sensitive membrane 152. The first potential controlling portion 11 has at least part formed in the semiconductor substrate 19 and is connected to the sensitive portion 15. Further, the chemical sensor 1 provides a first electric-charge flow portion 13 through which electric charges are flowable to and from the floating gate 123 in accordance with an applied voltage. The first electric-charge flow portion 13 has part formed in the semiconductor substrate 19.

As illustrated in FIG. 1, the first potential controlling portion 11 has a P-well region 111 (one example of a first impurity diffused region) formed in the semiconductor substrate 19 and connected to the sensitive portion 15 via a wiring line. The P-well region 111 has a P-type (one example of a first conductivity type), for example. Although details will be described later, the wiring line via which connects the P-well region 111 and the sensitive portion 15 has a plug 21a, a plug 21b, an intermediate wiring line 25a, a plug 21c, an intermediate wiring line 25b, and a plug 21d. The first potential controlling portion 11 has a highly-concentrated impurity diffused region 112 containing impurities at a concentration higher than that in the P-well region 111 and formed in the P-well region 111. The P-well region 111 and the highly-concentrated impurity diffused region 112 are formed in an upper part of the semiconductor substrate 19, for example. Further, the p-well region 111 and the highly-concentrated impurity diffused region 112 are formed in a surface layer of the semiconductor substrate 19, for example. The p-well region 111 and the highly-concentrated impurity diffused region 112 correspond to the part formed in the semiconductor substrate. Note that “PW” illustrated in FIG. 1 indicates a P-well region. The P-well region 111 is electrically connected to the sensitive membrane 152 of the sensitive portion 15 via the highly-concentrated impurity diffused region 112 and the wiring line having the plug 21a and so on.

In the section illustrated in FIG. 1, the highly-concentrated impurity diffused region 112 is placed in the P-well region 111 to be closer to an end part side of the chemical sensor 1 than to a central part side of the chemical sensor 1. The highly-concentrated impurity diffused region 112 has a P+ region 112a and an N+ region 112b. An element isolation layer 191b formed in the P-well region 111 is placed between the P+ region 112a and the N+ region 112b. Hereby, the P+ region 112a and the N+ region 112b do not make direct contact with each other. The P+ region 112a is placed closer to the end part side of the chemical sensor 1 than the N+ region 112b.

The first potential controlling portion 11 has an N-well region 115 formed in the semiconductor substrate 19. The N-well region 115 is formed around the P-well region 111 in a state where part of the N-well region 115 makes contact with the P-well region 111. The N-well region 115 is formed to have generally the same depth as the P-well region 111. The first potential controlling portion 11 has an N+ region 116 formed in the N-well region 115. The N+ region 116 is formed in the N-well region 115 on the end part side of the chemical sensor 1. An element isolation layer 191c is formed between the N-well region 115 and the P-well region 111. The element isolation layer 191c is also placed between the N+ region 116 and the P+ region 112a. Hereby, the N+ region 116 and the P+ region 112a do not make direct contact with each other. Note that “NW” illustrated in FIG. 1 indicates an N-well region.

As illustrated in FIG. 1, the chemical sensor 1 provides a deep N-well region 114 (one example of a fifth impurity diffused region) formed in the semiconductor substrate 19 to surround the P-well region 111 at a position deeper than the P-well region 111 and having an N-type (one example of a second conductivity type). The deep N-well region 114 is formed to cover the lower side of the P-well region 111. Since the deep N-well region 114 is formed to surround the P-well region 111 as such, the chemical sensor 1 can prevent leakage current from flowing into the semiconductor substrate 19 in response to a voltage being applied to the P-well region 111.

The first potential controlling portion 11 has a control insulating film 161 placed on the first surface side of the semiconductor substrate 19 and formed in the semiconductor substrate 19 to make contact with the P-well region 111. The first potential controlling portion 11 has a control floating portion 113 placed on the first surface side and placed at a position where the control floating portion 113 faces the P-well region 111 across the control insulating film 161. The control floating portion 113 is conductive with the floating gate 123. The control floating portion 113 is insulated from the P-well region 111 and is placed to be connected to the floating gate 123 in an electrically floating state. The control floating portion 113 is formed on the control insulating film 161. That is, the control floating portion 113 is formed to make contact with the control insulating film 161. The control floating portion 113 is insulated from the P-well region 111 by the control insulating film 161. The control floating portion 113 has a single layer (that is, one layer) structure, for example. The control floating portion 113 is made of polysilicon, for example.

The control insulating film 161 is a thermal oxide film, for example. The control insulating film 161 is formed by thermally oxidizing a surface of the semiconductor substrate 19 at high temperature. The control insulating film 161 and an after-mentioned gate insulating film 162 and first insulating film 163 are formed at the same time in the same heat treatment step, for example. The control insulating film 161 is made of a silicon oxide film (SiO₂), a silicon oxynitride film (SiON), or the like, for example. Since the control insulating film 161 is made of a thermal oxide film by high-temperature treatment, it is possible to prevent the occurrence of leakage current in the first potential controlling portion 11.

Since the control insulating film 161 is formed in the same heat treatment step as the first insulating film 163, for example, the control insulating film 161 has a film thickness in the same film thickness range (e.g., not less than 6 nm but less than 15 nm) as the first insulating film 163. Electric charges do not pass through the control insulating film 161 differently from the first insulating film 163 described below, and therefore, the control insulating film 161 may have a film thickness thicker than the first insulating film 163.

As illustrated in FIG. 1, the floating gate 123 provided in the transistor 12 has a single layer (that is, one layer) structure, for example. The floating gate 123 is made of polysilicon, for example.

The transistor 12 has a P-well region 121 (one example of a fourth impurity diffused region) formed in the semiconductor substrate 19 and having the P-type. The P-well region 121 has the same impurity concentration as the P-well region 111, for example. The transistor 12 has the gate insulating film 162 placed to be sandwiched between the P-well region 121 and the floating gate 123 and formed to make contact with the P-well region 121 and the floating gate 123. The gate insulating film 162 is formed right under the floating gate 123. The P-well region 121 is formed to include a region right under the gate insulating film 162.

The gate insulating film 162 is a thermal oxide film, for example. The gate insulating film 162 is formed by thermally oxidizing the surface of the semiconductor substrate 19 at high temperature. The gate insulating film 162 is made of a silicon oxide film (SiO₂), a silicon oxynitride film (SiON), or the like, for example. As described above, since the gate insulating film 162 is made of a thermal oxide film by high-temperature treatment, it is possible to prevent the occurrence of leakage current in the transistor 12.

Since the gate insulating film 162 is formed in the same heat treatment step as the first insulating film 163, for example, the gate insulating film 162 has a film thickness in the same film thickness range (e.g., not less than 6 nm but less than 15 nm) as the first insulating film 163. Electric charges do not pass through the gate insulating film 162 differently from the first insulating film 163 described below, and therefore, the gate insulating film 162 may have a film thickness thicker than the first insulating film 163.

The transistor 12 has a source S formed in the P-well region 121 on either one of the opposite sides of the floating gate 123 and having the N-type, and a drain D formed in the P-well region 121 on the other one of the opposite sides of the floating gate 123 and having the N-type. The source S and the drain D are constituted by a highly-concentrated impurity diffused region having an impurity concentration higher than that of the P-well region 121.

The transistor 12 has a P+ region 122 (one example of a highly-concentrated impurity diffused region) having the P-type and containing impurities at a concentration higher than that in the P-well region 121. The P+ region 122 is formed in the P-well region 121, and a voltage is applicable to the P+ region 122. An element isolation layer 192b is formed between the P+ region 122 and the source S. The element isolation layer 192b is formed in the P-well region 121. Hereby, the P+ region 122 and the source S do not make direct contact with each other.

The transistor 12 has an N-well region 125 formed in the semiconductor substrate 19. The N-well region 125 is formed around the P-well region 121 in a state where the N-well region 125 partially makes contact with the P-well region 121. The N-well region 125 is formed to have generally the same depth as the P-well region 121. The transistor 12 has an N+ region 126 formed in the N-well region 125. An element isolation layer 192c is formed between the N-well region 125 and the P+ region 122. The element isolation layer 192c is formed in the P-well region 121. The element isolation layer 192c is also placed between the N+ region 126 and the P+ region 122. Hereby, the N+ region 126 and the P+ region 122 do not make direct contact with each other.

The chemical sensor 1 provides a deep N-well region 124 having the N-type and formed in the semiconductor substrate 19 to surround the P-well region 121 at a position deeper than the P-well region 121. The deep N-well region 124 is formed to cover the lower side of the P-well region 121. Since the deep N-well region 124 is formed to surround the P-well region 121 as such, the chemical sensor 1 can prevent leakage current from flowing into the semiconductor substrate 19 in response to a voltage being applied to the P-well region 121.

As illustrated in FIG. 1, the chemical sensor 1 provides the first electric-charge flow portion 13 through which electric charges are flowable to and from the floating gate 123 in accordance with an applied voltage. The first electric-charge flow portion 13 has at least part formed in the semiconductor substrate 19. Although details are described later, the chemical sensor 1 is configured such that electrons as electric charges are injected into the floating gate 123 or electrons are discharged from the floating gate 123 via the first electric-charge flow portion 13. Hereby, the chemical sensor 1 can adjust a threshold voltage of the transistor 12.

The first electric-charge flow portion 13 has a P-well region 131 (one example of a second impurity diffused region) formed in the semiconductor substrate 19 and having the P-type, and a highly-concentrated impurity diffused region 132 formed in the P-well region 131 and containing impurities at a concentration higher than that in the P-well region 131 and to which a voltage is applied. The P-well region 131 and the highly-concentrated impurity diffused region 132 are formed in the upper part of the semiconductor substrate 19, for example. Further, the P-well region 131 and the highly-concentrated impurity diffused region 132 are formed in the surface layer of the semiconductor substrate 19, for example. The p-well region 131 and the highly-concentrated impurity diffused region 132 correspond to the part formed in the semiconductor substrate.

In the section illustrated in FIG. 1, the highly-concentrated impurity diffused region 132 is placed on a side closer to the central part side of the chemical sensor 1 from a central part of the P-well region 131. The highly-concentrated impurity diffused region 132 has a P+ region 132a and an N+ region 132b. An element isolation layer 193b formed in the P-well region 131 is placed between the P+ region 132a and the N+ region 132b. Hereby, the P+ region 132a and the N+ region 132b do not make direct contact with each other. The P+ region 132a is placed closer to the central part side of the chemical sensor 1 than the N+ region 132b.

The first electric-charge flow portion 13 has an N-well region 135 formed in the semiconductor substrate 19 and having the N-type. The N-well region 135 is formed around the P-well region 131 in a state where the N-well region 135 partially makes contact with the P-well region 131. The N-well region 135 is formed to have generally the same depth as the P-well region 131. The first electric-charge flow portion 13 has an N+ region 136 formed in the N-well region 135. In the section illustrated in FIG. 1, the N+ region 136 is formed in the N-well region 135 on the central part side of the chemical sensor 1. An element isolation layer 193c is formed between the N-well region 135 and the P-well region 131. The element isolation layer 193c is also placed between the N+ region 136 and the P+ region 132a. Hereby, the N+ region 136 and the P+ region 132a do not make direct contact with each other.

As illustrated in FIG. 1, the chemical sensor 1 provides a deep N-well region 134 (one example of the fifth impurity diffused region) having the N-type and formed in the semiconductor substrate 19 to surround the P-well region 131 at a position deeper than the P-well region 131. The deep N-well region 134 is formed to cover the lower side of the P-well region 131. Since the deep N-well region 134 is formed to surround the P-well region 131 as such, the chemical sensor 1 can prevent leakage current from flowing into the semiconductor substrate 19 in response to a voltage being applied to the P-well region 131.

The first electric-charge flow portion 13 has a first insulating film 163 formed to make contact with the P-well region 131, and a first floating portion 133 making contact with the first insulating film 163 and formed on the first surface side of the semiconductor substrate 19 in an electrically floating state. The first floating portion 133 is connected to the floating gate 123. The first floating portion 133 is formed on the first insulating film 163. The first floating portion 133 is insulated from the P-well region 131 by the first insulating film 163. The first floating portion 133 has a single layer (that is, one layer) structure, for example. The first floating portion 133 is made of polysilicon, for example.

The first insulating film 163 at least partially has a region with a film thickness of not less than 6 nm but less than 15 nm, for example. In the present embodiment, the first insulating film 163 has the region with a film thickness of not less than 6 nm but less than 15 nm as a whole. The first insulating film 163 may have a film thickness within a range of not less than 6 nm but less than 15 nm as a whole, and an irregular shape may be formed on a surface of the first insulating film 163. Alternatively, the first insulating film 163 may have a uniform film thickness (e.g., a uniform thickness of 6 nm) within a range of not less than 6 nm but less than 15 nm, for example, and the surface of the first insulating film 163 may have a flat shape. When the first insulating film 163 has a film thickness thinner than 6 nm, direct tunneling easily occurs in the first insulating film 163, and the electric-charge retention characteristic (retention characteristic) of the first floating portion 133 worsens. In the meantime, when the first insulating film 163 has a film thickness thicker than 15 nm, injection of electric charges into the first floating portion 133 and discharge of electric charges from the first floating portion 133 become slow. In view of this, when the first insulating film 163 at least partially has the region with a film thickness of not less than 6 nm but less than 15 nm, the chemical sensor 1 can achieve improvement in the electric-charge retention characteristic and improvement in injection speed and discharge speed of electric charges between the first floating portion 133 and the P-well region 131.

The first insulating film 163 is a thermal oxide film, for example. The first insulating film 163 is formed by thermally oxidizing the surface of the semiconductor substrate 19 at high temperature. The control insulating film 161, the gate insulating film 162, and the first insulating film 163 are formed at the same time in the same heat treatment step, for example. The first insulating film 163 is made of a silicon oxide film (SiO₂), a silicon oxynitride film (SiON), or the like, for example. Since the first insulating film 163 is made of a thermal oxide film by high-temperature treatment, it is possible to prevent the occurrence of leakage current in the first electric-charge flow portion 13.

The chemical sensor 1 provides a first connecting portion 17a via which the floating gate 123 is connected to the control floating portion 113, and a second connecting portion 17b via which the floating gate 123 is connected to the first floating portion 133. The first connecting portion 17a and the second connecting portion 17b each have a single layer (that is, one layer) structure, for example. The first connecting portion 17a and the second connecting portion 17b are each made of polysilicon, for example. The first connecting portion 17a is formed on the element isolation layers 191a, 192b, 192c and other element isolation layers (not illustrated). The second connecting portion 17b is formed on the element isolation layers 192a, 193b, 193c and other element isolation layers (not illustrated).

The control floating portion 113, the first connecting portion 17a, and the floating gate 123 are formed integrally. Further, the floating gate 123, the second connecting portion 17b, and the first floating portion 133 are formed integrally. Accordingly, the floating gate 123, the control floating portion 113, and the first floating portion 133 are formed integrally. An overall shape of a combination of the control floating portion 113, the first connecting portion 17a, the floating gate 123, the second connecting portion 17b, and the first floating portion 133 has an E-shape, for example, when viewed in a direction perpendicular to the surface of the semiconductor substrate 19 on which the gate insulating film 162 and so on are laminated. The overall shape of the combination of the control floating portion 113, the first connecting portion 17a, the floating gate 123, the second connecting portion 17b, and the first floating portion 133 is not limited to the E-shape and may be other shapes.

As such, the first potential controlling portion 11, the transistor 12, and the first electric-charge flow portion 13 are electrically connected to each other via the floating gate 123, the control floating portion 113, and the first floating portion 133, in the upper part of the semiconductor substrate 19. In the meantime, the first potential controlling portion 11, the transistor 12, and the first electric-charge flow portion 13 are electrically isolated from each other in the semiconductor substrate 19 by the element isolation layer 191a and the element isolation layer 192a. More specifically, the element isolation layer 191a is formed in the semiconductor substrate 19 between the P-well region 111 provided in the first potential controlling portion 11 and the N-well region 125 provided in the transistor 12. Hereby, the element isolation layer 191a electrically isolates the first potential controlling portion 11 from the transistor 12 in the semiconductor substrate 19. The element isolation layer 192a is formed in the semiconductor substrate 19 between the P-well region 121 provided in the transistor 12 and the N-well region 135 provided in the first electric-charge flow portion 13. Hereby, the element isolation layer 192a electrically isolates the transistor 12 from the first electric-charge flow portion 13 in the semiconductor substrate 19.

Further, the chemical sensor 1 has a P-well region 195 formed in the semiconductor substrate 19 between the N-well region 115 and the N-well region 125. Hereby, the N-well region 115 and the N-well region 125 do not make direct contact with each other. As a result, even when different voltages are applied to the N-well region 115 and the N-well region 125, respective potentials of the N-well region 115 and the N-well region 125 do not interfere with each other.

Further, the chemical sensor 1 has a P-well region 196 formed in the semiconductor substrate 19 between the N-well region 125 and the N-well region 135. Hereby, the N-well region 125 and the N-well region 135 do not make direct contact with each other. As a result, even when different voltages are applied to the N-well region 125 and the N-well region 135, respective potentials of the N-well region 125 and the N-well region 135 do not interfere with each other.

Further, the chemical sensor 1 provides an element isolation layer 191d formed in a peripheral edge of the chemical sensor 1. The element isolation layer 191d is formed in the semiconductor substrate 19. the element isolation layer 191d is provided such that, when a plurality of chemical sensors 1 is formed in an array form, the element isolation layer 191d electrically isolates adjacent chemical sensors 1 from each other.

As illustrated in FIG. 1, the chemical sensor 1 provides an interlayer insulating film 18 formed on the semiconductor substrate 19. The interlayer insulating film 18 is formed at least in a region where the control floating portion 113, the first connecting portion 17a, the floating gate 123, the second connecting portion 17b, the first floating portion 133, the source S, the drain D, the highly-concentrated impurity diffused regions 112, 132, the N+ regions 116, 126, 136, and the element isolation layers 191a, 191b, 191c, 192a, 192b, 192c, 193b, 193c, 191d are provided. The interlayer insulating film 18 has a function as a protective film that protects the control floating portion 113, the first connecting portion 17a, the floating gate 123, the second connecting portion 17b, the first floating portion 133, the source S, the drain D, the highly-concentrated impurity diffused regions 112, 132, the N+ regions 116, 126, 136, and so on.

As illustrated in FIG. 1, the chemical sensor 1 provides the plugs 21a, 21b embedded in openings that are formed in the interlayer insulating film 18 and that expose part of the highly-concentrated impurity diffused region 112 to respective bottom faces of the openings, and the intermediate wiring line 25a electrically connected to the plugs 21a, 21b and formed in the interlayer insulating film 18. A first end of the plug 21a is formed to make contact with the P+ region 112a of the highly-concentrated impurity diffused region 112. A first end of the plug 21b is formed to make contact with the N+ region 112b of the highly-concentrated impurity diffused region 112. Silicides are formed on respective surfaces of the P+ region 112a and the N+ region 112b, for example. The plug 21a is formed on the silicide formed on the surface of the P+ region 112a. This is to reduce contact resistance between the plug 21a and the P+ region 112a. The plug 21b is formed on the silicide formed on the surface of the N+ region 112b. This is to reduce contact resistance between the plug 21b and the N+ region 112b. The intermediate wiring line 25a is formed to make contact with a second end of the plug 21a and a second end of the plug 21b. Hereby, the plug 21a and the plug 21b are connected to each other via the intermediate wiring line 25a.

The chemical sensor 1 provides the plug 21c embedded in an opening that is formed in the interlayer insulating film 18 and that exposes part of the intermediate wiring line 25a to a bottom face of the opening, and the intermediate wiring line 25b electrically connected to the plug 21c and formed in the interlayer insulating film 18. A first end of the plug 21c is formed to make contact with the intermediate wiring line 25a. The intermediate wiring line 25b is formed to make contact with a second end of the plug 21c.

The chemical sensor 1 provides the plug 21d embedded in an opening that is formed in the interlayer insulating film 18 and that exposes part of the intermediate wiring line 25b to a bottom face of the opening. A first end of the plug 21d is formed to make contact with the intermediate wiring line 25b. A second end of the plug 21d is connected to the sensitive portion 15.

The chemical sensor 1 provides a plug 21e embedded in an opening that is formed in the interlayer insulating film 18 and that exposes part of the N+ region 116 to a bottom face of the opening, and an intermediate wiring line 25c electrically connected to the plug 21e and formed in the interlayer insulating film 18. A first end of the plug 21e is formed to make contact with the N+ region 116. A silicide is formed on a surface of the N+ region 116, for example. The plug 21e is formed on the silicide formed on the surface of the N+ region 116. This is to reduce contact resistance between the plug 21e and the N+ region 116. The intermediate wiring line 25c is formed to make contact with a second end of the plug 21e.

The chemical sensor 1 provides a plug 21f embedded in an opening that is formed in the interlayer insulating film 18 and that exposes part of the intermediate wiring line 25c on a bottom face of the opening, and an intermediate wiring line 25d electrically connected to the plug 21f and formed in the interlayer insulating film 18. A first end of the plug 21f is formed to make contact with the intermediate wiring line 25c.

The intermediate wiring line 25d is formed to make contact with a second end of the plug 21f. The intermediate wiring line 25d is connected to an external terminal Tb1 (not illustrated in FIG. 1) via plugs (not illustrated) or intermediate wiring lines (not illustrated). Hereby, a voltage can be applied to the N+ region 116 via the external terminal Tb1, the intermediate wiring line 25d, the plug 21f, and so on.

As illustrated in FIG. 1, the chemical sensor 1 provides a plug 22a embedded in an opening that is formed in the interlayer insulating film 18 and exposes part of the P+ region 122 on a bottom face of the opening. A first end of the plug 22a is formed to make contact with the P+ region 122. A silicide is formed on a surface of the P+ region 122, for example. The plug 22a is formed on the silicide formed on the surface of the P+ region 122. This is to reduce contact resistance between the plug 22a and the P+ region 122.

The chemical sensor 1 provides a plug 22b embedded in an opening that is formed in the interlayer insulating film 18 and that exposes part of the source S to a bottom face of the opening. A first end of the plug 22b is formed to make contact with the source S. A silicide is formed on a surface of the source S, for example. The plug 22b is formed on the silicide formed on the surface of the source S. This is to reduce contact resistance between the plug 22b and the source S.

The chemical sensor 1 provides an intermediate wiring line 26a electrically connected to the plugs 22a, 22b and formed in the interlayer insulating film 18. The intermediate wiring line 26a is formed to make contact with a second end of the plug 22a and a second end of the plug 22b. Hereby, the plug 22a and the plug 22b are connected to each other via the intermediate wiring line 26a.

The chemical sensor 1 provides a plug 22c embedded in an opening that is formed in the interlayer insulating film 18 and that exposes part of the intermediate wiring line 26a to a bottom face of the opening, and an intermediate wiring line 26b electrically connected to the plug 22c and formed in the interlayer insulating film 18. A first end of the plug 22c is formed to make contact with the intermediate wiring line 26a. The intermediate wiring line 26b is formed to make contact with a second end of the plug 22c. The intermediate wiring line 26b is connected to an external terminal Ts (not illustrated in FIG. 1) via plugs (not illustrated) or intermediate wiring lines (not illustrated). Hereby, a voltage can be applied to the source S and the P+ region 122 via the external terminal Ts, the intermediate wiring line 26b, the plug 22c, the intermediate wiring line 26a, the plugs 22a, 22b, and so on.

The chemical sensor 1 provides a plug 22g embedded in an opening that is formed in the interlayer insulating film 18 and that exposes part of the drain D to a bottom face of the opening, and an intermediate wiring line 26e electrically connected to the plug 22g and formed in the interlayer insulating film 18. A first end of the plug 22g is formed to make contact with the drain D. A silicide is formed on a surface of the drain D, for example. The plug 22g is formed on the silicide formed on the surface of the drain D. This is to reduce contact resistance between the plug 22g and the drain D. The intermediate wiring line 26e is formed to make contact with a second end of the plug 22g.

The chemical sensor 1 provides a plug 22h embedded in an opening that is formed in the interlayer insulating film 18 and that exposes part of the intermediate wiring line 26e to a bottom face of the opening, and an intermediate wiring line 26f electrically connected to the plug 22h and formed in the interlayer insulating film 18. A first end of the plug 22h is formed to make contact with the intermediate wiring line 26e.

The intermediate wiring line 26f is formed to make contact with a second end of the plug 22h. The intermediate wiring line 26f is connected to an external terminal Td (not illustrated in FIG. 1) via plugs (not illustrated) or intermediate wiring lines (not illustrated). Hereby, a voltage can be applied to the drain D via the external terminal Td, the intermediate wiring line 26c, the plug 22e, and so on. Further, currents flowing through the external terminal Td and the external terminal Ts can be detected.

The chemical sensor 1 provides a plug 22e embedded in an opening that is formed in the interlayer insulating film 18 that exposes part of the N+ region 126 on a bottom face of the opening, and an intermediate wiring line 26c electrically connected to the plug 22e and formed in the interlayer insulating film 18. A first end of the plug 22e is formed to make contact with the N+ region 126. A silicide is formed on a surface of the N+ region 126, for example. The plug 22e is formed on the silicide formed on the surface of the N+ region 126. This is to reduce contact resistance between the plug 22e and the N+ region 126. The intermediate wiring line 26c is formed to make contact with a second end of the plug 22e.

The chemical sensor 1 provides a plug 22f embedded in an opening that is formed in the interlayer insulating film 18 and that exposes part of the intermediate wiring line 26c to a bottom face of the opening, and an intermediate wiring line 26d electrically connected to the plug 22f and formed in the interlayer insulating film 18. A first end of the plug 22f is formed to make contact with the intermediate wiring line 26c.

The intermediate wiring line 26d is formed to make contact with a second end of the plug 22f. The intermediate wiring line 26d is connected to an external terminal Tb2 (not illustrated in FIG. 1) via plugs (not illustrated) or intermediate wiring lines (not illustrated). Hereby, a voltage can be applied to the N+ region 126 via the external terminal Tb2, the intermediate wiring line 26d, the plug 22f, and so on.

As illustrated in FIG. 1, the chemical sensor 1 provides plugs 23a, 23b embedded in openings that are formed in the interlayer insulating film 18 and that expose part of the highly-concentrated impurity diffused region 132 to respective bottom faces of the openings, and an intermediate wiring line 27a electrically connected to the plugs 23a, 23b and formed in the interlayer insulating film 18. A first end of the plug 23a is formed to make contact with the P+ region 132a of the highly-concentrated impurity diffused region 132. A first end of the plug 23b is formed to make contact with the N+ region 132b of the highly-concentrated impurity diffused region 132. Silicides are formed on respective surfaces of the P+ region 132a and the N+ region 132b, for example. The plug 23a is formed on the silicide formed on the surface of the P+ region 132a. This is to reduce contact resistance between the plug 23a and the P+ region 132a. The plug 23b is formed on the silicide formed on the surface of the N+ region 132b. This is to reduce contact resistance between the plug 23b and the N+ region 132b. The intermediate wiring line 27a is formed to make contact with a second end of the plug 23a and a second end of the plug 23b. Hereby, the plug 23a and the plug 23b are connected to each other via the intermediate wiring line 27a.

The chemical sensor 1 provides a plug 23c embedded in an opening that is formed in the interlayer insulating film 18 that is exposes part of the intermediate wiring line 27a to a bottom face of the opening, and an intermediate wiring line 27b electrically connected to the plug 23c and formed in the interlayer insulating film 18. A first end of the plug 23c is formed to make contact with the intermediate wiring line 27a. The intermediate wiring line 27b is formed to make contact with a second end of the plug 23c. The intermediate wiring line 27b is connected to an external terminal Tc2 (not illustrated in FIG. 1) via plugs (not illustrated) or intermediate wiring lines (not illustrated). Hereby, a voltage can be applied to the highly-concentrated impurity diffused region 132 via the external terminal Tc2, the intermediate wiring line 27b, the plug 23c, the intermediate wiring line 27a, the plugs 23a, 23b, and so on.

The chemical sensor 1 provides a plug 23e embedded in an opening that is formed in the interlayer insulating film 18 and that exposes part of the N+ region 136 to a bottom face of the opening, and an intermediate wiring line 27c electrically connected to the plug 23e and formed in the interlayer insulating film 18. A first end of the plug 23e is formed to make contact with the N+ region 136. A silicide is formed on a surface of the N+ region 136, for example. The plug 23e is formed on the silicide formed on the surface of the N+ region 136. This is to reduce contact resistance between the plug 23e and the N+ region 136. The intermediate wiring line 27c is formed to make contact with a second end of the plug 23e.

The chemical sensor 1 provides a plug 23f embedded in an opening that is formed in the interlayer insulating film 18 and that exposes part of the intermediate wiring line 27c on a bottom face of the opening, and an intermediate wiring line 27d electrically connected to the plug 23f and formed in the interlayer insulating film 18. A first end of the plug 23f is formed to make contact with the intermediate wiring line 27d.

The intermediate wiring line 27d is formed to make contact with a second end of the plug 23f. The intermediate wiring line 27d is connected to an external terminal Tb3 (not illustrated in FIG. 1) via plugs (not illustrated) or intermediate wiring lines (not illustrated). Hereby, a voltage can be applied to the N+ region 136 via the external terminal Tb3, the intermediate wiring line 27d, the plug 23f, and so on.

As illustrated in FIG. 1, the sensitive portion 15 provided in the chemical sensor 1 is placed above the floating gate 123 and the control floating portion 113. The sensitive portion 15 has a sensitive membrane 152 and a conductive portion 151 connected to the first potential controlling portion 11, and the sensitive membrane 152 is formed on a first surface side of the conductive portion 151. The conductive portion 151 has a flat-plate shape, for example. Here, the first surface out of the both surfaces of the conductive portion 151 is a surface where the sensitive membrane 152 is formed, and a second surface out of the both surfaces is a surface facing the semiconductor substrate 19. That is, the sensitive membrane 152 is provided to make contact with the surface, out of the opposite surfaces of the conductive portion 151, that does not face the semiconductor substrate 19. The conductive portion 151 is made of metal, for example. The sensitive portion 15 has a flat-plate shape as a whole. A second end of the plug 21d makes contact with a back surface (a surface where the sensitive membrane 152 is not formed) of the conductive portion 151. Hereby, the sensitive portion 15 is electrically connected to the first potential controlling portion 11.

The sensitive membrane 152 has a film thickness of not less than 1 nm but not more than 1000 nm, for example. Further, the sensitive membrane 152 may be any film sensitive to a specific chemical substance, e.g., an insulating sensitive membrane, an organic sensitive membrane, an antibody membrane, or the like. Accordingly, an analysis target to be analyzed by the chemical sensor 1 is not limited. For example, in a case where the chemical sensor 1 measures hydrogen ions, the sensitive membrane 152 may be made of silicon nitride, silicon oxynitride, aluminum oxide, tantalum oxide, hafnium oxide, tin oxide, silicon dioxide, or the like. The sensitive membrane 152 is deposited on an uppermost surface of the conductive portion 151 and placed in an uppermost part of the sensitive portion 15. The interlayer insulating film 18 above the sensitive portion 15 is opened, and therefore, the sensitive membrane 152 is exposed to outside. Hereby, a test sample 91 can be directly placed on the sensitive membrane 152. Thus, the chemical sensor 1 has a structure that allows the sensitive membrane 152 to make direct contact with the test sample 91.

As illustrated in FIG. 1, in the chemical sensor 1, a reference electrode 81 is placed to make contact with the test sample 91. An input terminal Tc1 into which a predetermined reference voltage is input is connected to the reference electrode 81. The predetermined reference voltage is input into the input terminal Tc1 in accordance with a detection operation to detect an ion concentration or the like of the test sample 91, an adjustment operation to adjust the threshold voltage of the transistor 12, and so on. Although details are described later, the reference voltage input from the reference electrode 81 is applied to the floating gate 123 of the transistor 12 via the control floating portion 113 of the first potential controlling portion 11. On this account, at the time of the detection operation of the chemical sensor 1, the reference voltage input from the reference electrode 81 is applied to a circuit in which a capacitance in the sensitive portion 15, a capacitance in the first potential controlling portion 11, and a capacitance in the transistor 12 are connected in series to each other.

In order to improve detectivity to detect the ion concentration or the like of the test sample 91, the chemical sensor 1 should be configured such that the capacitance in the sensitive portion 15 is larger than the capacitance in the transistor 12. This configuration has an effect to efficiently transmit the reference voltage input from the reference electrode 81 to the floating gate 123, in comparison with a configuration in which the capacitance in the sensitive portion 15 is smaller than the capacitance in the transistor 12. Further, in order to efficiently apply the reference voltage input from the reference electrode 81 to the transistor 12, the chemical sensor 1 should be configured such that the capacitance in the first potential controlling portion 11 is larger than the capacitance in the transistor 12. This configuration has an effect to efficiently transmit the reference voltage input from the reference electrode 81 to the floating gate 123, in comparison with a configuration in which the capacitance in the first potential controlling portion 11 is smaller than the capacitance in the transistor 12. Further, in order to efficiently apply the reference voltage input from the reference electrode 81 to the transistor 12, the chemical sensor 1 should be configured such that the capacitance in the sensitive portion 15 is larger than the series combined capacitance of the capacitance in the first potential controlling portion 11 and the capacitance in the transistor 12. This configuration has an effect to efficiently transmit the reference voltage input from the reference electrode 81 to the floating gate 123, in comparison with a configuration in which the capacitance in the sensitive portion 15 is smaller than the series combined capacitance of the capacitance in the first potential controlling portion 11 and the capacitance in the transistor 12. When the reference voltage input from the reference electrode 81 is efficiently transmitted to the floating gate 123 as described above, it is possible to improve the detectivity.

Here, when the capacitance in the transistor 12 is referred to as C12, the capacitance in the first potential controlling portion 11 is referred to as C11, the series combined capacitance of the capacitance in the first potential controlling portion 11 and the capacitance in the transistor 12 is referred to as Cs, and the capacitance in the sensitive portion 15 is referred to as Cm, the chemical sensor 1 should satisfy relationships expressed by Formula (1) and Formula (2).

C11>C12 (1)

Cm>Cs (2)

In the meantime, the capacitance in the sensitive portion 15 is dominated by a capacitance formed by the sensitive membrane 152. On this account, the capacitance formed by the sensitive membrane 152 can be regarded as the capacitance in the sensitive portion 15. Further, a capacitance in the control floating portion 113 can be regarded as the capacitance in the first potential controlling portion 11. The capacitance in the control floating portion 113 is dominated by a capacitance formed by the control insulating film 161. On this account, the capacitance formed by the control insulating film 161 can be regarded as the capacitance in the control floating portion 113. Further, a capacitance in the floating gate 123 can be regarded as the capacitance in the transistor 12. The capacitance in the floating gate 123 is dominated by a capacitance formed by the gate insulating film 162. On this account, the capacitance formed by the gate insulating film 162 can be regarded as the capacitance in the floating gate 123. Accordingly, from Formula (1), the capacitance of the sensitive membrane 152 should be larger than a series combined capacitance of the capacitances in the gate insulating film 162 and in the control insulating film 161.

More specifically, the chemical sensor 1 is configured such that the ratio of the capacitance in the sensitive membrane 152 to the sum of the capacitance in the sensitive membrane 152 and a series combined capacitance of the capacitance in the floating gate 123 and the capacitance in the control floating portion 113 is not less than 0.7 but not more than 1.0. On this account, a voltage of 70% or more of the reference voltage input from the reference electrode 81 is applied to the series combined capacitance of the control floating portion 113 and the floating gate 123. Hereby, in the chemical sensor 1, the reference voltage can be applied to the floating gate 123 of the transistor 12 more efficiently, and thus, it is possible to improve the detectivity.

The chemical sensor 1 is configured such that the ratio of the capacitance in the control floating portion 113 to the sum of the capacitance in the floating gate 123 and the capacitance in the control floating portion 113 is not less than 0.7 but not more than 1.0. On this account, a voltage of 49% or more of the reference voltage input from the reference electrode 81 is applied to the floating gate 123. Hereby, in the chemical sensor 1, the reference voltage can be applied to the floating gate 123 of the transistor 12 further more efficiently, and thus, it is possible to improve the detectivity.

<Operation of Chemical Sensor>

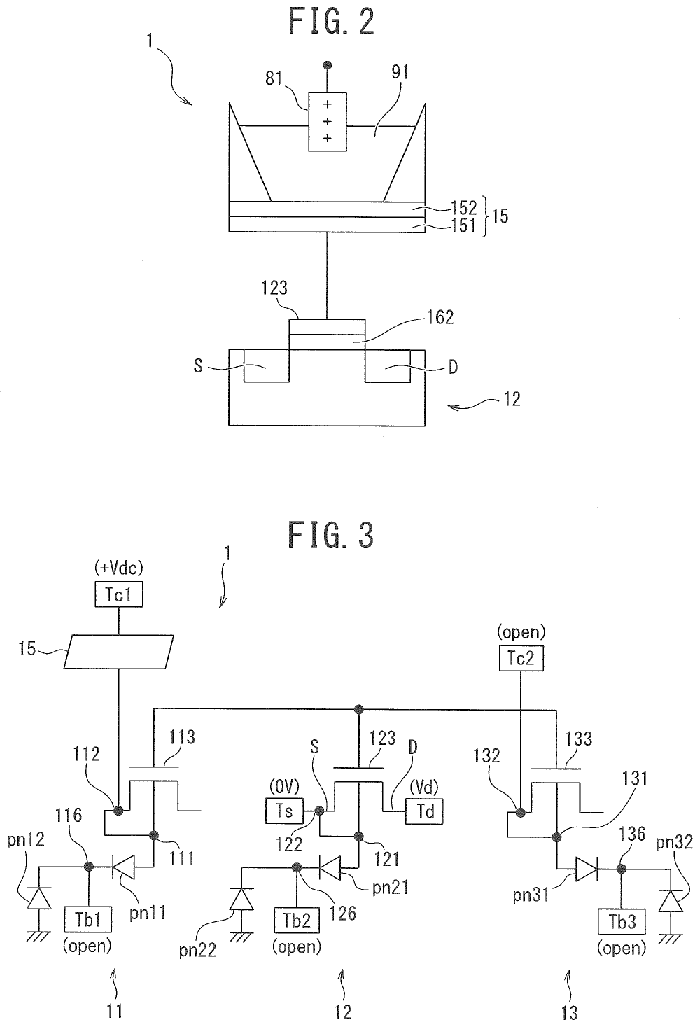

Next will be described the operation of the chemical sensor 1 according to the present embodiment by taking, as an example, a hydrogen-ion concentration sensor, with reference to FIGS. 2 to 5 as well as FIG. 1. First described is the detection principle of the chemical sensor 1 to detect a test sample, with reference to FIG. 2. In order to facilitate understanding, the first potential controlling portion 11 and the first electric-charge flow portion 13 are not illustrated in FIG. 2.

(Detection Principle of Chemical Sensor)

As illustrated in FIG. 2, in the chemical sensor 1, when the test sample 91 is placed on the sensitive portion 15, and a reference voltage is input into the sensitive portion 15 from the reference electrode 81 via the test sample 91, a sensitive group on an interface of the sensitive membrane 152, e.g., a hydroxy group, dissociates, and an electrochemically balanced state is established. At this time, a potential corresponding to the concentration of the test sample 91 occurs on the interface of the sensitive portion 15.

An interface voltage changes in accordance with the concentration of the test sample 91. Accordingly, even when the voltage value of the reference voltage input from the reference electrode 81 is the same, the voltage value of a gate voltage applied to the floating gate 123 of the transistor 12 changes in accordance with the concentration of the test sample 91. By directly reading a drain current Id flowing through the transistor 12 or an interface potential at this time, the concentration of the test sample 91 can be detected.

The characteristic of the drain current to the gate voltage changes in accordance with the threshold voltage of the transistor. The chemical sensor 1 according to the present embodiment can adjust the threshold voltage of the transistor 12 by adjusting the amount of electric charges (electrons) present in the floating gate 123. On this account, the chemical sensor 1 can detect a hydrogen-ion concentration or the like of the test sample 91 without being affected by manufacture variations, variations with time, and so on in the threshold voltage of the transistor 12. Hereby, the chemical sensor 1 can improve the detection accuracy of the test sample 91.

Next will be described the detection operation of the chemical sensor 1 according to the present embodiment with reference to FIGS. 3 to 5. Upon describing the detection operation of the chemical sensor 1, an equivalent circuit of the chemical sensor 1 will be described first with reference to FIG. 3.

(Equivalent Circuit of Chemical Sensor)

The first potential controlling portion 11 has the highly-concentrated impurity diffused region 112 provided on one of the both sides of the control floating portion 113. However, the element isolation layer 191a (not illustrated in FIG. 3, see FIG. 1) is placed on the other of the both sides of the control floating portion 113. On this account, as illustrated in FIG. 3, the first potential controlling portion 11 can be expressed by a circuit mark indicative of a field effect transistor (FET) that one of two terminals that corresponds to a source or a drain is the highly-concentrated impurity diffused region 112 and the other of the two terminals is an opened state.

The input terminal Tc1 for the reference voltage is connected to the highly-concentrated impurity diffused region 112 of the first potential controlling portion 11 via the plugs 21a, 21b (not illustrated in FIG. 3, see FIG. 1) and so on, the sensitive portion 15, and the reference electrode 81 (not illustrated in FIG. 3, see FIG. 1). The highly-concentrated impurity diffused region 112 is connected to the P-well region 111 via the P+ region 112a. Between the P-well region 111 and the N+ region 116, a PN junction pn11 is formed by the P-well region 111, the deep N-well region 114 (not illustrated in FIG. 3, see FIG. 1), the N-well region 115 (not illustrated in FIG. 3, see FIG. 1), and the N+ region 116.

The external terminal Tb1 is connected to the N+ region 116 via the plug 21f (not illustrated in FIG. 3, see FIG. 1) and so on. Between the N+ region 116 and a P-type region (a region indicated by “Psub” in FIG. 1) where well regions of the semiconductor substrate 19 are not formed, a PN junction pn12 is formed by the N+ region 116, the N-well region 115, the deep N-well region 114, and the P-type region. In the chemical sensor 1 according to the present embodiment, the P-type region is connected to the ground, for example.

As illustrated in FIG. 3, the control floating portion 113 of the first potential controlling portion 11 is connected to the floating gate 123 of the transistor 12 via the first connecting portion 17a (not illustrated in FIG. 3, see FIG. 1). The external terminal Ts is connected to the source S of the transistor 12 via the plug 22b and so on. The external terminal Td is connected to the drain D of the transistor 12 via the plug 22e and so on.

Further, the P+ region 122 is connected to the source S of the transistor 12. The P-well region 121 of the transistor 12 is connected to the P+ region 122. Between the P-well region 121 and the N+ region 126, a PN junction pn21 is formed by the P-well region 121, the deep N-well region 124 (not illustrated in FIG. 3, see FIG. 1), the N-well region 125 (not illustrated in FIG. 3, see FIG. 1), and the N+ region 126.

The external terminal Tb2 is connected to the N+ region 126 via the plug 22f (not illustrated in FIG. 3, see FIG. 1) and so on. Between the N+ region 126 and the P-type region of the semiconductor substrate 19 where well regions are not formed, a PN junction pn22 is formed by the N+ region 126, the N-well region 125, the deep N-well region 124, and the P-type region.

As illustrated in FIG. 3, the floating gate 123 of the transistor 12 is connected to the first floating portion 133 of the first electric-charge flow portion 13 via the second connecting portion 17b (not illustrated in FIG. 3, see FIG. 1). The first electric-charge flow portion 13 has the highly-concentrated impurity diffused region 132 provided on one of the both sides of the first floating portion 133. However, the element isolation layer 191d (not illustrated in FIG. 3, see FIG. 1) is placed on the other of the both sides of the first floating portion 133. On this account, as illustrated in FIG. 3, in the first electric-charge flow portion 13 can be expressed by a circuit mark indicative of a field effect transistor (FET) that one of two terminals that corresponds to a source or a drain is the highly-concentrated impurity diffused region 132, and the other of the two terminals is an opened state.

The external terminal Tc2 is connected to the highly-concentrated impurity diffused region 132 of the first electric-charge flow portion 13 via the plug 23a, 23b (not illustrated in FIG. 3, see FIG. 1) and so on. The highly-concentrated impurity diffused region 132 is connected to the P-well region 131 via the P+ region 132a. Between the P-well region 131 and the N+ region 136, a PN junction pn31 is formed by the P-well region 131, the deep N-well region 134 (not illustrated in FIG. 3, see FIG. 1), the N-well region 135 (not illustrated in FIG. 3, see FIG. 1), and the N+ region 136.

The external terminal Tb3 is connected to the N+ region 136 via the plug 23f (not illustrated in FIG. 3, see FIG. 1) and so on. Between the N+ region 136 and the P-type region of the semiconductor substrate 19 where well regions are not formed, a PN junction pn32 is formed by the N+ region 136, the N-well region 135, the deep N-well region 134, and the P-type region.

(Detection Operation of Chemical Sensor)

As illustrated in FIG. 3, in the chemical sensor 1, in a case where the hydrogen-ion concentration or the like of the test sample 91 is to be detected, a positive direct voltage Vdc is input into the input terminal Tc1 as the reference voltage. Further, in this case, in the chemical sensor 1, a voltage of zero volts (V) is input into the source S of the transistor 12, and a voltage as a drain voltage Vd (e.g., 0.1 V) is input into the drain D of the transistor 12. Further, in this case, in the chemical sensor 1, the external terminals Tb1, Tb2, Tb3, Tc2 are brought into an opened state.

Hereby, a gate voltage obtained by adding an interface voltage on the sensitive membrane 152 to the direct voltage Vdc is applied to the floating gate 123 of the transistor 12 via the sensitive portion 15 and the first potential controlling portion 11. Further, respective voltages described above are input into the source S and the drain D of the transistor 12. Hereby, the transistor 12 operates. Since the interface voltage of the sensitive membrane 152 changes in accordance with the hydrogen-ion concentration of the test sample 91, a gate voltage on which the hydrogen-ion concentration of the test sample 91 is reflected is applied to the floating gate 123 of the transistor 12. As a result, a drain current on which the hydrogen-ion concentration of the test sample 91 is reflected flows through the transistor 12. Hereby, the chemical sensor 1 can detect the hydrogen-ion concentration of the test sample 91.

(Adjustment Operation on Threshold Voltage of Transistor in Chemical Sensor)

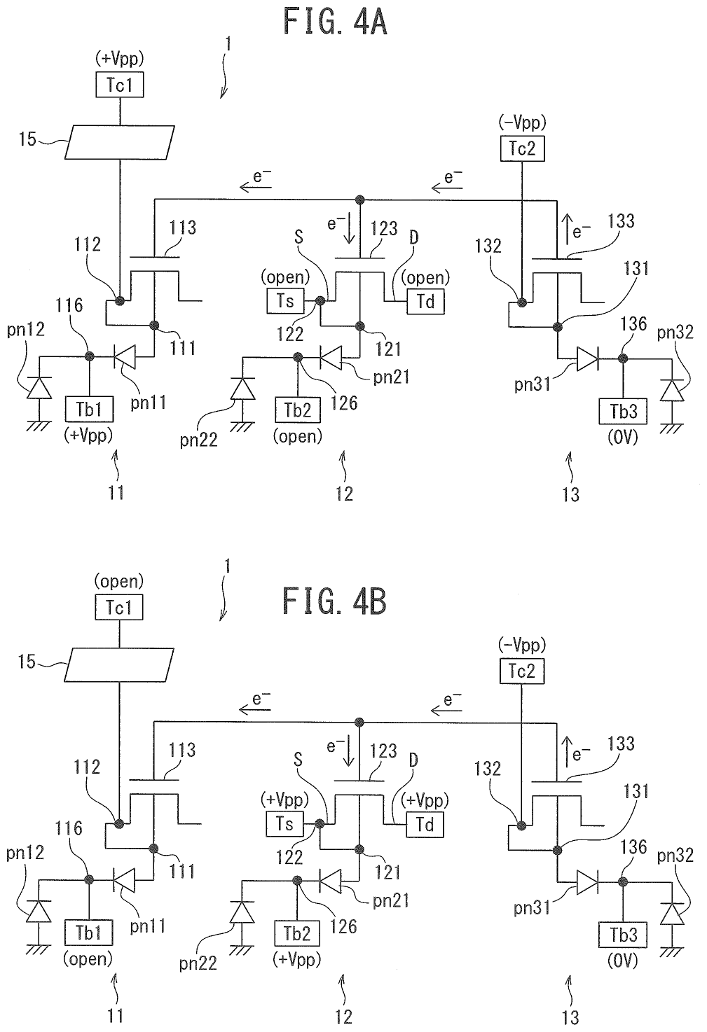

With reference to FIGS. 4A and 4B, the following describes an operation to adjust the threshold voltage to bring the transistor 12 provided in the chemical sensor 1 into an enhancement state by injecting electric charges into the floating gate 123. First described is a first operation to adjust the threshold voltage to bring the transistor 12 into the enhancement state, with reference to FIG. 4A.

As illustrated in FIG. 4A, in the first operation, a reference sample used for adjustment of the threshold voltage of the transistor 12 is placed on the sensitive portion 15. The reference sample is a sample the hydrogen-ion concentration of which is known. In the first operation, in the chemical sensor 1, a pulse voltage of which the voltage value is inverted from 0 V to +Vpp is input into the input terminal Tc1 as the reference voltage. The reference voltage is applied to the first floating portion 133 via the reference sample, the sensitive portion 15, the control floating portion 113 of the first potential controlling portion 11, the first connecting portion 17a, the floating gate 123 of the transistor 12, and the second connecting portion 17b. Further, in the case of the first operation, in the chemical sensor 1, the same pulse voltage as the input terminal Tc1 is applied to the external terminal Tb1. Further, in the case of the first operation, in the chemical sensor 1, the external terminal Ts connected to the source S of the transistor 12 and the external terminal Td connected to the drain D of the transistor 12 are brought into an opened state. Furthermore, in the case of the first operation, in the chemical sensor 1, a pulse voltage of which is the voltage value inverted from 0 V to −Vpp is input into the external terminal Tc2 of the first electric-charge flow portion 13, and a voltage of 0 V is input into the external terminal Tb3 of the first electric-charge flow portion 13 (the external terminal Tb3 is connected to the ground, for example).

Hereby, Fowler-Nordheim tunneling conduction (FN tunneling) occurs in the first insulating film 163, and as indicated by straight arrows in FIG. 4A, electrons e− are injected into the floating gate 123 from the P-well region 131 of the first electric-charge flow portion 13 through the first insulating film 163, the first floating portion 133, and the second connecting portion 17b. Hereby, the threshold voltage of the transistor 12 increases. After electric charges are injected, the threshold voltage of the transistor 12 in a state where the reference sample is placed is checked by a method similar to the detection operation of the chemical sensor 1 as described with reference to FIG. 3. The injection of the electrons e− into the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are injected into the floating gate 123 by the first operation, the capacitance in the control floating portion 113 should be larger than the capacitance in the first floating portion 133. This configuration has an effect to efficiently transmit a voltage input into the control floating portion 113 to the first floating portion 133, in comparison with a configuration in which the capacitance in the control floating portion 113 is smaller than the capacitance in the first floating portion 133. As a result, the efficiency of the adjustment of the threshold voltage can be improved.

Next described is a second operation to adjust the threshold voltage to bring the transistor 12 into the enhancement state, with reference to FIG. 4B.

As illustrated in FIG. 4B, in the second operation, in the chemical sensor 1, the input terminal Tc1 and the external terminal Tb1 are brought into an opened state. In the second operation, the reference sample is not placed on the sensitive portion 15. Further, in the case of the second operation, in the chemical sensor 1, a pulse voltage of which the voltage value is inverted from 0 V to +Vpp is input into the source S and the drain D of the transistor 12 and the external terminal Tb2. Furthermore, in the case of the second operation, in the chemical sensor 1, a pulse voltage of which the voltage value is inverted from 0 V to −Vpp is input into the external terminal Tc2 of the first electric-charge flow portion 13, and a voltage of 0 V is input into the external terminal Tb3 of the first electric-charge flow portion 13 (the external terminal Tb3 is connected to the ground, for example).

Hereby, FN tunneling occurs in the first insulating film 163, and as indicated by straight arrows in FIG. 4B, electrons e− are injected into the floating gate 123 from the P-well region 131 through the first insulating film 163, the first floating portion 133, and the second connecting portion 17b. Hereby, the threshold voltage of the transistor 12 increases. The threshold voltage of the transistor 12 is checked by a method similar to the detection operation of the chemical sensor 1 as described with reference to FIG. 3. The injection of the electrons e− into the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are injected into the floating gate 123 by the second operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

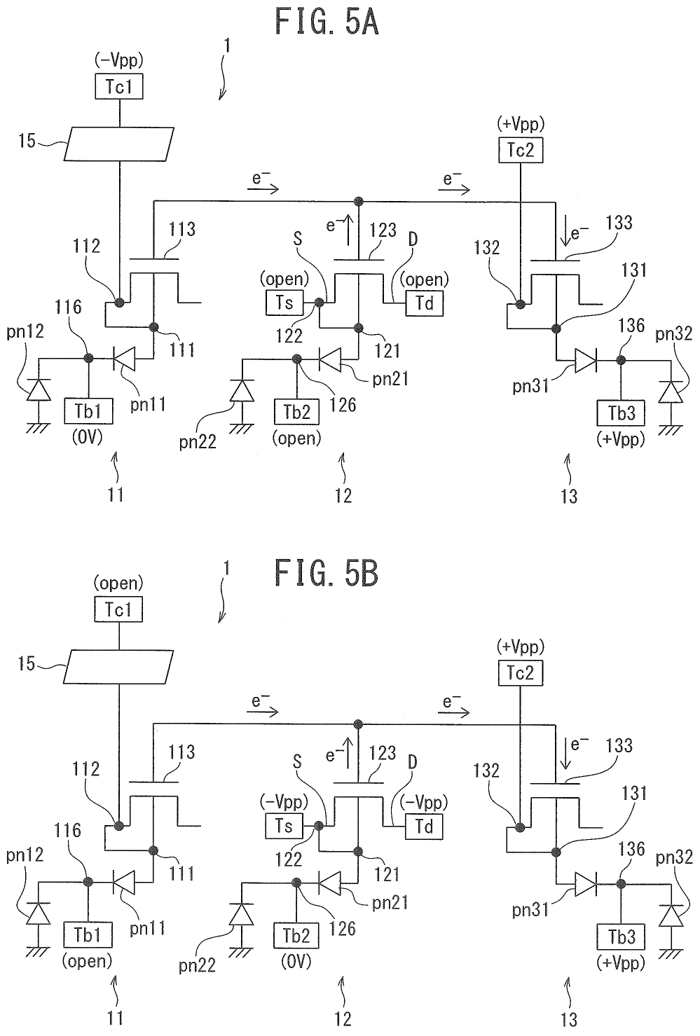

With reference to FIGS. 5A and 5B, the following describes an operation to adjust the threshold voltage to bring the transistor 12 provided in the chemical sensor 1 into a depression state by discharging electric charges from the floating gate 123. First described is a first operation to adjust the threshold voltage to bring the transistor 12 to into the depression state, with reference to FIG. 5A.

As illustrated in FIG. 5A, in the first operation, a reference sample used for adjustment of the threshold voltage of the transistor 12 is placed on the sensitive portion 15. In the first operation, in the chemical sensor 1, a pulse voltage of which the voltage value is inverted from 0 V to −Vpp is input into the input terminal Tc1 as the reference voltage. The reference voltage is applied to the first floating portion 133 via the reference sample, the sensitive portion 15, the control floating portion 113 of the first potential controlling portion 11, the first connecting portion 17a, the floating gate 123 of the transistor 12, and the second connecting portion 17b. Further, in the case of the first operation, in the chemical sensor 1, a voltage of 0 V is input into the external terminal Tb1 (the external terminal Tb1 is connected to the ground, for example). Further, in the case of the first operation, in the chemical sensor 1, the source S and the drain D of the transistor 12 are brought into an opened state. Furthermore, in the case of the first operation, in the chemical sensor 1, a pulse voltage the of which voltage value is inverted from 0 V to +Vpp is input into the external terminal Tc2 and the external terminal Tb3 of the first electric-charge flow portion 13.

Hereby, FN tunneling occurs in the first insulating film 163, and as indicated by straight arrows in FIG. 5A, electrons e− are discharged from the floating gate 123 to the P-well region 131 through the second connecting portion 17b, the first floating portion 133, and the first insulating film 163. Hereby, the threshold voltage of the transistor 12 decreases. The threshold voltage of the transistor 12 is checked by a method similar to the detection operation of the chemical sensor 1 as described with reference to FIG. 3. The discharge of the electrons e− from the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are discharged from the floating gate 123 by the first operation, the capacitance in the control floating portion 113 should be larger than the capacitance in the first floating portion 133. This configuration has an effect to efficiently transmit a voltage input into the control floating portion 113 to the first floating portion 133, in comparison with a configuration in which the capacitance in the control floating portion 113 is smaller than the capacitance in the first floating portion 133. As a result, the efficiency of the adjustment of the threshold voltage can be improved.

Next described is a second operation to adjust the threshold voltage to bring the transistor 12 into the depression state, with reference to FIG. 5B.

As illustrated in FIG. 5B, in the second operation, in the chemical sensor 1, the input terminal Tc1 and the external terminal Tb1 are brought into an opened state. In the second operation, the reference sample is not placed on the sensitive portion 15. Further, in the case of the second operation, in the chemical sensor 1, a pulse voltage of which the voltage value is inverted from 0 V to +Vpp is input into the source S and the drain D of the transistor 12 and the external terminal Tb2. Furthermore, in the case of the second operation, in the chemical sensor 1, a pulse voltage of which the voltage value is inverted from 0 V to +Vpp is input into the external terminal Tc2 and the external terminal Tb3 of the first electric-charge flow portion 13.

Hereby, FN tunneling occurs in the first insulating film 163, and as indicated by straight arrows in FIG. 5B, electrons e− are discharged from the floating gate 123 to the P-well region 131 through the second connecting portion 17b, the first floating portion 133, and the first insulating film 163. Hereby, the threshold voltage of the transistor 12 decreases. The threshold voltage of the transistor 12 is checked by a method similar to the detection operation of the chemical sensor 1 as described with reference to FIG. 3. The discharge of the electrons e− from the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are discharged from the floating gate 123 by the second operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

(Effect of Chemical Sensor)

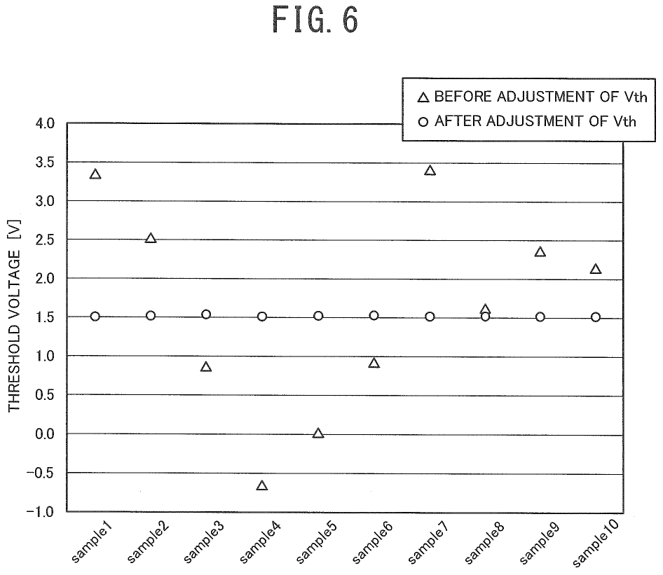

Next will be described an effect of the chemical sensor 1 according to the present embodiment with reference to FIG. 6. FIG. 6 is a graph illustrating measurement results of threshold voltages before and after adjustment regarding transistors provided in samples having a configuration similar to the chemical sensor 1. Triangular marks illustrated in FIG. 6 indicate measured values of threshold voltages of the transistors before adjustment, and circular marks illustrated in FIG. 6 indicate measured values of threshold voltages of the transistors, the threshold voltages being adjusted to a range of 1.5 V to ±0.01 V by use of phosphate buffer of pH 6.9. Each of the measured values of the threshold voltages before and after the adjustment, illustrated in FIG. 6, is the average value of 10 measured values of the threshold voltage of each sample. The horizontal axis in the graph illustrated in FIG. 6 indicates sample. The vertical axis in the graph illustrated in FIG. 6 indicates threshold voltage [V]. In FIG. 6, a gate voltage at which a drain current of 3 nA flows is defined as the threshold voltage.

As illustrated in FIG. 6, regarding 10 samples from sample 1 to sample 10, before the threshold voltages are adjusted, the threshold voltages of the transistors vary within a range from −1 V to 3.5 V. On the other hand, after the threshold voltages are adjusted, the threshold voltages fall within the range of 1.5 V to ±0.01 V in all the 10 samples from sample 1 to sample 10. As such, the chemical sensor 1 according to the present embodiment can adjust the threshold voltage of the transistor 12 to a desired value, and thus, it is possible to improve the detection accuracy of a test sample.

The chemical sensor 1 according to the present embodiment includes the control insulating film 161, the gate insulating film 162, and the first insulating film 163 having an excellent membrane quality and formed by thermal oxidation. The floating gate 123 is capacitively coupled to the gate insulating film 162, the control floating portion 113 is capacitively coupled to the control insulating film 161, and the first floating portion 133 is capacitively coupled to the first insulating film 163. Hereby, the chemical sensor 1 has a structure in which electric charges are trapped in the control floating portion 113, the floating gate 123, and the first floating portion 133 by the control insulating film 161, the gate insulating film 162, and the first insulating film 163. On this account, the chemical sensor 1 can achieve improvement in the electric-charge retention characteristic.

Further, the chemical sensor 1 does not have a structure in which a conductive portion of a sensitive portion is directly connected to a floating gate made of polysilicon through a wiring via like conventional chemical sensors. When the conductive portion is directly connected to the floating gate like the conventional chemical sensors, an electric-charge accumulation part expands to the wiring via and the conductive portion. The wiring via and the conductive portion are not designed to retain electric charges. Because of this, when a floating portion extends to the wiring via and the conductive portion such that an electric-charge accumulation layer expands, a parasitic capacitance increases, and leakage current easily occurs. As a result of diligent studies by the inventors of the present invention, it was found that, when the electric-charge accumulation layer expands to the wiring via and the conductive portion, the amount of leakage current increases, and an adjusted threshold voltage of a transistor cannot be retained for a long time.

The chemical sensor 1 according to the present embodiment has a structure in which the conductive portion 151 of the sensitive portion 15 is connected not to the floating gate 123 but to the highly-concentrated impurity diffused region 112 of the first potential controlling portion 11. Hereby, electric charges can be accumulated only in the floating gate 123, the control floating portion 113, and the first floating portion 133 that are designed to be used as memories. As a result, the chemical sensor 1 can retain the electric charges accumulated in the floating gate 123, the control floating portion 113, and the first floating portion 133 for a long time. Further, since the chemical sensor 1 is configured such that the conductive portion 151 is connected to the highly-concentrated impurity diffused region 112 that is part of the semiconductor substrate 19, plasma damage caused when plugs and intermediate wiring lines are formed can be released to the substrate. As a result, the chemical sensor 1 can achieve improvement in reliability of the control insulating film 161, the gate insulating film 162, and the first insulating film 163.

<Modifications>

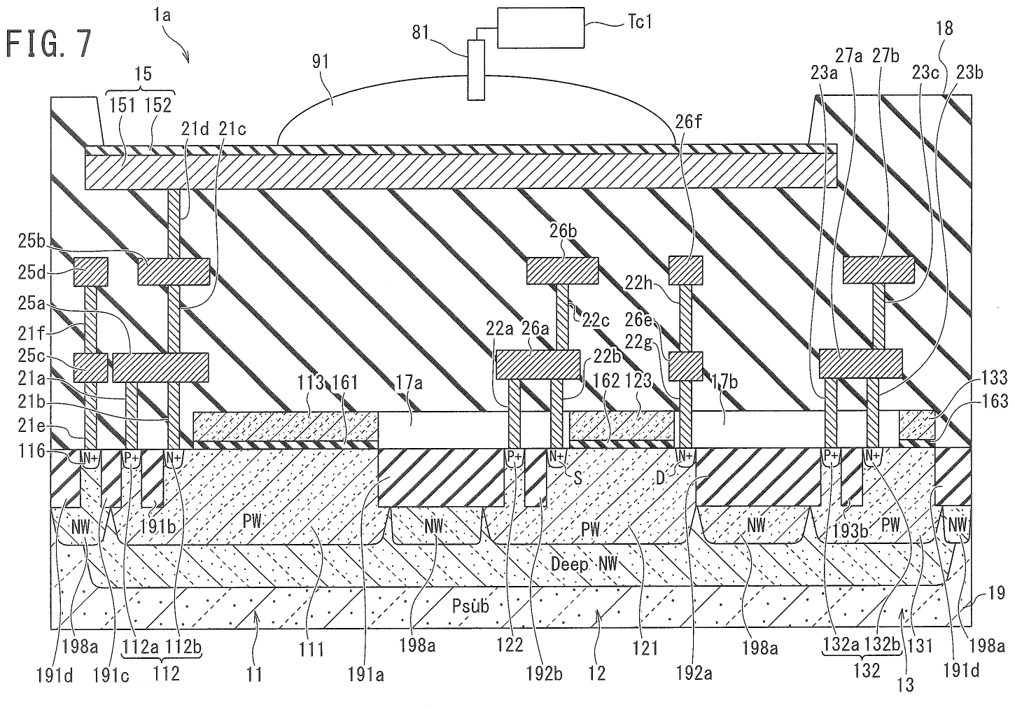

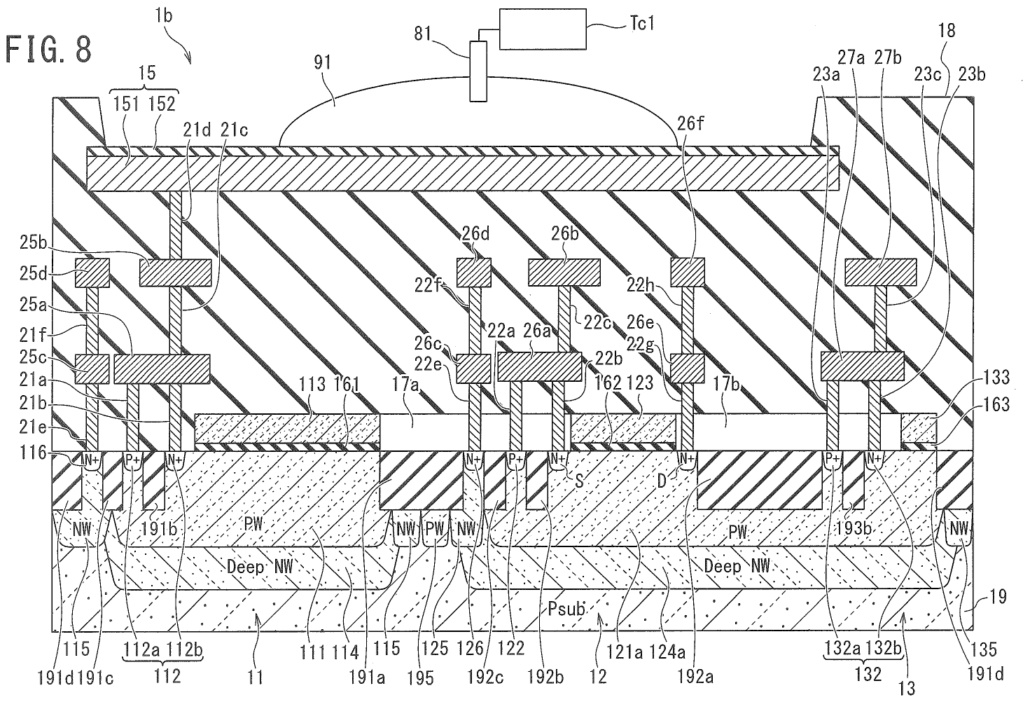

The following describes chemical sensors according to modifications of the present embodiment with reference to FIGS. 7 and 8. Upon describing the chemical sensors according to the modifications, the same reference sign as a constituent in the chemical sensor 1 according to the present embodiment is assigned to a constituent having a similar operation and function to those of the constituent in the chemical sensor 1, and descriptions of the constituent are omitted.

(Modification 1)

As illustrated in FIG. 7, a chemical sensor 1a according to Modification 1 of the present embodiment does not have the N+ regions 126, 136, the plugs 22e, 22f, 23e, 23f, and the intermediate wiring lines 26c, 26d, 27c, 27d, as compared with the chemical sensor 1 according to the above embodiment. Further, the chemical sensor 1a has an N-well region 198a instead of the N-well regions 115, 125, 135 and the P-well region 195, 196, as compared with the chemical sensor 1 according to the above embodiment. The N-well region 198a is placed right under the element isolation layers 191a, 192a.

The chemical sensor 1a provides a deep N-well region 199a having the N-type and formed in the semiconductor substrate 19 to surround the P-well region 111, the P-well region 121, and the P-well region 131 at a position deeper than the P-well region 111, the P-well region 121, and the P-well region 131. Further, the chemical sensor 1a has the N-well region 198a formed around the P-well region 111, the P-well region 121, and the P-well region 131. The N-well region 198a is formed in the deep N-well region 199a. Hereby, the chemical sensor 1a can prevent leakage current from flowing into the semiconductor substrate 19 in response to a voltage being applied to at least one of the P-well region 111, the P-well region 121, and the P-well region 131, similarly to the chemical sensor 1.

(Modification 2)

As illustrated in FIG. 8, a chemical sensor 1b according to Modification 2 of the present embodiment does not have the N+ region 136, the plugs 23e, 23f, and the intermediate wiring lines 27c, 27d, as compared with the chemical sensor 1 according to the above embodiment. Further, the chemical sensor 1b has a P-well region 121a instead of the P-well regions 121, 131, as compared with the chemical sensor 1 according to the above embodiment. The P-well region 121a is formed continuously over the transistor 12 and the first electric-charge flow portion 13.

The chemical sensor 1b provides a deep N-well region 124a having the N-type and formed in the semiconductor substrate 19 right under the P-well region 121a over the arrangement region for the transistor 12 and the arrangement region for the first electric-charge flow portion 13 at a position deeper than the P-well region 121a. Hereby, the chemical sensor 1b can prevent leakage current from flowing into the semiconductor substrate 19 in response to a voltage being applied to at least one of the P-well region 111 and the P-well region 121a, similarly to the chemical sensor 1.

As described above, the chemical sensors according to the present embodiment and the modifications can control the threshold voltage of the transistor and achieve improvement in the electric-charge retention characteristic.

### Second Embodiment

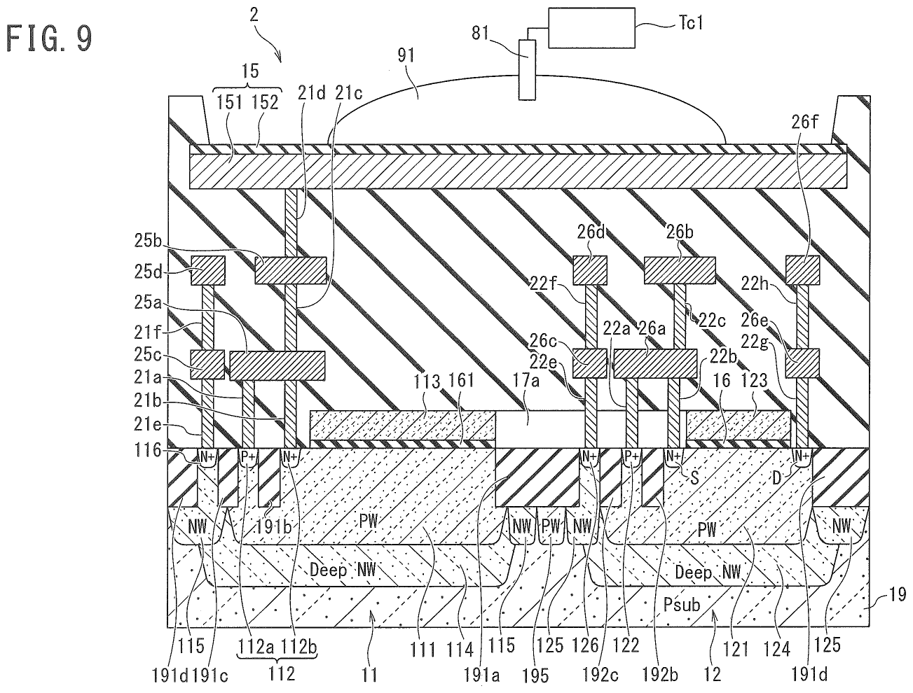

The following describes a chemical sensor according to a second embodiment of the present invention with reference to FIGS. 9 to 13. First described is a schematic configuration of a chemical sensor 2 according to the present embodiment with reference to FIG. 9. Upon describing the chemical sensor according to the present embodiment, the same reference sign as a constituent in the chemical sensor according to the first embodiment or the modifications is assigned to a constituent having a similar operation and function to those of the constituent in the chemical sensor according to the first embodiment or the modifications, and descriptions of the constituent are omitted.

<Configuration of Chemical Sensor>

As illustrated in FIG. 9, the chemical sensor 2 according to the present embodiment does not include an electric-charge flow portion, differently from the chemical sensor 1 according to the first embodiment. The chemical sensor 2 has a feature in that electric charges are injected into the floating gate 123 or electric charges are discharged from the floating gate 123 by use of the transistor 12. The first potential controlling portion 11 and the sensitive portion 15 included in the chemical sensor 2 have the same configurations as the first potential controlling portion 11 and the sensitive portion 15 included in the chemical sensor 1 according to the first embodiment.

The transistor 12 includes the P-well region 121 (one example of the fourth impurity diffused region) formed in the semiconductor substrate 19 and having the P-type. The P-well region 121 has the same configuration as the P-well region 111 in the first embodiment. The transistor 12 includes a gate insulating film 16 placed to be sandwiched between the P-well region 121 and the floating gate 123 and formed to make contact with the P-well region 121 and the floating gate 123. The gate insulating film 16 is formed right under the floating gate 123. The P-well region 121 is formed to include a region right under the gate insulating film 16.

The gate insulating film 16 at least partially has a region with a film thickness of not less than 6 nm but less than 15 nm, for example. In the present embodiment, the gate insulating film 16 has the region with a film thickness of not less than 6 nm but less than 15 nm as a whole. The gate insulating film 16 may have a film thickness within a range of not less than 6 nm but less than 15 nm as a whole, and an irregular shape may be formed on a surface of the gate insulating film 16. Alternatively, the gate insulating film 16 may have a uniform film thickness (e.g., a given thickness of 6 nm) within a range of not less than 6 nm but less than 15 nm, for example, and the surface of the gate insulating film 16 may have a flat shape. When the gate insulating film 16 has a film thickness thinner than 6 nm, direct tunneling easily occurs in the gate insulating film 16, and the electric-charge retention characteristic (retention characteristic) of the floating gate 123 worsens. In the meantime, when the gate insulating film 16 has a film thickness thicker than 15 nm, injection of electric charges into the floating gate 123 and discharge of electric charges from the floating gate 123 become slow. In view of this, when the gate insulating film 16 at least partially has the region with a film thickness of not less than 6 nm but less than 15 nm, the chemical sensor 2 can achieve improvement in the electric-charge retention characteristic and improvement in injection speed and discharge speed of electric charges between the floating gate 123 and the P-well region 121.

The gate insulating film 16 is a thermal oxide film, for example. The gate insulating film 16 is formed by thermally oxidizing the surface of the semiconductor substrate 19 at high temperature. The control insulating film 161 and the gate insulating film 16 are formed at the same time in the same heat treatment step, for example. The gate insulating film 16 is made of a silicon oxide film (SiO₂), a silicon oxynitride film (SiON), or the like, for example. Since the gate insulating film 16 is made of a thermal oxide film by high-temperature treatment, it is possible to prevent the occurrence of leakage current in the transistor 12.

The transistor 12 has the source S formed in the P-well region 121 on one of the both sides of the floating gate 123 and having the N-type, and the drain D formed in the P-well region 121 on the other of the both sides of the floating gate 123 and having the N-type. The source S and the drain D are constituted by a highly-concentrated impurity diffused region having an impurity concentration higher than that of the P-well region 121.

The transistor 12 has the P+ region 122 (one example of the highly-concentrated impurity diffused region) having the P-type and containing impurities at a concentration higher than that in the P-well region 121. The P+ region 122 is formed in the P-well region 121, and a voltage is applicable to the P+ region 122. The element isolation layer 192b is formed between the P+ region 122 and the source S. The element isolation layer 192b is formed in the P-well region 121. Hereby, the P+ region 122 and the source S do not make direct contact with each other.

The transistor 12 has the N-well region 125 formed in the semiconductor substrate 19. The N-well region 125 is formed around the P-well region 121 in a state where the N-well region 125 partially makes contact with the P-well region 121. The N-well region 125 is formed to have generally the same depth as the P-well region 121. The transistor 12 has the N+ region 126 formed in the N-well region 125. The element isolation layer 192c is formed between the N-well region 125 and the P+ region 122. The element isolation layer 192c is formed in the P-well region 121. The element isolation layer 192c is also placed between the N+ region 126 and the P+ region 122. Hereby, the N+ region 126 and the P+ region 122 do not make direct contact with each other.

<Operation of Chemical Sensor>

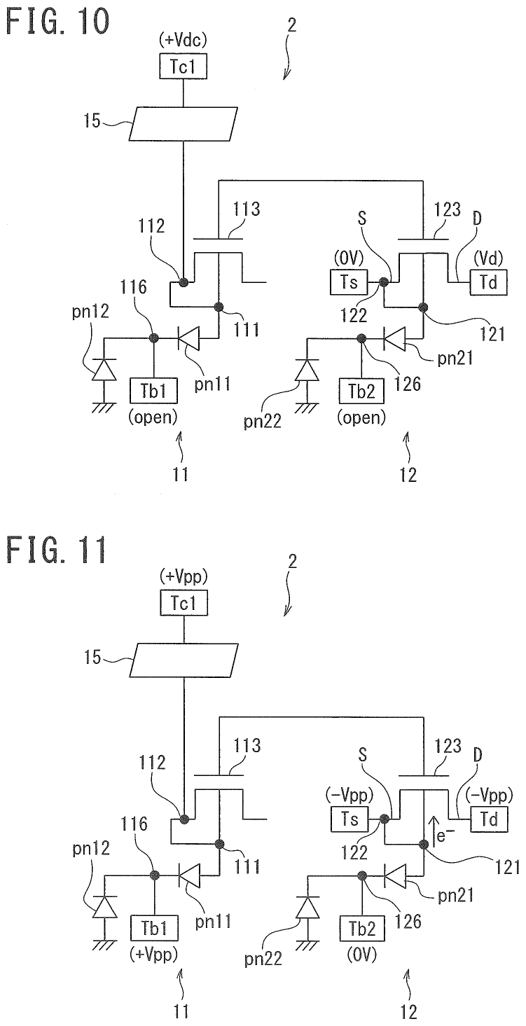

Next will be described the operation of the chemical sensor 2 according to the present embodiment by taking, as an example, a hydrogen-ion concentration sensor, with reference to FIGS. 10 to 12 as well as FIG. 9.

(Equivalent Circuit of Chemical Sensor)

As illustrated in FIG. 9, the chemical sensor 2 according to the present embodiment can be expressed by an equivalent circuit similar to that of the chemical sensor 1 according to the first embodiment except that the chemical sensor 2 does not include the first electric-charge flow portion.

(Detection Operation of Chemical Sensor)

As illustrated in FIG. 10, in the chemical sensor 2 according to the present embodiment, in a case where the hydrogen-ion concentration or the like of the test sample 91 is to be detected, a positive direct voltage Vdc is input into the input terminal Tc1 as a reference voltage. Further, in this case, in the chemical sensor 2, a voltage of zero volts (V) is input into the source S of the transistor 12, a voltage as a drain voltage Vd (e.g., 0.1 V) is input into the drain D of the transistor 12, and the external terminals Tb1, Tb2 are brought into an opened state.

Hereby, a gate voltage obtained by adding an interface voltage on the sensitive membrane 152 to a pulse voltage Vpp is applied to the floating gate 123 of the transistor 12 via the sensitive portion 15 and the first potential controlling portion 11. Further, respective voltages described above are input into the source S and the drain D of the transistor 12. Hereby, the transistor 12 operates. Since the interface voltage of the sensitive membrane 152 changes in accordance with the hydrogen-ion concentration of the test sample 91, a gate voltage on which the hydrogen-ion concentration of the test sample 91 is reflected is applied to the floating gate 123 of the transistor 12. As a result, a drain current on which the hydrogen-ion concentration of the test sample 91 is reflected flows through the transistor 12. Hereby, the chemical sensor 2 can detect the hydrogen-ion concentration of the test sample 91. Thus, the chemical sensor 2 can detect the hydrogen-ion concentration or the like of the test sample 91 by an operation similar to that of the chemical sensor 1 according to the first embodiment.

(Adjustment Operation of Threshold Voltage of Transistor in Chemical Sensor)

With reference to FIG. 11, the following describes an operation to adjust the threshold voltage to bring the transistor 12 provided in the chemical sensor 2 into the enhancement state by injecting electric charges into the floating gate 123.

As illustrated in FIG. 11, in the adjustment operation on the threshold voltage to bring the transistor 12 into the enhancement state, a reference sample used for adjustment of the threshold voltage of the transistor 12 is placed on the sensitive portion 15. The reference sample is a sample of which the hydrogen-ion concentration is known. In the adjustment operation on the threshold voltage, in the chemical sensor 2, a pulse voltage of which the voltage value is inverted from 0 V to +Vpp is input into the input terminal Tc1 as the reference voltage. The reference voltage is applied to the control floating portion 113 via the reference sample, the sensitive portion 15, the control floating portion 113 of the first potential controlling portion 11, and the first connecting portion 17a. Further, in the case of the adjustment operation on the threshold voltage, in the chemical sensor 2, the same pulse voltage as the input terminal Tc1 is applied to the external terminal Tb1. Further, in the case of the adjustment operation on the threshold voltage, in the chemical sensor 2, a pulse voltage of which the voltage value is inverted from 0 V to −Vpp is input into the external terminal Ts connected to the source S of the transistor 12 and the external terminal Td connected to the drain D of the transistor 12. Further, in the case of the adjustment operation on the threshold voltage, in the chemical sensor 2, a voltage of 0 V is input into the external terminal Tb2 (the external terminal Tb2 is connected to the ground, for example).

Hereby, FN tunneling occurs in the gate insulating film 16, and as indicated by straight arrows in FIG. 11, electrons e− are injected into the floating gate 123 from the P-well region 121 through the gate insulating film 16. The threshold voltage of the transistor 12 increases. The threshold voltage of the transistor 12 is checked by a method similar to the detection operation of the chemical sensor 2 as described with reference to FIG. 10. The injection of the electrons e− into the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are injected into the floating gate 123, the capacitance in the control floating portion 113 should be larger than the capacitance in the floating gate 123. This configuration has an effect to efficiently transmit a voltage input into the control floating portion 113 to the floating gate 123, in comparison with a configuration in which the capacitance in the control floating portion 113 is smaller than the capacitance in the floating gate 123. As a result, the efficiency of the adjustment of the threshold voltage can be improved.

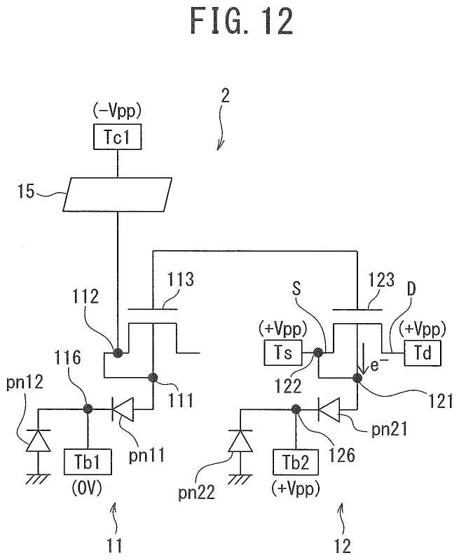

With reference to FIG. 12, the following describes an operation to adjust the threshold voltage to bring the transistor 12 included in the chemical sensor 2 into the depression state by discharging electric charges from the floating gate 123.

As illustrated in FIG. 12, in the adjustment operation on the threshold voltage, a reference sample used for adjustment of the threshold voltage of the transistor 12 is placed on the sensitive portion 15. In the adjustment operation on the threshold voltage, in the chemical sensor 2, a pulse voltage of which the voltage value is inverted from 0 V to −Vpp is input into the input terminal Tc1 as the reference voltage. The reference voltage is applied to the floating gate 123 via the reference sample, the sensitive portion 15, the control floating portion 113 of the first potential controlling portion 11, and the first connecting portion 17a. Further, in the case of the adjustment operation on the threshold voltage, in the chemical sensor 2, a voltage of 0 V is input into the external terminal Tb1 (the external terminal Tb1 is connected to the ground, for example). Further, in the case of the adjustment operation on the threshold voltage, in the chemical sensor 2, a pulse voltage of which the voltage value is inverted from 0 V to +Vpp is input into the external terminal Ts connected to the source S of the transistor 12 and the external terminal Td connected to the drain D. Furthermore, in the case of the adjustment operation on the threshold voltage, in the chemical sensor 2, a pulse voltage of which the voltage value is inverted from 0 V to +Vpp is input into the input terminal Tb2.

Hereby, FN tunneling occurs in the gate insulating film 16, and as indicated by straight arrows in FIG. 12, electrons e− are discharged from the floating gate 123 to the P-well region 121 through the gate insulating film 16. Hereby, the threshold voltage of the transistor 12 decreases. The threshold voltage of the transistor 12 is checked by a method similar to the detection operation of the chemical sensor 2 as described with reference to FIG. 10. The discharge of the electrons e− from the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished. Note that, in a case where electric charges are discharged from the floating gate 123, the capacitance in the control floating portion 113 should be larger than the capacitance in the floating gate 123. This configuration has an effect to efficiently transmit a voltage input into the control floating portion 113 to the floating gate 123, in comparison with a configuration in which the capacitance in the control floating portion 113 is smaller than the capacitance in the floating gate 123. As a result, the efficiency of the adjustment of the threshold voltage can be improved.

Thus, the chemical sensor 2 according to the present embodiment can adjust the threshold voltage of the transistor 12 by controlling the amount of electric charge of the floating gate 123 via the P-well region 121 and the gate insulating film 16 of the transistor 12.

<Modification>

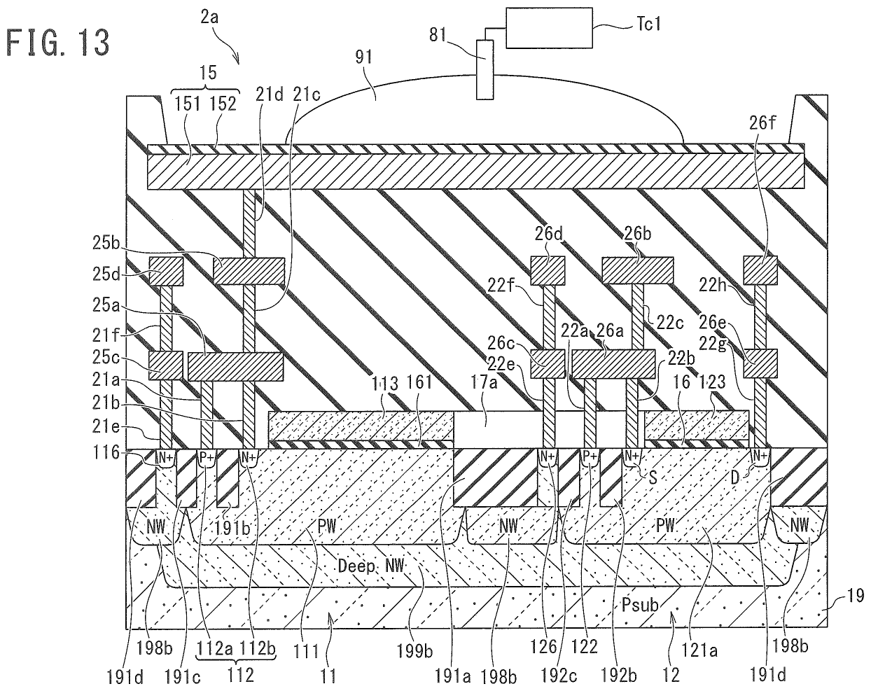

The following describes a chemical sensor according to a modification of the present embodiment with reference to FIG. 13. Upon describing the chemical sensor according to the present modification, the same reference sign as a constituent in the chemical sensor 2 according to the second embodiment is assigned to a constituent having a similar operation and function to those of the constituent in the chemical sensor 2 according to the second embodiment, and descriptions of the constituent are omitted.

As illustrated in FIG. 13, a chemical sensor 2a according to the present modification provides a deep N-well region 199b having the N-type and formed in the semiconductor substrate 19 to surround the P-well region 111 and the P-well region 121 at a position deeper than the P-well region 111 and the P-well region 121, as compared with the chemical sensor 2 according to the above embodiment. Further, the chemical sensor 2a has an N-well region 198b formed around the P-well region 111 and the P-well region 121, as compared with the chemical sensor 2 according to the above embodiment. The N-well region 198b is formed in the deep N-well region 199b. Hereby, the chemical sensor 2a can prevent leakage current from flowing into the semiconductor substrate 19 in response to a voltage being applied to at least one of the P-well region 111 and the P-well region 121, similarly to the chemical sensor 2.

As described above, the chemical sensors according to the present embodiment and the modification can control the threshold voltage of the transistor and achieve improvement in the electric-charge retention characteristic. Further, since the transistor functions as an injection portion and a discharge portion of electric charge, the chemical sensor according to the present embodiment does not provide an electric-charge flow portion. Hereby, the chemical sensor according to the present embodiment can be reduced in size as compared with the chemical sensor 1 according to the first embodiment.

### Third Embodiment

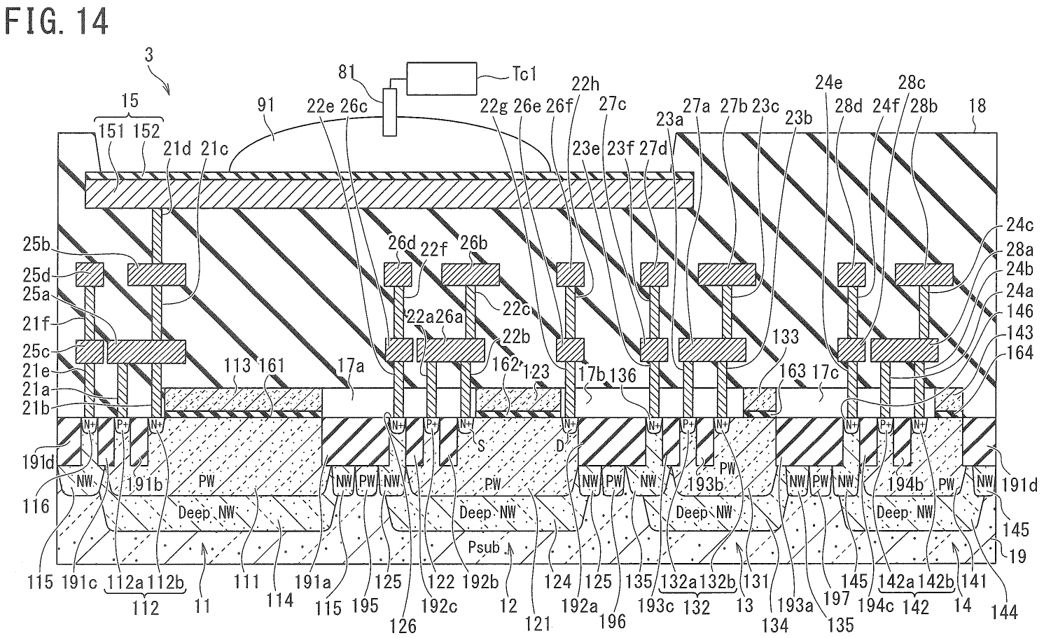

The following describes a chemical sensor according to a third embodiment of the present invention with reference to FIGS. 14 to 19. First described is a schematic configuration of a chemical sensor 3 according to the present embodiment with reference to FIG. 14. Upon describing the chemical sensor according to the present embodiment, the same reference sign as a constituent in the chemical sensor according to the first embodiment is assigned to a constituent having a similar operation and function to those of the constituent in the chemical sensor according to the first embodiment, and descriptions of the constituent are omitted.

<Configuration of Chemical Sensor>

As illustrated in FIG. 14, the chemical sensor 3 according to the present embodiment has a feature in that the chemical sensor 3 provides a second electric-charge flow portion 14 in addition to the configuration of the chemical sensor 1 according to the first embodiment.

As illustrated in FIG. 14, the chemical sensor 3 provides the second electric-charge flow portion 14 through which electric charges are flowable to and from the floating gate 123 in accordance with an applied voltage, and that has at least part formed in the semiconductor substrate 19. Although details are described later, the chemical sensor 3 is configured such that electric charges are injected into the floating gate 123 by use of either of the first electric-charge flow portion 13 and the second electric-charge flow portion 14, and electric charges are discharged from the floating gate 123 by use of the other one of the first electric-charge flow portion 13 and the second electric-charge flow portion 14. Hereby, the chemical sensor 3 can adjust the threshold voltage of the transistor 12.

The second electric-charge flow portion 14 has a P-well region 141 (one example of a third impurity diffused region) formed in the semiconductor substrate 19, and a highly-concentrated impurity diffused region 142 formed in the P-well region 141 and containing impurities at a concentration higher than that in the P-well region 141, and to which a voltage is applied. The P-well region 141 and the highly-concentrated impurity diffused region 142 are formed in the upper part of the semiconductor substrate 19, for example. Further, the P-well region 141 and the highly-concentrated impurity diffused region 142 are formed in the surface layer of the semiconductor substrate 19, for example. The p-well region 141 and the highly-concentrated impurity diffused region 142 correspond to the part formed in the semiconductor substrate. Here, the second impurity diffused region in the present embodiment may have the P-type (one example of the first conductivity type) or the N-type (one example of the second conductivity type) different from the P-type. In the present embodiment, the second impurity diffused region has the P-type.

In the section illustrated in FIG. 14, the highly-concentrated impurity diffused region 142 is placed closer to a central part side of the chemical sensor 3 from a central part of the P-well region 141. The highly-concentrated impurity diffused region 142 has a P+ region 142a and an N+ region 142b. An element isolation layer 194b formed in the P-well region 141 is placed between the P+ region 142a and the N+ region 142b. Hereby, the P+ region 142a and the N+ region 142b do not make direct contact with each other. In the section illustrated in FIG. 14, the P+ region 142a is placed closer to the central part side of the chemical sensor 3 than the N+ region 142b.

The second electric-charge flow portion 14 has an N-well region 145 formed in the semiconductor substrate 19 and having the N-type. The N-well region 145 is formed around the P-well region 141 in a state where the N-well region 145 partially makes contact with the P-well region 141. The N-well region 145 is formed to have generally the same depth as the P-well region 141. The second electric-charge flow portion 14 has an N+ region 146 formed in the N-well region 145. In the section illustrated in FIG. 14, the N+ region 146 is formed closer to the central part side of the chemical sensor 3 in the N-well region 145. An element isolation layer 194c is formed between the N-well region 145 and the P-well region 141. The element isolation layer 194c is also placed between the N+ region 146 and the P+ region 142a. Hereby, the N+ region 146 and the P+ region 142a do not make direct contact with each other.

As illustrated in FIG. 14, the chemical sensor 3 provides a deep N-well region 144 (one example of the fifth impurity diffused region) having the N-type and formed in the semiconductor substrate 19 to surround the P-well region 141 at a position deeper than the P-well region 141. The deep N-well region 144 is formed to cover the lower side of the P-well region 141. Since the deep N-well region 144 is formed to surround the P-well region 141 as such, the chemical sensor 3 can prevent leakage current from flowing into the semiconductor substrate 19 in response to a voltage being applied to the P-well region 141.

The second electric-charge flow portion 14 has a second insulating film 164 formed to make contact with the P-well region 141, and a second floating portion 143 making contact with the second insulating film 164 and formed on the first surface side of the semiconductor substrate 19 in an electrically floating state. The second floating portion 143 is connected to the floating gate 123. The second floating portion 143 is formed on the second insulating film 164. The second floating portion 143 is insulated from the P-well region 141 by the second insulating film 164. The second floating portion 143 has a single layer (that is, one layer) structure, for example. The second floating portion 143 is made of polysilicon, for example.

The second insulating film 164 at least partially has a region with a film thickness of not less than 6 nm but less than 15 nm, for example. In the present embodiment, the second insulating film 164 has the region with a film thickness of not less than 6 nm but less than 15 nm as a whole. The second insulating film 164 may have a film thickness within a range of not less than 6 nm but less than 15 nm as a whole, and an irregular shape may be formed on a surface of the second insulating film 164. Alternatively, the second insulating film 164 may have a uniform film thickness (e.g., a uniform thickness of 6 nm) within a range of not less than 6 nm but less than 15 nm, for example, and the surface of the second insulating film 164 may have a flat shape. When the second insulating film 164 has a film thickness thinner than 6 nm, direct tunneling easily occurs in the second insulating film 164, and the electric-charge retention characteristic (retention characteristic) of the second floating portion 143 worsens. In the meantime, when the second insulating film 164 has a film thickness thicker than 15 nm, injection of electric charges into the second floating portion 143 and discharge of electric charges from the second floating portion 143 become slow. In view of this, when the second insulating film 164 at least partially has the region with a film thickness of not less than 6 nm but less than 15 nm, the chemical sensor 3 can achieve improvement in the electric-charge retention characteristic and improvement in injection speed and discharge speed of electric charges between the second floating portion 143 and the P-well region 141.

The second insulating film 164 is a thermal oxide film, for example. The second insulating film 164 is formed by thermally oxidizing the surface of the semiconductor substrate 19 at high temperature. The control insulating film 161, the gate insulating film 162, the first insulating film 163, and the second insulating film 164 are formed at the same time in the same heat treatment step, for example. The second insulating film 164 is made of a silicon oxide film (SiO₂), a silicon oxynitride film (SiON), or the like, for example. Since the second insulating film 164 is made of a thermal oxide film by high-temperature treatment, it is possible to prevent the occurrence of leakage current in the second electric-charge flow portion 14.

The chemical sensor 3 provides a third connecting portion 17c via which the first floating portion 133 is connected to the second floating portion 143. The third connecting portion 17c has a single layer (that is, one layer) structure, for example. The third connecting portion 17c is made of polysilicon, for example. The third connecting portion 17c is formed on the element isolation layers 193a, 194b and other element isolation layers (not illustrated).

The control floating portion 113, the first connecting portion 17a, the floating gate 123, the second connecting portion 17b, the first floating portion 133, the third connecting portion 17c, and the second floating portion 143 are formed integrally. Accordingly, the floating gate 123, the control floating portion 113, the first floating portion 133, and the second floating portion 143 are formed integrally. The control floating portion 113, the first connecting portion 17a, the floating gate 123, the second connecting portion 17b, the first floating portion 133, the third connecting portion 17c, and the second floating portion 143 are formed on insulating films such as the gate insulating film 162 and element isolation layers such as the element isolation layer 191a and have a comb shape, for example.

As such, the first potential controlling portion 11, the transistor 12, the first electric-charge flow portion 13, and the second electric-charge flow portion 14 are electrically connected to each other via the floating gate 123, the control floating portion 113, the first floating portion 133, and the second floating portion 143, in the upper part of the semiconductor substrate 19. In the meantime, the first potential controlling portion 11, the transistor 12, the first electric-charge flow portion 13, and the second electric-charge flow portion 14 are electrically isolated from each other in the semiconductor substrate 19 by the element isolation layer 191a, the element isolation layer 192a, and the element isolation layer 193a. More specifically, the element isolation layer 193a is formed in the semiconductor substrate 19 between the P-well region 131 provided in the first floating portion 133 and the N-well region 145 provided in the second floating portion 143. Hereby, the element isolation layer 191c electrically isolates the first floating portion 133 from the second floating portion 143 in the semiconductor substrate 19.

Further, the chemical sensor 3 has a P-well region 197 formed in the semiconductor substrate 19 between the N-well region 135 and the N-well region 145. Hereby, the N-well region 135 and the N-well region 145 do not make direct contact with each other. As a result, even when different voltages are applied to the N-well region 135 and the N-well region 145, respective potentials of the N-well region 135 and the N-well region 145 do not interfere with each other.

As illustrated in FIG. 14, the chemical sensor 3 provides plugs 24a, 24b embedded in openings that are formed in the interlayer insulating film 18 and that expose part of the highly-concentrated impurity diffused region 142 to respective bottom faces of the openings, and an intermediate wiring line 28a electrically connected to the plugs 24a, 24b and formed in the interlayer insulating film 18. A first end of the plug 24a is formed to make contact with the P+ region 142a of the highly-concentrated impurity diffused region 142. A first end of the plug 24b is formed to make contact with the N+ region 142b of the highly-concentrated impurity diffused region 142. Silicides are formed on respective surfaces of the P+ region 142a and the N+ region 142b, for example. The plug 24a is formed on the silicide formed on the surface of the P+ region 142a. This is to reduce contact resistance between the plug 24a and the P+ region 142a. The plug 24b is formed on the silicide formed on the surface of the N+ region 142b. This is to reduce contact resistance between the plug 24b and the N+ region 142b. The intermediate wiring line 28a is formed to make contact with a second end of the plug 24a and a second end of the plug 24b. Hereby, the plug 24a and the plug 24b are connected to each other via the intermediate wiring line 28a.

The chemical sensor 3 provides a plug 24c embedded in an opening that are formed in the interlayer insulating film 18 and that exposes part of the intermediate wiring line 28a to a bottom face of the opening, and an intermediate wiring line 28b electrically connected to the plug 24c and formed in the interlayer insulating film 18. A first end of the plug 24c is formed to make contact with the intermediate wiring line 28a. The intermediate wiring line 28b is formed to make contact with a second end of the plug 24c. The intermediate wiring line 28b is connected to an external terminal Tc3 (not illustrated in FIG. 14) via plugs (not illustrated) or intermediate wiring lines (not illustrated). Hereby, a voltage can be applied to the highly-concentrated impurity diffused region 142 via the external terminal Tc3, the intermediate wiring line 28b, the plug 24c, the intermediate wiring line 28a, the plugs 24a, 24b, and so on.

The chemical sensor 3 provides a plug 24e embedded in an opening that are formed in the interlayer insulating film 18 and that exposes part of the N+ region 146 to a bottom face of the opening, and an intermediate wiring line 28d electrically connected to the plug 24e and formed in the interlayer insulating film 18. A first end of the plug 24e is formed to make contact with the N+ region 146. A silicide is formed on a surface of the N+ region 146, for example. The plug 24e is formed on the silicide formed on the surface of the N+ region 146. This is to reduce contact resistance between the plug 24e and the N+ region 146.

The chemical sensor 3 provides a plug 24f embedded in an opening that are formed in the interlayer insulating film 18 and that exposes part of the intermediate wiring line 28c to a bottom face of the opening, and an intermediate wiring line 28d electrically connected to the plug 24f and formed in the interlayer insulating film 18. The intermediate wiring line 28d is formed to make contact with a second end of the plug 24f. The intermediate wiring line 28d is connected to an external terminal Tb4 (not illustrated in FIG. 14) via plugs (not illustrated) or intermediate wiring lines. Hereby, a voltage can be applied to the N+ region 146 via the external terminal Tb4, the intermediate wiring line 28d, the plug 24f, and so on.

<Operation of Chemical Sensor>

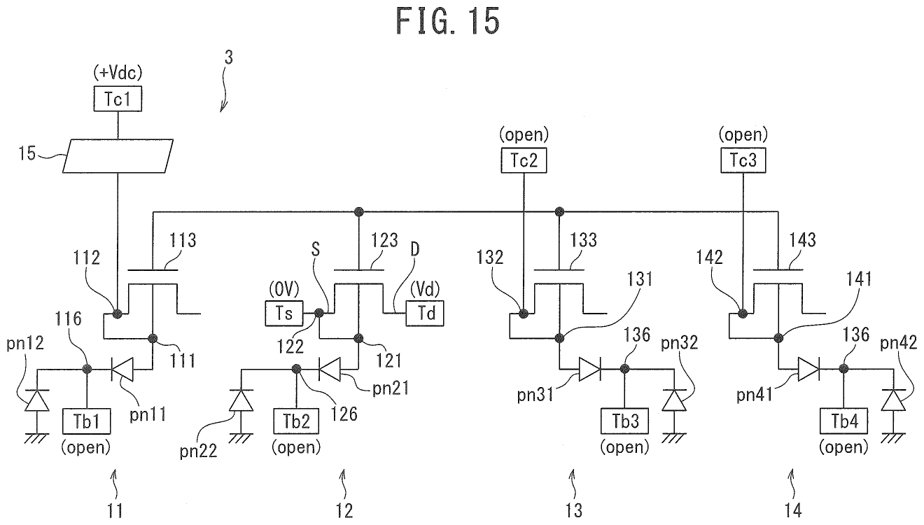

Next will be described the operation of the chemical sensor 3 according to the present embodiment by taking, as an example, a hydrogen-ion concentration sensor, with reference to FIGS. 15 to 17 as well as FIG. 14.

(Equivalent Circuit of Chemical Sensor)

As illustrated in FIG. 15, the first floating portion 133 of the first electric-charge flow portion 13 is connected to the second floating portion 143 of the second electric-charge flow portion 14 via the third connecting portion 17c (not illustrated in FIG. 15, see FIG. 14). The second electric-charge flow portion 14 has the highly-concentrated impurity diffused region 142 placed on one of the both sides of the second floating portion 143. However, the element isolation layer 191d (not illustrated in FIG. 15, see FIG. 14) is placed on the other of the both sides of the second floating portion 143. In view of this, as illustrated in FIG. 15, the second electric-charge flow portion 14 can be expressed by a circuit mark indicative of a field effect transistor (FET) that one of two terminals that corresponds to a source or a drain is the highly-concentrated impurity diffused region 142 and the other of the two terminals is an opened state.

The external terminal Tc3 is connected to the highly-concentrated impurity diffused region 142 of the second electric-charge flow portion 14 via the plugs 24a, 24b (not illustrated in FIG. 15, see FIG. 14) and so on. The highly-concentrated impurity diffused region 142 is connected to the P-well region 141 via the P+ region 142a. Between the P-well region 141 and the N+ region 146, a PN junction pn41 is formed by the P-well region 141, the deep N-well region 144 (not illustrated in FIG. 15, see FIG. 14), the N-well region 145 (not illustrated in FIG. 15, see FIG. 14), and the N+ region 146.

The external terminal Tb4 is connected to the N+ region 146 via the plug 24f (not illustrated in FIG. 15, see FIG. 14) and so on. Between the N+ region 146 and the P-type region of the semiconductor substrate 19 where well regions are not formed, a PN junction pn42 is formed by the N+ region 146, the N-well region 145, the deep N-well region 144, and the P-type region.

(Detection Operation of Chemical Sensor)

As illustrated in FIG. 15, in a case where the chemical sensor 3 detects the hydrogen-ion concentration or the like of the test sample 91, a positive direct voltage Vdc is input into the input terminal Tc1 as a reference voltage. Further, in this case, in the chemical sensor 3, a voltage of zero volts (V) is input into the source S of the transistor 12, and a voltage as a drain voltage Vd (e.g., 0.1 V) is input into the drain D of the transistor 12. Further, in this case, in the chemical sensor 3, the external terminals Tb1, Tb2, Tb3, Tb4, Tc2, Tc3 are brought into an opened state.

Hereby, a gate voltage obtained by adding an interface voltage on the sensitive membrane 152 to the direct voltage Vdc is applied to the floating gate 123 of the transistor 12 via the sensitive portion 15 and the first potential controlling portion 11. Further, respective voltages described above are input into the source S and the drain D of the transistor 12. Hereby, the transistor 12 operates. Since the interface voltage of the sensitive membrane 152 changes in accordance with the hydrogen-ion concentration of the test sample 91, a gate voltage on which the hydrogen-ion concentration of the test sample 91 is reflected is applied to the floating gate 123 of the transistor 12. As a result, a drain current on which the hydrogen-ion concentration of the test sample 91 is reflected flows through the transistor 12. Hereby, the chemical sensor 3 can detect the hydrogen-ion concentration of the test sample 91.

(Adjustment Operation of Threshold Voltage of Transistor in Chemical Sensor)

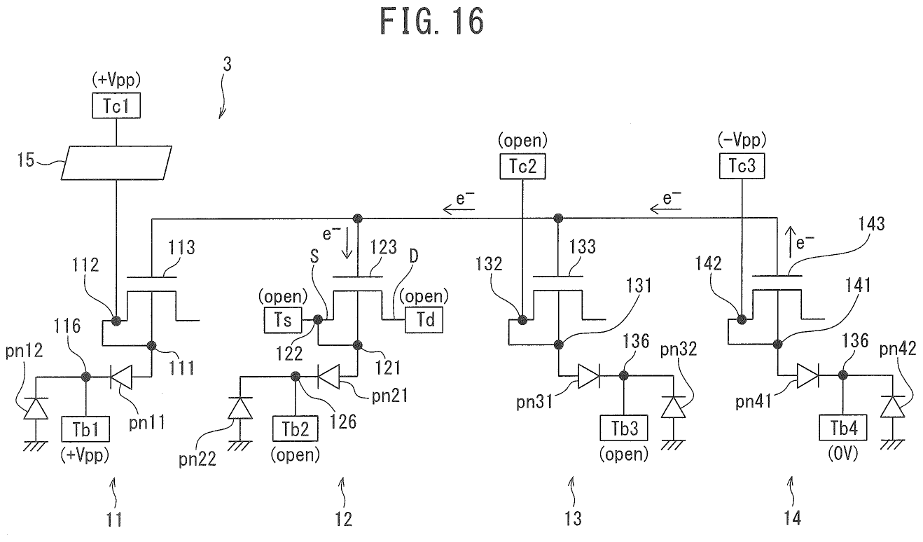

With reference to FIG. 16, the following describes an operation to adjust the threshold voltage to bring the transistor 12 provided in the chemical sensor 3 into the enhancement state by injecting electric charges into the floating gate 123.

As illustrated in FIG. 16, in the operation to adjust the threshold voltage to bring the transistor 12 provided in the chemical sensor 3 into the enhancement state, a reference sample used for adjustment of the threshold voltage of the transistor 12 is placed on the sensitive portion 15. In the adjustment operation on the threshold voltage, in the chemical sensor 3, a pulse voltage of which the voltage value is inverted from 0 V to +Vpp is input into the input terminal Tc1 as the reference voltage. The reference voltage is applied to the second floating portion 143 via the reference sample, the sensitive portion 15, the control floating portion 113 of the first potential controlling portion 11, the first connecting portion 17a, the floating gate 123 of the transistor 12, the second connecting portion 17b, the first floating portion 133, and the third connecting portion 17c. Further, in the case of the adjustment operation on the threshold voltage, in the chemical sensor 3, the same pulse voltage as the input terminal Tc1 is applied to the external terminal Tb1. Further, in the case of the adjustment operation on the threshold voltage, in the chemical sensor 3, the external terminal Ts connected to the source S of the transistor 12 and the external terminal Td connected to the drain D are brought into an opened state. Further, in the case of the adjustment operation of the threshold voltage, in the chemical sensor 3, a pulse voltage of which the voltage value is inverted from 0 V to −Vpp is input into the external terminal Tc3 of the second electric-charge flow portion 14, and a voltage of 0 V is input into the external terminal Tb4 of the second electric-charge flow portion 14 (the external terminal Tb4 is connected to the ground, for example). Furthermore, in the case of the adjustment operation on the threshold voltage, in the chemical sensor 3, a voltage of 0 V is input into the external terminal Tc2 and the external terminal Tb3 of the first electric-charge flow portion 13 (the external terminal Tc2 and the external terminal Tb3 are connected to the ground, for example).

Hereby, FN tunneling occurs in the second insulating film 164, and as indicated by straight arrows in FIG. 16, electrons e− are injected into the floating gate 123 from the P-well region 141 of the second electric-charge flow portion 14 through the second insulating film 164, the second floating portion 143, the third connecting portion 17c, the first floating portion 133, and the second connecting portion 17b. Hereby, the threshold voltage of the transistor 12 increases. The threshold voltage of the transistor 12 is checked by a method similar to the detection operation of the chemical sensor 3 as described with reference to FIG. 15. The injection of the electrons e− into the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished.

Although not illustrated herein, in the chemical sensor 3, the threshold voltage of the transistor 12 can be adjusted by an operation similar to the second operation to adjust the threshold voltage to bring the transistor 12 provided in the chemical sensor 1 according to the first embodiment into the enhancement state. In this case, the first potential controlling portion 11 and the transistor 12 in the present embodiment are operated in respective states similar to those of the first potential controlling portion 11 and the transistor 12 in the second operation in the first embodiment. Further, a pulse voltage of which the voltage value is inverted from 0 V to −Vpp is input into the external terminal Tc3 of the second electric-charge flow portion 14 in the present embodiment, and a voltage of 0 V is input into the external terminal Tb4 of the second electric-charge flow portion 14 (the external terminal Tb4 is connected to the ground, for example). Further, the external terminal Tc2 and the external terminal Tb3 of the first electric-charge flow portion 13 in the present embodiment are brought into an opened state. Hereby, the chemical sensor 3 can inject electrons e− into the floating gate 123 via the second electric-charge flow portion 14. Note that, in a case where electric charges are injected into the floating gate 123 by the operation, the capacitance in the floating gate 123 should be larger than the capacitance in the second floating portion 143. This configuration has an effect to efficiently transmit a voltage input into the floating gate 123 to the second floating portion 143, in comparison with a configuration in which the capacitance in the floating gate 123 is smaller than the capacitance in the second floating portion 143. As a result, the efficiency of the adjustment of the threshold voltage can be improved.

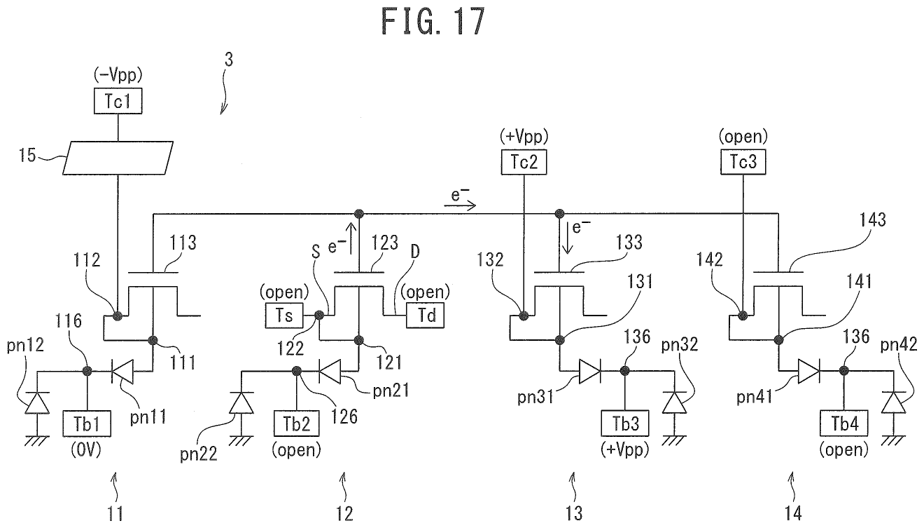

With reference to FIG. 17, the following describes an operation to adjust the threshold voltage to bring the transistor 12 included in the chemical sensor 3 into the depression state by discharging electric charges from the floating gate 123.

As illustrated in FIG. 17, in the operation to adjust the threshold voltage to bring the transistor 12 provided in the chemical sensor 3 into the depression state, a reference sample used for adjustment of the threshold voltage of the transistor 12 is placed on the sensitive portion 15. In the adjustment operation on the threshold voltage, in the chemical sensor 3, a pulse voltage of which the voltage value is inverted from 0 V to −Vpp is input into the input terminal Tc1 as the reference voltage. The reference voltage is applied to the first floating portion 133 via the reference sample, the sensitive portion 15, the control floating portion 113 of the first potential controlling portion 11, and the first connecting portion 17a. Further, in the case of the adjustment operation on the threshold voltage, in the chemical sensor 3, a voltage of 0 V is input into the external terminal Tb1 (the external terminal Tb1 is connected to the ground, for example). Further, in the case of the adjustment operation of the threshold voltage, in the chemical sensor 3, the source S and the drain D of the transistor 12 are brought into an opened state. Furthermore, in the case of the adjustment operation of the threshold voltage, in the chemical sensor 3, a pulse voltage of which the voltage value is inverted from 0 V to +Vpp is input into the external terminal Tc2 and the external terminal Tb3 of the first electric-charge flow portion 13. Furthermore, in the case of the adjustment operation on the threshold voltage, in the chemical sensor 3, the external terminal Tc3 and the external terminal Tb4 of the second electric-charge flow portion 14 are brought into an opened state.

Hereby, FN tunneling occurs in the first insulating film 163, and as indicated by straight arrows in FIG. 17, electrons e− are discharged from the floating gate 123 to the P-well region 131 through the second connecting portion 17b, the first floating portion 133, and the first insulating film 163. Hereby, the threshold voltage of the transistor 12 decreases. The threshold voltage of the transistor 12 is checked by a method similar to the detection operation of the chemical sensor 3 as described with reference to FIG. 15. The discharge of the electrons e− from the floating gate 123 and the check of the threshold voltage of the transistor 12 are repeatedly executed until the transistor 12 reaches its desired threshold voltage. When the transistor 12 reaches the desired threshold voltage, the voltage application of the pulse voltage and so on is finished. Hereby, the adjustment operation on the threshold voltage of the transistor 12 is finished.

Although not illustrated herein, in the chemical sensor 3, the threshold voltage of the transistor 12 can be adjusted by an operation similar to the second operation to adjust the threshold voltage to bring the transistor 12 provided in the chemical sensor 1 according to the first embodiment into the depression state. In this case, the first potential controlling portion 11, the transistor 12, and the first electric-charge flow portion 13 in the present embodiment are operated in respective states similar to those of the first potential controlling portion 11, the transistor 12, and the first electric-charge flow portion 13 in the second operation in the first embodiment. Further, the external terminal Tc3 and the external terminal Tb4 of the second electric-charge flow portion 14 in the present embodiment are brought into an opened state. Hereby, the chemical sensor 3 can discharge electrons e− from the floating gate 123 via the first electric-charge flow portion 13. Note that, in a case where electric charges are discharged from the floating gate 123 by the operation, the capacitance in the floating gate 123 should be larger than the capacitance in the control floating portion 113. This configuration has an effect to efficiently transmit a voltage input into the floating gate 123 to the control floating portion 113, in comparison with a configuration in which the capacitance in the floating gate 123 is smaller than the capacitance in the control floating portion 113. As a result, the efficiency of the adjustment of the threshold voltage can be improved.

As such, in the chemical sensor 3 according to the present embodiment, the first electric-charge flow portion 13 is used to discharge electric charges (electrons in the present embodiment) from the floating gate 123, and the second electric-charge flow portion 14 is used to inject electric charges (electrons in the present embodiment) into the floating gate 123. In the chemical sensor 3, the second electric-charge flow portion 14 may be used to discharge electric charges (electrons in the present embodiment) from the floating gate 123, and the first electric-charge flow portion 13 is used to inject electric charges (electrons in the present embodiment) into the floating gate 123. Since different paths are used for a path where electric charges are discharged from the floating gate 123 and for a path where electric charges are injected into the floating gate 123 as such, the amount of electric charge passing through the first insulating film 163 provided in the first electric-charge flow portion 13 and the second insulating film 164 provided in the second electric-charge flow portion 14 can be decreased. Hereby, the chemical sensor 3 can restrain deterioration of the first insulating film 163 and the second insulating film 164 and achieve improvement in the electric-charge retention characteristics of the floating gate 123, the control floating portion 113, the first floating portion 133, and the second floating portion 143.

<Modifications>

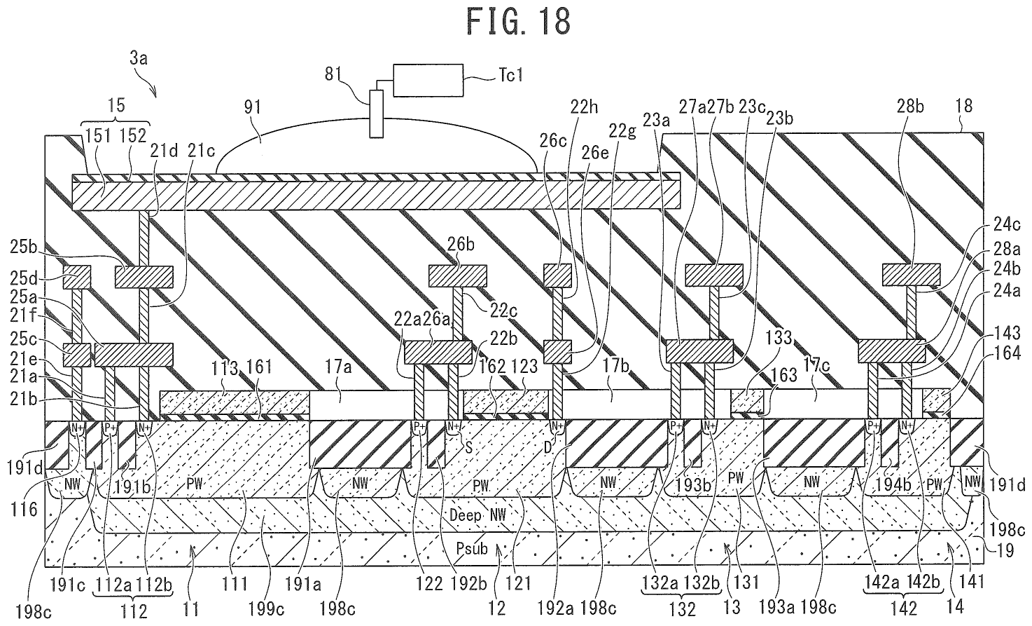

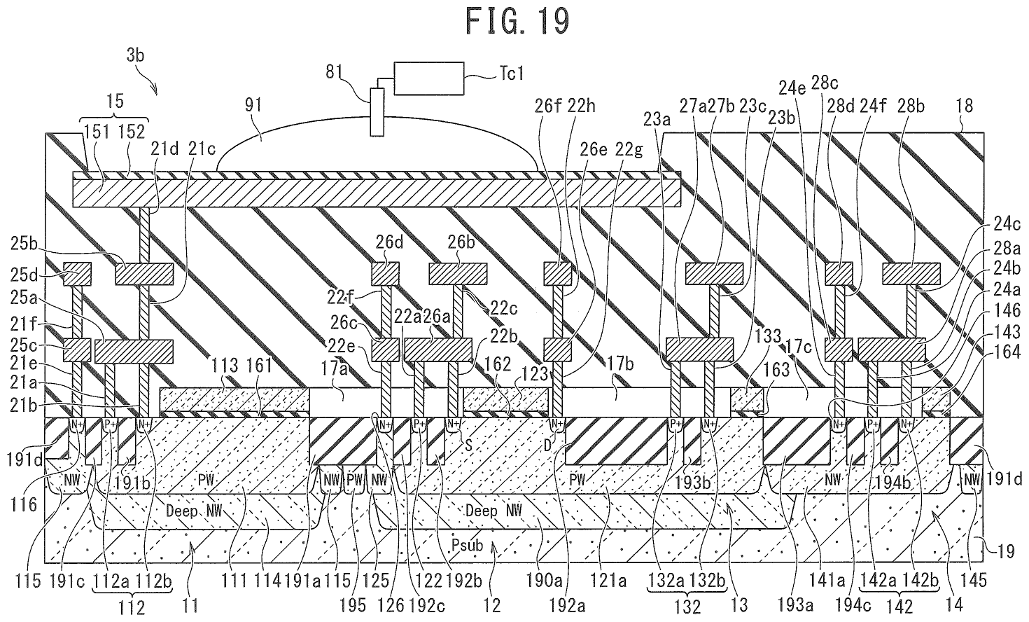

The following describes chemical sensors according to modifications of the present embodiment with reference to FIGS. 18 and 19. Upon describing the chemical sensors according to the modifications, the same reference sign as a constituent in the chemical sensor 3 according to the present embodiment is assigned to a constituent having a similar operation and function to those of the constituent in the chemical sensor 3 according to the third embodiment, and descriptions of the constituent are omitted.

(Modification 1)

As illustrated in FIG. 18, a chemical sensor 3a according to Modification 1 of the present embodiment does not have the N+ regions 126, 136, 146, the plugs 22e, 22f, 23e, 23f, 24e, 24f, and the intermediate wiring lines 26c, 26d, 27c, 27d, 28c, 28d, as compared with the chemical sensor 3 according to the third embodiment. Further, the chemical sensor 3a has N-well regions 198c instead of the N-well regions 115, 125 and the P-well region 195, and N-well regions 198c instead of the N-well regions 135, 145 and the P-well region 197, as compared with the chemical sensor 3 according to the third embodiment. The N-well regions 198c are placed right under the element isolation layers 191a, 192a, 193a.

The chemical sensor 3a provides a deep N-well region 199c having the N-type and formed in the semiconductor substrate 19 to surround the P-well region 111, the P-well region 121, the P-well region 131, and the P-well region 141 at a position deeper than the P-well region 111, the P-well region 121, the P-well region 131, and the P-well region 141. Further, the chemical sensor 3a has the N-well region 198c formed around the P-well region 111, the P-well region 121, the P-well region 131, and the P-well region 141. The N-well regions 198c placed right under the element isolation layers 191a, 192a, 193a are formed in the deep N-well region 199c. Hereby, the chemical sensor 3a can prevent leakage current from flowing into the semiconductor substrate 19 in response to a voltage being applied to at least one of the P-well region 111, the P-well region 121, the P-well region 131, and the P-well region 141, similarly to the chemical sensor 3.

(Modification 2)

As illustrated in FIG. 19, a chemical sensor 3b according to Modification 2 of the present embodiment does not have the N+ region 136, the plugs 23e, 23f, and the intermediate wiring lines 27c, 27d, as compared with the chemical sensor 3 according to the third embodiment. Further, the chemical sensor 3b has the P-well region 121a instead of the P-well regions 121, 131, as compared with the chemical sensor 3 according to the third embodiment. The P-well region 121a is formed continuously over the transistor 12 and the first electric-charge flow portion 13.

Further, the chemical sensor 3b has a deep N-well region 190a instead of the deep N-well regions 124, 134, as compared with the chemical sensor 3 according to the third embodiment. The deep N-well region 190a is formed continuously over the transistor 12 and the first electric-charge flow portion 13. The P-well region 121a is formed in the deep N-well region 190a. Further, the chemical sensor 3b has an N-well region 141a instead of the N-well regions 135, 145 and the P-well region 197, 141 in the second electric-charge flow portion 14, as compared with the chemical sensor 3 according to the third embodiment. Further, the chemical sensor 3b has the deep N-well region 190a, as compared with the chemical sensor 3 according to the third embodiment. Thus, the second electric-charge flow portion 14 in the present modification has the N-well region 141a (one example of the third impurity diffused region) formed in the semiconductor substrate 19. The N-well region 141a in the present modification may have the P-type (one example of the first conductivity type) or the N-type (one example of the second conductivity type) different from the P-type. In the present modification, the N-well region 141a has the N-type.

In the chemical sensor 3b according to the present modification, the first electric-charge flow portion 13 is used to inject electric charges (electrons in the present embodiment) into the floating gate 123, and the second electric-charge flow portion 14 is used to discharge electric charges (electrons in the present embodiment) from the floating gate 123. On this account, when electric charges are discharged from the floating gate 123, a positive pulse voltage is applied to the N-well region 141a of the second electric-charge flow portion 14, and the P-type region (the region indicated by “Psub” in FIG. 19) of the semiconductor substrate 19 where well regions are not formed is connected to the ground, for example. Hereby, when electric charges are discharged from the floating gate 123, a reverse bias is applied to the N-well region 141a and the P-type region. Accordingly, leakage current can be hardly caused. Further, the N-well region 141a of the second electric-charge flow portion 14 is brought into an opened state except for a state where electric charges are discharged from the floating gate 123. Further, the P-well region 111 is surrounded by the deep N-well region 114, and the P-well region 121a is surrounded by the deep N-well region 190a.

Hereby, the chemical sensor 3b of the present modification can prevent leakage current from flowing into the semiconductor substrate 19 in response to a voltage being applied to at least one of the P-well region 111, the P-well region 121, the P-well region 131, and the N-well region 141a, similarly to the chemical sensor 3.

As described above, the chemical sensors according to the present embodiment and the modifications can control the threshold voltage of the transistor and achieve improvement in the electric-charge retention characteristic. Further, the chemical sensor according to the present embodiment provides an electric-charge flow portion for exclusive use of discharging electrons from the floating gate, and an electric-charge flow portion for exclusive use of injecting electrons into the floating gate. Hereby, the chemical sensors according to the present embodiment and the modifications can restrain deterioration of the insulating films and achieve improvement in the electric-charge retention characteristics of the floating gate and the floating portions.

### Fourth Embodiment

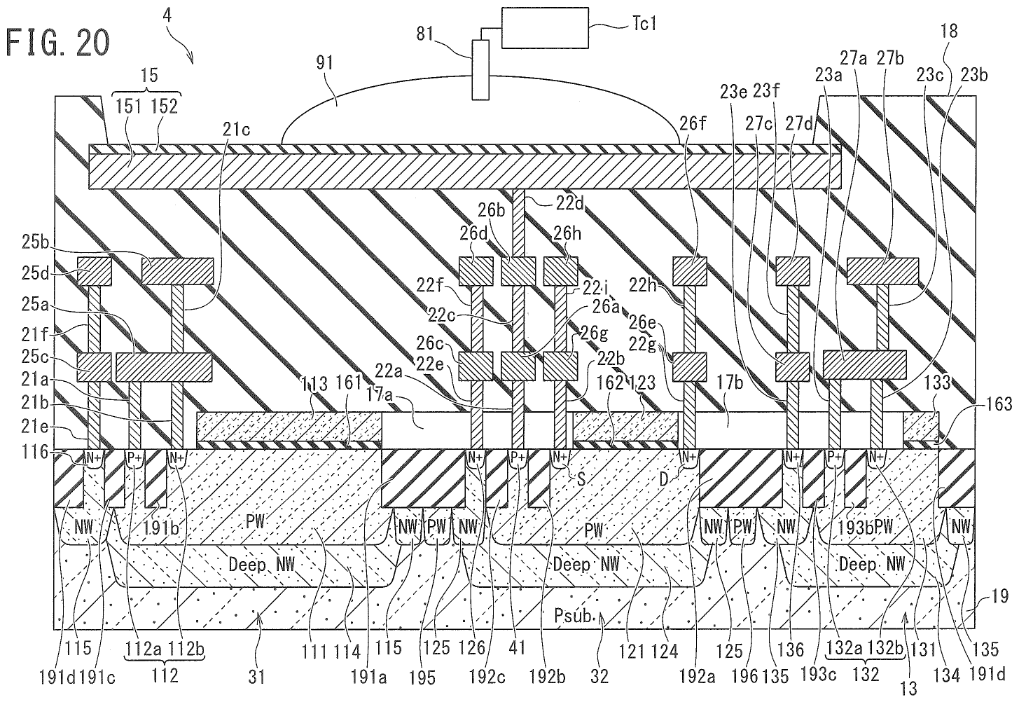

The following describes a chemical sensor according to a fourth embodiment of the present invention with reference to FIGS. 20 to 23. First described is a schematic configuration of a chemical sensor 4 according to the present embodiment with reference to FIG. 20. Upon describing the chemical sensor according to the present embodiment, the same reference sign as a constituent in the chemical sensor 1 according to the first embodiment is assigned to a constituent having a similar operation and function to those of the constituent in the chemical sensor 1 according to the first embodiment, and descriptions of the constituent are omitted.

<Configuration of Chemical Sensor>

As illustrated in FIG. 20, the chemical sensor 4 according to the present embodiment provides the semiconductor substrate 19 constituted by a P-type silicone substrate, for example, and the sensitive portion 15 placed on the semiconductor substrate 19 and having the sensitive membrane 152 sensitive to a chemical substance. Further, the sensitive portion 15 in the present embodiment has the same configuration as the sensitive portion 15 in the first embodiment.

Further, the chemical sensor 4 provides a transistor 32 having the floating gate 123 and the gate insulating film 162 formed to make contact with the floating gate 123. The floating gate 123 is placed on the first surface side of the semiconductor substrate 19 in an electrically floating state. The transistor 32 functions as an ISFET in the chemical sensor 4. Further, the chemical sensor 4 provides a first potential controlling portion 41 configured to control the potential of the floating gate 123 in accordance with a voltage applied to the sensitive membrane 152. The first potential controlling portion 41 has at least part formed in the semiconductor substrate 19 and is connected to the sensitive portion 15. Further, the chemical sensor 4 provides a second potential controlling portion 31 having at least part formed in the semiconductor substrate 19 and configured to control the potential of the floating gate 123. The second potential controlling portion 31 is configured to control the potential of the floating gate 123 to adjust the threshold voltage of the transistor 32, for example. Further, the chemical sensor 4 provides the first electric-charge flow portion 13 through which electric charges are flowable to and from the floating gate 123 in accordance with an applied voltage and that has at least part formed in the semiconductor substrate 19.

As illustrated in FIG. 20, the second potential controlling portion 31 has a configuration similar to that of the first potential controlling portion 11 in the first embodiment except that the second potential controlling portion 31 is not connected to the sensitive portion 15. On this account, the same reference sign as a constituent of the first potential controlling portion 11 is assigned to a constituent of the second potential controlling portion 31 that has a similar operation and function to those of the constituent of the first potential controlling portion 11, and detailed descriptions are omitted.

The second potential controlling portion 31 has the P-well region 111 (one example of a sixth impurity diffused region) formed in the semiconductor substrate 19 and having the P-type, and the highly-concentrated impurity diffused region 112 formed in the P-well region 111 and containing impurities at a concentration higher than that in the P-well region 111. Further, the second potential controlling portion 31 has the control floating portion 113 insulated from the P-well region 111 and formed on the first surface side of the semiconductor substrate 19 in an electrically floating state. The control floating portion 113 is connected to the floating gate 123.

The second potential controlling portion 31 is used to apply a pulse voltage to the floating gate 123 at the time when the threshold voltage of the transistor 32 is to be adjusted. Furthermore, the second potential controlling portion 31 is used to apply a direct voltage to the floating gate 123 to operate the transistor 32 at the time when the ion concentration and so on of the test sample are to be detected.

An external terminal Tc6 (not illustrated in FIG. 20) is connected to the highly-concentrated impurity diffused region 112 provided in the second potential controlling portion 31 via the plugs 21a, 21b, the intermediate wiring line 25a, the plug 21c, and the intermediate wiring line 25b, but the sensitive portion 15 is not connected to the highly-concentrated impurity diffused region 112. The direct voltage and the pulse voltage to be applied to the floating gate 123 of the transistor 32 by the second potential controlling portion 31 are input into the external terminal Tc6.

As illustrated in FIG. 20, the transistor 32 in the present embodiment has a configuration similar to that of the transistor 12 in the first embodiment except that the transistor 32 is connected to the sensitive portion 15. On this account, the same reference sign as a constituent of the transistor 12 is assigned to a constituent of the transistor 32 that has a similar operation and function to those of the constituent of the transistor 12, and detailed descriptions of the constituent are omitted.

The chemical sensor 4 provides the plug 22b embedded in an opening that is formed in the interlayer insulating film 18 and that exposes part of the source S to the bottom face of the opening, and an intermediate wiring line 26g electrically connected to the plug 22b and formed in the interlayer insulating film 18. A first end of the plug 22b is formed to make contact with the source S. A silicide is formed on a surface of the source S, for example. The plug 22b is formed on the silicide formed on the surface of the source S. This is to reduce contact resistance between the plug 22b and the source S. The intermediate wiring line 26g is formed to make contact with a second end of the plug 22b.

The chemical sensor 4 provides a plug 22i embedded in an opening is that formed in the interlayer insulating film 18 and that exposes part of the intermediate wiring line 26g to a bottom face of the opening, and an intermediate wiring line 26h electrically connected to the plug 22i and formed in the interlayer insulating film 18. A first end of the plug 22i is formed to make contact with the intermediate wiring line 26g. The intermediate wiring line 26h is formed to make contact with a second end of the plug 22i. The intermediate wiring line 26h is connected to the external terminal Ts (not illustrated in FIG. 20) via plugs or intermediate wiring lines (not illustrated). Hereby, a voltage can be applied to the source S and the P-well region 121 via the external terminal Ts, the intermediate wiring line 26h, the plug 22i, the intermediate wiring line 26g, the plug 22b, and so on.

As illustrated in FIG. 20, the first potential controlling portion 41 provided in the chemical sensor 4 has the P-type, contains impurities at a concentration higher than that in the P-well region 121, is formed in the P-well region 121. The first potential controlling portion 41 is constituted by a P+ region. As such, the first potential controlling portion 41 has part formed in the semiconductor substrate 19 (in the present embodiment, a whole of the first potential controlling portion 41 is formed in the semiconductor substrate 19). The first potential controlling portion 41 is formed in the upper part of the semiconductor substrate 19, for example. Further, the first potential controlling portion 41 is formed in the surface layer of the semiconductor substrate 19, for example.

The transistor 32 is connected to the sensitive portion 15 via the first potential controlling portion 41. The first potential controlling portion 41 is connected to the sensitive portion 15 via the plug 22a, the intermediate wiring line 26a, the plug 22c, the intermediate wiring line 26b, and a plug 22d.

More specifically, the chemical sensor 4 provides the plug 22a embedded in an opening that is formed in the interlayer insulating film 18 and that exposes part of the first potential controlling portion 41 to the bottom face of the opening, and the intermediate wiring line 26a electrically connected to the plug 22a and formed in the interlayer insulating film 18. The first end of the plug 22a is formed to make contact with the P+ region constituting the first potential controlling portion 41. A silicide is formed on a surface of the P+ region constituting the first potential controlling portion 41, for example. The plug 22a is formed on the silicide formed on the surface of the P+ region constituting the first potential controlling portion 41. This accordingly achieves a reduction in contact resistance between the plug 22a and the P+ region constituting the first potential controlling portion 41. The intermediate wiring line 26a makes contact with the second end of the plug 22a.

The chemical sensor 4 provides the plug 22c embedded in an opening that is formed in the interlayer insulating film 18 and that exposes part of the intermediate wiring line 26a on the bottom face of the opening, and the intermediate wiring line 26b electrically connected to the plug 22c and formed in the interlayer insulating film 18. The first end of the plug 22c is formed to make contact with the intermediate wiring line 26a. The intermediate wiring line 26b is formed to make contact with the second end of the plug 22c.

The chemical sensor 4 provides the plug 22d embedded in an opening that is formed in the interlayer insulating film 18 and that exposes part of the intermediate wiring line 26b to a bottom face of the opening. A first end of the plug 22d is formed to make contact with the intermediate wiring line 26b. A second end of the plug 22d is formed to make contact with the conductive portion 151 provided in the sensitive portion 15. Hereby, the plug 22d is electrically connected to the conductive portion 151. Accordingly, the conductive portion 151 is connected to the first potential controlling portion 41 via the plug 22d, the intermediate wiring line 26b, the plug 22c, the intermediate wiring line 26a, and the plug 22a.

As such, the sensitive portion 15 has the conductive portion 151 connected to the first potential controlling portion 41, and the sensitive membrane 152 formed on the first surface side of the conductive portion 151 such that a chemical substance makes contact with the sensitive membrane 152. Here, the first surface out of the both surfaces of the conductive portion 151 is a surface where the sensitive membrane 152 is formed, and the second surface out of the both surfaces is a surface facing the semiconductor substrate 19. That is, the sensitive membrane 152 is provided to make contact with a surface, out of the both surfaces of the conductive portion 151, that does not face the semiconductor substrate 19.

Although details are described later, the chemical sensor 4 can apply, to the P-well region 121, a voltage to which an interface voltage on the sensitive membrane 152 is added to a reference voltage input into the input terminal Tc1 and apply a gate voltage having a predetermined potential to the floating gate 123 of the transistor 32 via the second potential controlling portion 31. On this account, the threshold voltage of the transistor 32 changes based on the concentration of the test sample 91 due to a substrate bias effect. Thus, the chemical sensor 4 can detect the concentration of the test sample 91 based on the fluctuation in the threshold voltage of the transistor 12 due to the substrate bias effect.

<Operation of Chemical Sensor>

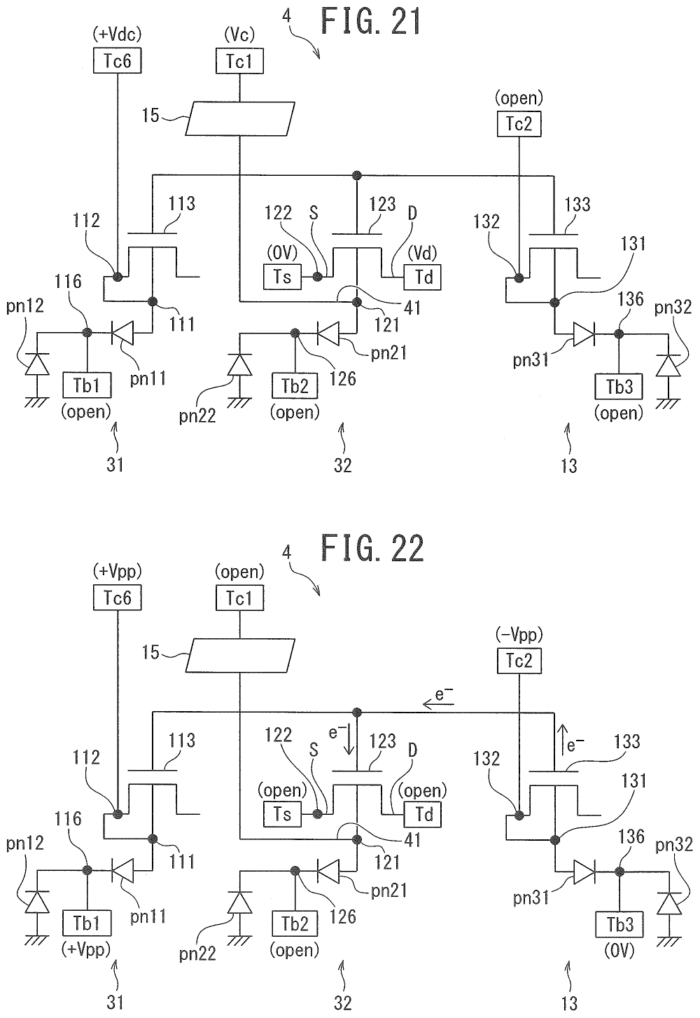

Next will be described the detection operation of the chemical sensor 4 according to the present embodiment by taking, as an example, a hydrogen-ion concentration sensor, with FIGS. 21 to 23. Upon describing the detection operation of the chemical sensor 4, an equivalent circuit of the chemical sensor 4 will be described first with reference to FIG. 21.

(Equivalent Circuit of Chemical Sensor)

The second potential controlling portion 31 has a configuration similar to that of the first potential controlling portion 11 except that the second potential controlling portion 31 is not connected to the sensitive portion 15. On this account, the second potential controlling portion 31 can be expressed by a circuit mark indicative of a field effect transistor (FET) that one of two terminals that corresponds to a source or a drain is the highly-concentrated impurity diffused region 112 and the other of the two terminals is an opened state.

As illustrated in FIG. 21, the external terminal Tc6 is connected to the highly-concentrated impurity diffused region 112 of the second potential controlling portion 31 via the plugs 21a, 21b (not illustrated in FIG. 21, see FIG. 20) and so on. The second potential controlling portion 31 can be expressed by an equivalent circuit similar to that of the first potential controlling portion 11 in the first embodiment except that the external terminal Tc6 is connected to the highly-concentrated impurity diffused region 112.

As illustrated in FIG. 21, the first potential controlling portion 41 is connected to the P-well region 121 of the transistor 32. The input terminal Tc1 for the reference voltage is connected to the first potential controlling portion 41 via the plug 22a (not illustrated in FIG. 21, see FIG. 20) and so on, the sensitive portion 15, and the reference electrode 81 (not illustrated in FIG. 21, see FIG. 20). The transistor 32 can be expressed by an equivalent circuit similar to that of the transistor 12 in the first embodiment except that the P-well region 121 is connected to the sensitive portion 15.

(Detection Operation of Chemical Sensor)

As illustrated in FIG. 21, in a case where the chemical sensor 4 detects the hydrogen-ion concentration or the like of the test sample 91, a positive direct voltage Vdc is input into the input terminal Tc6. Further, in this case, in the chemical sensor 4, a direct reference voltage having a voltage value of Vc is input into the input terminal Tc1. Further, in this case, in the chemical sensor 4, a voltage of zero volts (V) is input into the external terminal Ts connected to the source S of the transistor 32, and a voltage as a drain voltage Vd (e.g., 0.1 V) is input into the external terminal Td connected to the drain D of the transistor 32. Further, in this case, in the chemical sensor 4, the external terminals Tb1, Tb2, Tb3, Tc2 are brought into an opened state.

Hereby, the direct voltage Vdc is applied to the floating gate 123 of the transistor 32 via the second potential controlling portion 31, and a voltage obtained by adding the interface voltage on the sensitive membrane 152 to the reference voltage is applied to the P-well region 121 of the transistor 32 via the first potential controlling portion 41. Further, respective voltages described above are input into the source S and the drain D of the transistor 32. The transistor 32 hereby operates in a state where a back bias is applied to the transistor 32. Since the interface voltage of the sensitive membrane 152 changes in accordance with the hydrogen-ion concentration of the test sample 91, a voltage on which the hydrogen-ion concentration of the test sample 91 is reflected is applied to the P-well region 121 of the transistor 32. As a result, a drain current on which the hydrogen-ion concentration of the test sample 91 is reflected flows through the transistor 32 due to the substrate bias effect. Hereby, the chemical sensor 4 can detect the hydrogen-ion concentration of the test sample 91.

(Adjustment Operation of Threshold Voltage of Transistor in Chemical Sensor)

With reference to FIG. 22, the following describes an operation to adjust the threshold voltage to bring the transistor 32 provided in the chemical sensor 4 into the enhancement state by injecting electric charges into the floating gate 123.

As illustrated in FIG. 22, in the operation to adjust the threshold voltage to bring the transistor 32 into the enhancement state, in the chemical sensor 4, a pulse voltage of which the voltage value is inverted from 0 V to +Vpp is input into the external terminal Tc6. The pulse voltage is applied to the first floating portion 133 via the intermediate wiring lines 25a, 25b, the plugs 21b, 21c, the highly-concentrated impurity diffused region 112, the P-well region 111, the control floating portion 113, the first connecting portion 17a, the floating gate 123 of the transistor 32, and the second connecting portion 17b. Further, in the case of the adjustment operation on the threshold voltage, in the chemical sensor 4, the same pulse voltage as the external terminal Tc6 is applied to the external terminal Tb1. Further, in the case of the adjustment operation on the threshold voltage, in the chemical sensor 4, the input terminal Tc1, the external terminal Ts connected to the source S of the transistor 32, the external terminal Td connected to the drain D, and the external terminal Tb2 are brought into an opened state. Further, in the case of the adjustment operation on the threshold voltage, in the chemical sensor 4, a pulse voltage of which the voltage value is inverted from 0 V to −Vpp is input into the external terminal Tc2 of the first electric-charge flow portion 13, and a voltage of 0 V is input into the external terminal Tb3 of the first electric-charge flow portion 13 (the external terminal Tb3 is connected to the ground, for example).

Hereby, FN tunneling occurs in the first insulating film 163, and as indicated by straight arrows in FIG. 22, electrons e− are injected into the floating gate 123 from the P-well region 131 of the first electric-charge flow portion 13 through the first insulating film 163, the first floating portion 133, and the second connecting portion 17b. Hereby, the threshold voltage of the transistor 32 increases. The threshold voltage of the transistor 32 is checked by a method similar to the detection operation of the chemical sensor 4 as described with reference to FIG. 21. The injection of the electrons e− into the floating gate 123 and the check of the threshold voltage of the transistor 32 are repeatedly executed until the transistor 32 reaches its desired threshold voltage. When the transistor 32 reaches the desired threshold voltage, the voltage application of the pulse voltage and so on is finished. Hereby, the adjustment operation on the threshold voltage of the transistor 32 is finished. Note that, in a case where electric charges are injected into the floating gate 123 by the operation, the capacitance in the second potential controlling portion 31 should be larger than the capacitance in the first floating portion 133. This configuration has an effect to efficiently transmit a voltage input into the second potential controlling portion 31 to the first floating portion 133, in comparison with a configuration in which the capacitance in the second potential controlling portion 31 is smaller than the capacitance in the first floating portion 133. As a result, the efficiency of the adjustment of the threshold voltage can be improved.

Although not illustrated herein, in the chemical sensor 4, the threshold voltage of the transistor 32 can be adjusted by an operation similar to the second operation to adjust the threshold voltage to bring the transistor 12 in the chemical sensor 1 according to the first embodiment into the enhancement state. In this case, a pulse voltage of which the voltage value is inverted from 0 V to +Vpp is input into the input terminal Tc1 as the reference voltage. The reference voltage is applied to the P-well region 121 via the reference sample, the sensitive portion 15, and the first potential controlling portion 41. Further, the same pulse voltage as the pulse voltage input into the input terminal Tc1 is applied to the source S and the drain D of the transistor 32 and the external terminal Tb2. Further, a pulse voltage of which the voltage value is inverted from 0 V to −Vpp is input into the external terminal Tc2 of the first electric-charge flow portion 13 in the present embodiment, and a voltage of 0 V is input into the external terminal Tb3 of the first electric-charge flow portion 13 (the external terminal Tb3 is connected to the ground, for example).

Further, the external terminal Tb1 and the external terminal Tc6 of the second potential controlling portion 31 are brought into an opened state. Hereby, the chemical sensor 4 can inject electrons e− into the floating gate 123 via the first electric-charge flow portion 13. Note that, in a case where electric charges are injected into the floating gate 123 by the operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

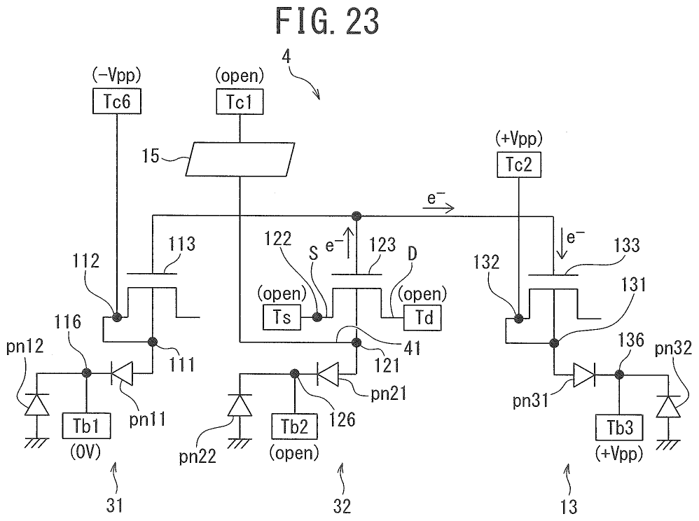

With reference to FIG. 23, the following describes an operation to adjust the threshold voltage to bring the transistor 32 provided in the chemical sensor 4 into the depression state by discharging electric charges from the floating gate 123.

As illustrated in FIG. 23, in the operation to adjust the threshold voltage to bring the transistor 32 into the depression state, in the chemical sensor 4, the input terminal Tc1, the external terminal Ts connected to the source S of the transistor 32, the external terminal Td connected to the drain D of the transistor 32, and the external terminal Tb2 are brought into an opened state. Further, in the case of the adjustment operation on the threshold voltage, in the chemical sensor 4, a pulse voltage of which the voltage value is inverted from 0 V to −Vpp is input into the external terminal Tc6. The pulse voltage is applied to the first floating portion 133 via the intermediate wiring lines 25a, 25b, the plugs 21b, 21c, the highly-concentrated impurity diffused region 112, the P-well region 111, the control floating portion 113, the first connecting portion 17a, the floating gate 123 of the transistor 32, and the second connecting portion 17b. Further, in the case of the adjustment operation on the threshold voltage, in the chemical sensor 4, a pulse voltage of which the voltage value is inverted from 0 V to +Vpp is input into the external terminal Tc2 and the external terminal Tb3 of the first electric-charge flow portion 13.

Hereby, FN tunneling occurs in the first insulating film 163, and as indicated by straight arrows in FIG. 23, electrons e− are discharged from the floating gate 123 to the P-well region 131 through the second connecting portion 17b, the first floating portion 133, and the first insulating film 163. Hereby, the threshold voltage of the transistor 32 decreases. The threshold voltage of the transistor 32 is checked by a method similar to the detection operation of the chemical sensor 4 as described with reference to FIG. 21. The discharge of the electrons e− from the floating gate 123 and the check of the threshold voltage of the transistor 32 are repeatedly executed until the transistor 32 reaches its desired threshold voltage. When the transistor 32 reaches the desired threshold voltage, the voltage application of the pulse voltage and so on is finished. Hereby, the adjustment operation on the threshold voltage of the transistor 32 is finished. Note that, in a case where electric charges are discharged from the floating gate 123 by the operation, the capacitance in the second potential controlling portion 31 should be larger than the capacitance in the first floating portion 133. This configuration has an effect to efficiently transmit a voltage input into the second potential controlling portion 31 to the first floating portion 133, in comparison with a configuration in which the capacitance in the second potential controlling portion 31 is smaller than the capacitance in the first floating portion 133. As a result, the efficiency of the adjustment of the threshold voltage can be improved.

Although not illustrated herein, in the chemical sensor 4, the threshold voltage of the transistor 32 can be adjusted by an operation similar to the second operation to adjust the threshold voltage to bring the transistor 12 in the chemical sensor 1 according to the first embodiment into the depression state. In this case, a voltage of 0 V is applied to the input terminal Tc1, the source S and the drain D of the transistor 32, and the external terminal Tb2. Further, the external terminal Tc6 and the external terminal Tb1 of the second potential controlling portion 31 are brought into an opened state. Further, a pulse voltage of which the voltage value is inverted from 0 V to +Vpp is input into the external terminal Tc2 of the first electric-charge flow portion 13 in the present embodiment, and a pulse voltage of which the voltage value is inverted from 0 V to +Vpp is input into the external terminal Tb3 of the first electric-charge flow portion 13. Hereby, the chemical sensor 4 can discharge electrons e− from the floating gate 123 via the first electric-charge flow portion 13. Note that, in a case where electric charges are discharged from the floating gate 123 by the operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

As described above, the chemical sensors according to the present embodiment can control the threshold voltage of the transistor and achieve improvement in the electric-charge retention characteristic.

### Fifth Embodiment

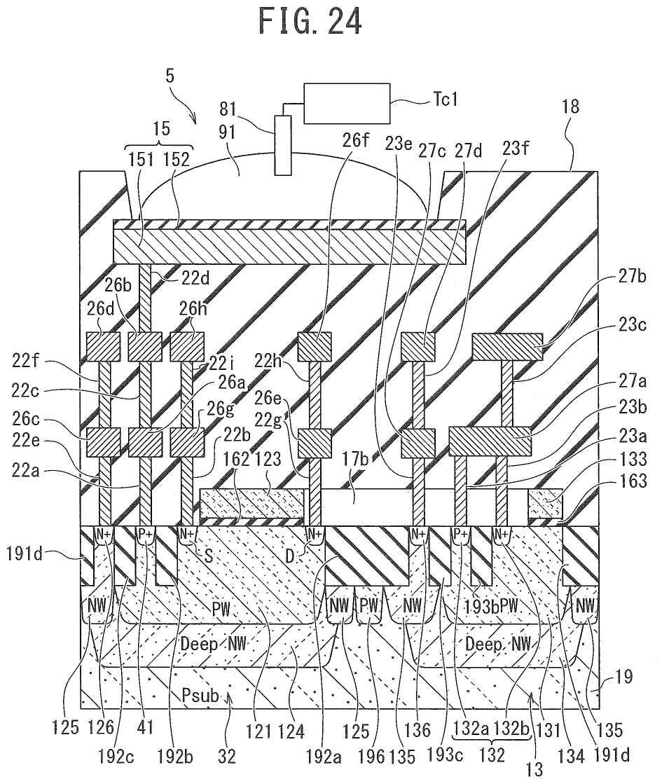

The following describes a chemical sensor according to a fifth embodiment of the present invention with reference to FIGS. 24 to 27. First described is a schematic configuration of a chemical sensor 5 according to the present embodiment with reference to FIG. 24. Upon describing the chemical sensor according to the present embodiment, the same reference sign as a constituent in the chemical sensor 4 according to the fourth embodiment is assigned to a constituent having a similar operation and function to those of the constituent in the chemical sensor 4 according to the fourth embodiment, and descriptions of the constituent are omitted.

<Configuration of Chemical Sensor>

As illustrated in FIG. 24, the chemical sensor 5 according to the present embodiment does not include the second potential controlling portion 31, differently from the chemical sensor 4 according to the fourth embodiment. The chemical sensor 5 has a feature in that the transistor 32 is operated by bringing the transistor 32 into the depression state, namely, a normally-on state of the threshold voltage. The transistor 32, the sensitive portion 15, and the first electric-charge flow portion 13 provided in the chemical sensor 5 have the same configurations as the transistor 32, the sensitive portion 15, and the first electric-charge flow portion 13 provided in the chemical sensor 4 according to the fourth embodiment.

<Operation of Chemical Sensor>

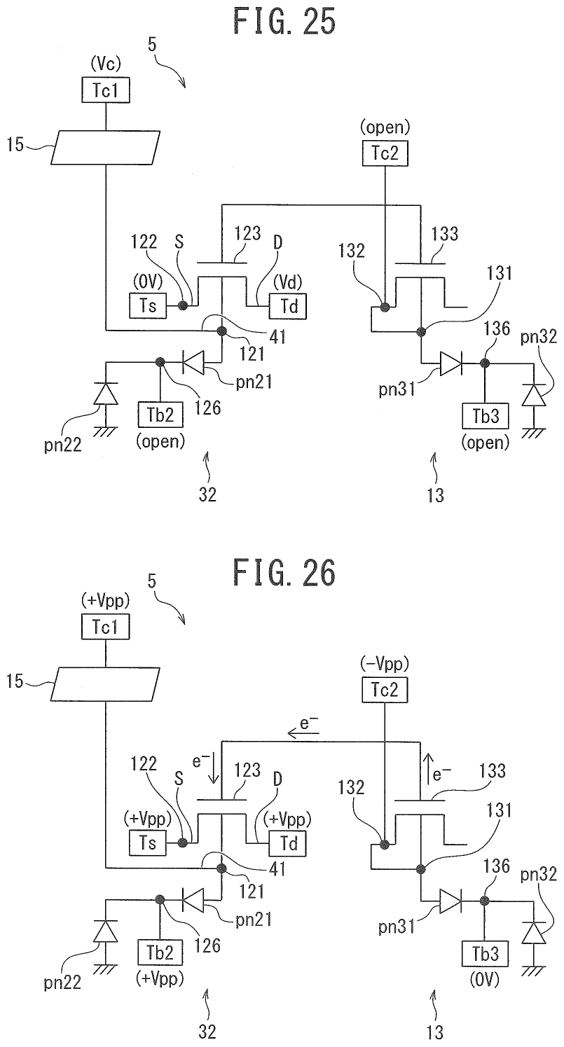

Next will be described the operation of the chemical sensor 5 according to the present embodiment by taking, as an example, a hydrogen-ion concentration sensor, with FIGS. 25 to 27 as well as FIG. 24.

(Equivalent Circuit of Chemical Sensor)

As illustrated in FIG. 25, the chemical sensor 5 according to the present embodiment can be expressed by an equivalent circuit similar to that of the chemical sensor 4 according to the fourth embodiment except that the chemical sensor 5 does not provide the second potential controlling portion.

(Detection Operation of Chemical Sensor)

As illustrated in FIG. 25, in the chemical sensor 5 according to the present embodiment, in a case where the hydrogen-ion concentration or the like of the test sample 91 is to be detected, a direct reference voltage having a voltage value of Vc is input into the input terminal Tc1 for the transistor 32 adjusted to the depression state. Further, in this case, in the chemical sensor 5, a voltage of zero volts (V) is input into the external terminal Ts connected to the source S of the transistor 32, and a voltage as a drain voltage Vd (e.g., 0.1 V) is input into the external terminal Td connected to the drain D of the transistor 32. Further, in this case, in the chemical sensor 5, the external terminals Tb2, Tb3, Tc2 are brought into an opened state.

Hereby, a back bias is applied to the transistor 32. Further, the floating gate 123 of the transistor 32 is maintained at a positive predetermined potential, for example. Accordingly, the transistor 32 operates in a state where a back bias is applied to the transistor 32. Sine the interface voltage on the sensitive membrane 152 changes in accordance with the hydrogen-ion concentration of the test sample 91, a voltage on which the hydrogen-ion concentration of the test sample 91 is reflected is applied to the P-well region 121 of the transistor 32. As a result, a drain current on which the hydrogen-ion concentration of the test sample 91 is reflected flows through the transistor 32 due to the substrate bias effect. Hereby, the chemical sensor 5 can detect the hydrogen-ion concentration of the test sample 91.

(Adjustment Operation of Threshold Voltage of Transistor in Chemical Sensor)

With reference to FIG. 26, the following describes an adjustment operation to increase the threshold voltage of the transistor 32 provided in the chemical sensor 5 by injecting electric charges into the floating gate 123.

As illustrated in FIG. 26, in the adjustment operation to increase the threshold voltage of the transistor 32, in the chemical sensor 5, a pulse voltage of which the voltage value is inverted from 0 V to +Vpp is input into the input terminal Tc1. The pulse voltage is applied to the first floating portion 133 via the intermediate wiring lines 26a, 26b, the plugs 22a, 22c, 22d, the first potential controlling portion 41, the P-well region 121, the floating gate 123, and the second connecting portion 17b. Further, in the case of the adjustment operation on the threshold voltage, in the chemical sensor 5, the same pulse voltage as the input terminal Tc1 is applied to the external terminal Ts connected to the source S of the transistor 32, the external terminal Td connected to the drain D of the transistor 32, and the external terminal Tb2. Further, in the case of the adjustment operation on the threshold voltage, in the chemical sensor 5, a pulse voltage of which the voltage value of which is inverted from 0 V to −Vpp is input into the external terminal Tc2 of the first electric-charge flow portion 13, and a voltage of 0 V is input into the external terminal Tb3 of the first electric-charge flow portion 13 (the external terminal Tb3 is connected to the ground, for example).

Hereby, FN tunneling occurs in the first insulating film 163, and as indicated by straight arrows in FIG. 26, electrons e− are injected into the floating gate 123 from the P-well region 131 of the first electric-charge flow portion 13 through the second connecting portion 17b, the first floating portion 133, and the first insulating film 163. Hereby, the threshold voltage of the transistor 32 increases. The threshold voltage of the transistor 32 is checked by a method similar to the detection operation of the chemical sensor 5 as described with reference to FIG. 25. The injection of the electrons e− into the floating gate 123 and the check of the threshold voltage of the transistor 32 are repeatedly executed until the transistor 32 reaches its desired threshold voltage. When the transistor 32 reaches the desired threshold voltage, the voltage application of the pulse voltage and so on is finished. Hereby, the adjustment operation on the threshold voltage of the transistor 32 is finished. Note that, in a case where electric charges are injected into the floating gate 123 by the operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

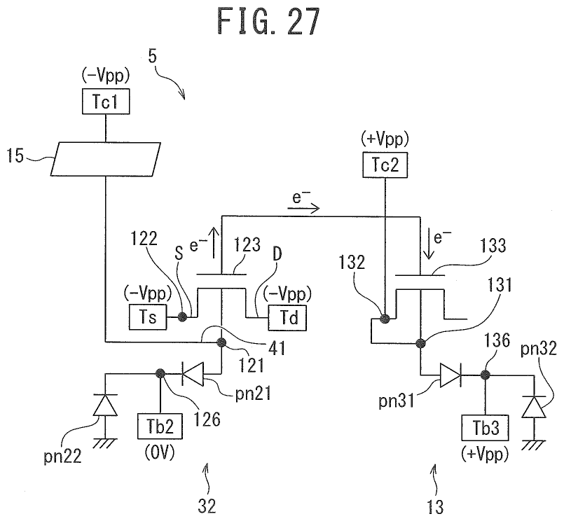

With reference to FIG. 27, the following describes an adjustment operation to decrease the threshold voltage of the transistor 32 provided in the chemical sensor 5 by discharging electric charges from the floating gate 123.

As illustrated in FIG. 27, in the adjustment operation to decrease the threshold voltage of the transistor 32, in the chemical sensor 5, a pulse voltage of which the voltage value is inverted from 0 V to −Vpp is input into the input terminal Tc1. The pulse voltage is applied to the first floating portion 133 via the intermediate wiring lines 26a, 26b, the plugs 22a, 22c, 22d, first potential controlling portion 41, the P-well region 121, the floating gate 123, and the second connecting portion 17b. Further, in the case of the adjustment operation on the threshold voltage, in the chemical sensor 5, the same pulse voltage as the input terminal Tc1 is applied to the external terminal Ts connected to the source S of the transistor 32 and the external terminal Td connected to the drain D. Further, in the case of the adjustment operation on the threshold voltage, in the chemical sensor 5, a voltage of 0 V is input into the external terminal Tb2 (the external terminal Tb2 is connected to the ground, for example). Further, in the case of the adjustment operation on the threshold voltage, in the chemical sensor 5, a pulse voltage of which the voltage value is inverted from 0 V to +Vpp is input into the external terminal Tc2 and the external terminal Tb3 of the first electric-charge flow portion 13.

Hereby, FN tunneling occurs in the first insulating film 163, and as indicated by straight arrows in FIG. 27, electrons e− are discharged from the floating gate 123 to the P-well region 131 through the second connecting portion 17b, the first floating portion 133, and the first insulating film 163. Hereby, the threshold voltage of the transistor 32 decreases. The threshold voltage of the transistor 32 is checked by a method similar to the detection operation of the chemical sensor 5 as described with reference to FIG. 25. The discharge of the electrons e− from the floating gate 123 and the check of the threshold voltage of the transistor 32 are repeatedly executed until the transistor 32 reaches its desired threshold voltage. When the transistor 32 reaches the desired threshold voltage, the voltage application of the pulse voltage and so on is finished. Hereby, the adjustment operation on the threshold voltage of the transistor 32 is finished. Note that, in a case where electric charges are discharged from the floating gate 123 by the operation, the capacitance in the floating gate 123 should be larger than the capacitance in the first floating portion 133. This configuration has an effect to efficiently transmit a voltage input into the floating gate 123 to the first floating portion 133, in comparison with a configuration in which the capacitance in the floating gate 123 is smaller than the capacitance in the first floating portion 133. As a result, the efficiency of the adjustment of the threshold voltage can be improved.

As described above, the chemical sensors according to the present embodiment can control the threshold voltage of the transistor and achieve improvement in the electric-charge retention characteristic.

### Sixth Embodiment

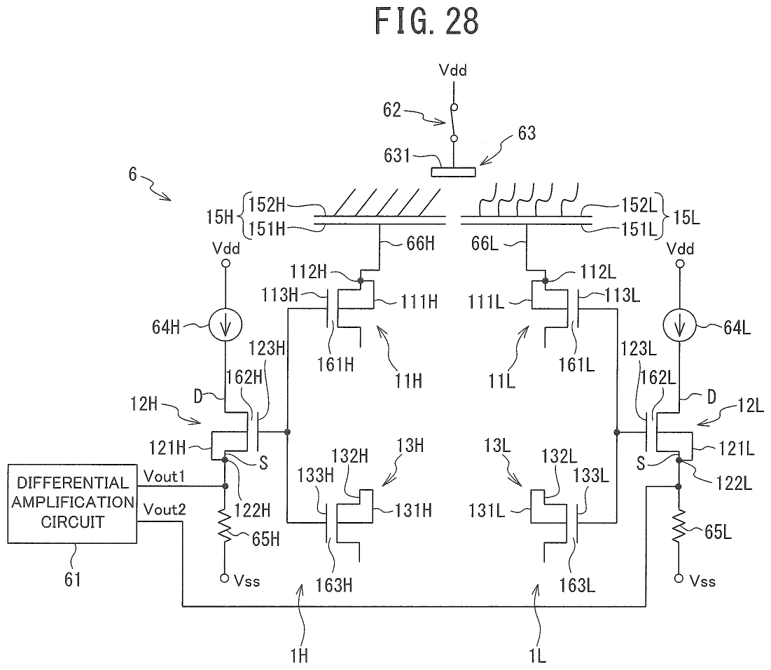

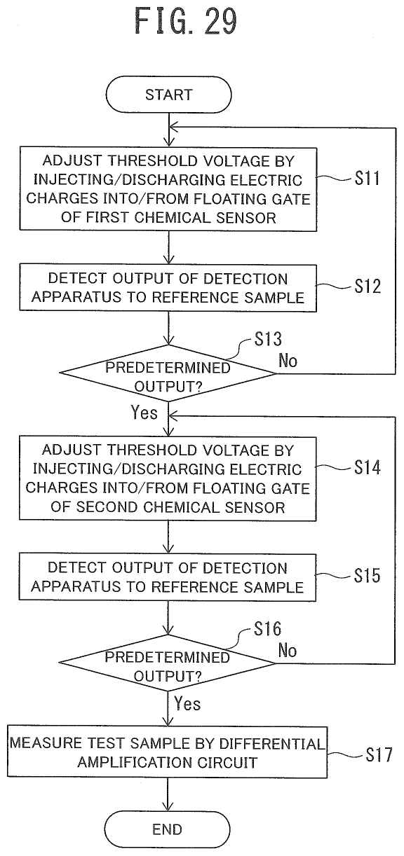

The following describes a detection apparatus according to a sixth embodiment of the present invention with reference to FIGS. 28 and 29. First, a schematic configuration of a detection apparatus 6 according to the present embodiment will be described with reference to FIG. 28.

<Configuration and Equivalent Circuit of Detecting Circuit>

As illustrated in FIG. 28, the detection apparatus 6 according to the present embodiment provides a first chemical sensor 1H, a second chemical sensor 1L (examples of two chemical sensors), an electrode structure 63 having a metal electrode as a pseudo-reference electrode 631, and a differential amplification circuit (an example of a detecting circuit) 61 configured to detect an output difference between the first chemical sensor 1H and the second chemical sensor 1L with respect to the pseudo-reference electrode 631. The pseudo-reference electrode 631 is made of platinum or gold, for example. A sensitive portion 15H provided in the first chemical sensor 1H (one example of one of the two chemical sensors 1) has a first sensibility. A sensitive portion 15L provided in the second chemical sensor 1L (one example of the other one of the two chemical sensors) has a second sensibility. The sensitive portion 15H provided in the first chemical sensor 1H, the sensitive portion 15L provided in the second chemical sensor 1L, and the pseudo-reference electrode 631 are provided to be immersible in a test sample (not illustrated) at the same time.

The first chemical sensor 1H and the second chemical sensor 1L have the same configuration. In the present embodiment, the first chemical sensor 1H and the second chemical sensor 1L have a configuration similar to that of the chemical sensor 1 according to the first embodiment, for example. However, the first chemical sensor 1H and the second chemical sensor 1L may have a structure similar to any of the structures of the chemical sensors according to the second embodiment to the fifth embodiment.

As illustrated in FIG. 28, the first chemical sensor 1H provides the sensitive portion 15H placed on a semiconductor substrate (not illustrated) and having a sensitive membrane 152H sensitive to a chemical substance. The sensitive portion 15H further has a conductive portion 151H connected to a first potential controlling portion 11H. The sensitive membrane 152H is formed on a first surface side of the conductive portion 151H. Here, the first surface side of the conductive portion 151H has the same meaning as the first surface side of the conductive portion 151 in the first embodiment. The first chemical sensor 1H provides a transistor 12H having a floating gate 123H and a gate insulating film 162H formed to make contact with the floating gate 123H. The first chemical sensor 1H provides the first potential controlling portion 11H configured to control the potential of the floating gate 123H in accordance with a voltage applied to the sensitive membrane 152H. Further, the first chemical sensor 1H provides a first electric-charge flow portion 13H through which electric charges are flowable to and from the floating gate 123H in accordance with an applied voltage. The first electric-charge flow portion 13H has part formed in the semiconductor substrate.

The first potential controlling portion 11H has a P-well region 111H (one example of the first impurity diffused region) formed in the semiconductor substrate and connected to the sensitive portion 15H via a wiring line 66H. Similarly to the wiring line in the first embodiment, the wiring line 66H has a structure in which a plurality of plugs and a plurality of intermediate wiring lines are put together, for example. The first potential controlling portion 11H has a control insulating film 161H placed on the first surface side of the semiconductor substrate and formed in the semiconductor substrate to make contact with the P-well region 111H. The first potential controlling portion 11H has a control floating portion 113H placed on the first surface side and placed at a position where the control floating portion 113H faces the P-well region 111H across the control insulating film 161H. The control floating portion 113H is conductive with the floating gate 123H. A capacitance of the sensitive membrane 152H is larger than a series combined capacitance of respective capacitances in the gate insulating film 162H and in the control insulating film 161H.

The first potential controlling portion 11H has a highly-concentrated impurity diffused region 112H containing impurities at a concentration higher than that in the P-well region 111H and formed in the P-well region 111H. The P-well region 111H has a structure similar to that of the P-well region 111 in the first embodiment, and the highly-concentrated impurity diffused region 112H has a structure similar to that of the highly-concentrated impurity diffused region 112 in the first embodiment. The P-well region 111H is electrically connected to the sensitive membrane 152H of the sensitive portion 15H via the highly-concentrated impurity diffused region 112H and the wiring line 66H.

Although not illustrated herein, the first chemical sensor 1H provides a deep N-well region having a structure similar to that of the deep N-well region 114 in the first embodiment, an N-well region having a structure similar to that of the N-well region 115 in the first embodiment, and an N+ region having a structure similar to that of the N+ region 116 in the first embodiment. On this account, in the first chemical sensor 1H, a PN junction (not illustrated) is formed between the P-well region 111H and the N+ region, similarly to the first embodiment. Further, in the first chemical sensor 1H, a PN junction (not illustrated) is formed between the N+ region and a P-type region of the semiconductor substrate where well regions are are not formed, similarly to the first embodiment. Further, an external terminal (not illustrated) is connected to the N+ region of the first chemical sensor 1H, similarly to the first embodiment.

As illustrated in FIG. 28, the first electric-charge flow portion 13H has a P-well region 131H formed in the semiconductor substrate and having the P-type, and a highly-concentrated impurity diffused region 132H formed in the P-well region 131H and containing impurities at a concentration higher than that in the P-well region 131H. A voltage is applied to the highly-concentrated impurity diffused region 132H. The first electric-charge flow portion 13H has a first insulating film 163H formed to make contact with the P-well region 131H, and a first floating portion 133H making contact with the first insulating film 163H and formed on the first surface side of the semiconductor substrate in an electrically floating state. The first floating portion 133H is connected to the floating gate 123H.

The P-well region 131H has a structure similar to that of the P-well region 131 in the first embodiment, and the highly-concentrated impurity diffused region 132H has a structure similar to that of the highly-concentrated impurity diffused region 132 in the first embodiment. The first insulating film 163H has a structure similar to that of the first insulating film 163 in the first embodiment, and the first floating portion 133H has a structure similar to that of the first floating portion 133 in the first embodiment.

Although not illustrated herein, the first chemical sensor 1H provides a deep N-well region having a structure similar to that of the deep N-well region 134 in the first embodiment, an N-well region having a structure similar to that of the N-well region 135 in the first embodiment, and an N+ region having a structure similar to that of the N+ region 136 in the first embodiment. On this account, in the first chemical sensor 1H, a PN junction (not illustrated) is formed between the P-well region 131H and the N+ region, similarly to the first embodiment. Further, in the first chemical sensor 1H, a PN junction (not illustrated) is formed between the N+ region and the P-type region of the semiconductor substrate where well regions are not formed, similarly to the first embodiment. Further, an external terminal (not illustrated) is connected to the N+ region of the first chemical sensor 1H, similarly to the first embodiment.

As illustrated in FIG. 28, the transistor 12H has a source S formed in the P-well region 121H on either one of the both sides of the floating gate 123H and having the N-type, and a drain D formed in the P-well region 121H on the other of the both sides of the floating gate 123H and having the N-type. The source S and the drain D of the transistor 12H are constituted by a highly-concentrated impurity diffused region having an impurity concentration higher than that of the P-well region 121H. The transistor 12H includes a P+ region 122H having the P-type and containing impurities at a concentration higher than that in the P-well region 121H. The P+ region 122H is formed in the P-well region 121H, and a voltage is applicable to the P+ region 122H.

Although not illustrated herein, the first chemical sensor 1H provides a deep N-well region having a structure similar to that of the deep N-well region 124 in the first embodiment, an N-well region having a structure similar to that of the N-well region 125 in the first embodiment, and an N+ region having a structure similar to that of the N+ region 126 in the first embodiment. On this account, in the first chemical sensor 1H, a PN junction (not illustrated) is formed between the P-well region 121H and the N+ region, similarly to the first embodiment. Further, in the first chemical sensor 1H, a PN junction (not illustrated) is formed between the N+ region and the P-type region of the semiconductor substrate where well regions are not formed, similarly to the first embodiment. Further, an external terminal (not illustrated) is connected to the N+ region of the first chemical sensor 1H, similarly to the first embodiment.

As illustrated in FIG. 28, the detection apparatus 6 provides a constant current source 64H connected to the drain D of the transistor 12H provided in the first chemical sensor 1H. The constant current source 64H has an input terminal to which a voltage Vdd is input, and an output terminal connected to the drain D of the transistor 12H. Hereby, the constant current source 64H can supply a constant current at a predetermined level to the transistor 12H.

The detection apparatus 6 provides a resistance element 65H connected to the source S of the transistor 12H. The resistance element 65H has a first terminal connected to the source S of the transistor 12H, and a second terminal connected to a region having a reference potential Vss. The first terminal of the resistance element 65H is connected to the differential amplification circuit 61. The transistor 12H adjusts a current supplied from the constant current source 64H in accordance with the potential of the floating gate 123H and outputs the current to the resistance element 65H. A detection result of the test sample in the sensitive portion 15H is reflected on the voltage of the floating gate 123H. Accordingly, a voltage drop in the resistance element 65H is a voltage on which the detection result of the test sample in the sensitive portion 15H is reflected. The first chemical sensor 1H outputs the voltage drop caused in the resistance element 65H to the differential amplification circuit 61 as an output voltage Vout1. Hereby, the first chemical sensor 1H can input the output voltage Vout1 on which the detection result of the test sample in the sensitive portion 15H is reflected to the differential amplification circuit 61.

As illustrated in FIG. 28, the second chemical sensor 1L provides the sensitive portion 15L placed on a semiconductor substrate (not shown) and having a sensitive membrane 152L sensitive to a chemical substance. The sensitive portion 15L further has a conductive portion 151L connected to a first potential controlling portion 11L. The sensitive membrane 152L is formed on a first surface side of the conductive portion 151L. Here, the first surface side of the conductive portion 151L has the same meaning as the first surface side of the conductive portion 151 in the first embodiment. The second chemical sensor 1L provides a transistor 12L including a floating gate 123L and a gate having film 162L formed to make contact with the floating gate 123L. The second chemical sensor 1L provides a first potential controlling portion 11L configured to control the potential of the floating gate 123L in accordance with a voltage applied to the sensitive membrane 152L. Further, the second chemical sensor 1L provides a first electric-charge flow portion 13L through which electric charges are flowable to and from the floating gate 123L in accordance with an applied voltage. The first electric-charge flow portion 13L has part formed in the semiconductor substrate.

The first potential controlling portion 11L has a P-well region 111L (one example of the first impurity diffused region) formed in the semiconductor substrate and connected to the sensitive portion 15L via a wiring line 66L. Similarly to the wiring line in the first embodiment, the wiring line 66L has a structure in which a plurality of plugs and a plurality of intermediate wiring lines are put together, for example. The first potential controlling portion 11L has a control insulating film 161L placed on the first surface side of the semiconductor substrate and formed in the semiconductor substrate to make contact with the P-well region 111L. The first potential controlling portion 11L has a control floating portion 113L placed on the first surface side and placed at a position where the control floating portion 113L faces the P-well region 111L across the control insulating film 161L. The control floating portion 113L is conductive with the floating gate 123L. A capacitance of the sensitive membrane 152L is larger than a series combined capacitance of respective capacitances in the gate insulating film 162L and in the control insulating film 161L.

The first potential controlling portion 11L has a highly-concentrated impurity diffused region 112L containing impurities at a concentration higher than that in the P-well region 111L and formed in the P-well region 111L. The P-well region 111L has a structure similar to that of the P-well region 111 in the first embodiment, and the highly-concentrated impurity diffused region 112L has a structure similar to that of the highly-concentrated impurity diffused region 112 in the first embodiment. The P-well region 111L is electrically connected to the sensitive membrane 152L of the sensitive portion 15L via the highly-concentrated impurity diffused region 112L and the wiring line 66L.

Although not illustrated herein, the second chemical sensor 1L provides a deep N-well region having a structure similar to that of the deep N-well region 114 in the first embodiment, an N-well region having a structure similar to that of the N-well region 115 in the first embodiment, and an N+ region having a structure similar to that of the N+ region 116 in the first embodiment. On this account, in the second chemical sensor 1L, a PN junction (not illustrated) is formed between the P-well region 111L and the N+ region, similarly to the first embodiment. Further, in the second chemical sensor 1L, a PN junction (not illustrated) is formed between the N+ region and a P-type region of the semiconductor substrate where well regions are not formed, similarly to the first embodiment. Further, an external terminal (not illustrated) is connected to the N+ region of the second chemical sensor 1L, similarly to the first embodiment.

As illustrated in FIG. 28, the first electric-charge flow portion 13L has a P-well region 131L formed in the semiconductor substrate and having the P-type, and a highly-concentrated impurity diffused region 132L formed in the P-well region 131L and containing impurities at a concentration higher than that in the P-well region 131L. A voltage is applied to the highly-concentrated impurity diffused region 132L. The first electric-charge flow portion 13L has a first insulating film 163L formed to make contact with the P-well region 131L, and a first floating portion 133L making contact with the first insulating film 163L and formed on the first surface side of the semiconductor substrate in an electrically floating state. The first floating portion 133L is connected to the floating gate 123L.

The P-well region 131L has a structure similar to that of the P-well region 131 in the first embodiment, and the highly-concentrated impurity diffused region 132L has a structure similar to that of the highly-concentrated impurity diffused region 132 in the first embodiment. The first insulating film 163L has a structure similar to that of the first insulating film 163 in the first embodiment, and the first floating portion 133L has a structure similar to that of the first floating portion 133 in the first embodiment.

Although not illustrated herein, the second chemical sensor 1L has a deep N-well region having a structure similar to that of the deep N-well region 134 in the first embodiment, an N-well region having a structure similar to that of the N-well region 135 in the first embodiment, and an N+ region having a structure similar to that of the N+ region 136 in the first embodiment. On this account, in the second chemical sensor 1L, a PN junction (not illustrated) is formed between the P-well region 131L and the N+ region, similarly to the first embodiment. Further, in the second chemical sensor 1L, a PN junction (not illustrated) is formed between the N+ region and the P-type region of the semiconductor substrate where well regions are not formed, similarly to the first embodiment. Further, an external terminal (not illustrated) is connected to the N+ region of the second chemical sensor 1L, similarly to the first embodiment.

As illustrated in FIG. 28, the transistor 12L has a source S formed in the P-well region 121L on one of the both sides of the floating gate 123L and having the N-type, and a drain D formed in the P-well region 121L on the other of the both sides of the floating gate 123L and having the N-type. The source S and the drain D of the transistor 12L are constituted by a highly-concentrated impurity diffused region having an impurity concentration higher than that of the P-well region 121L. The transistor 12L has a P+ region 122L having the P-type and containing impurities at a concentration higher than that in the P-well region 121L. The P+ region 122L is formed in the P-well region 121L, and a voltage is applicable to the P+ region 122L.

Although not illustrated herein, the second chemical sensor 1L provides a deep N-well region having a structure similar to that of the deep N-well region 124 in the first embodiment, an N-well region having a structure similar to that of the N-well region 125 in the first embodiment, and an N+ region having a structure similar to that of the N+ region 126 in the first embodiment. On this account, in the second chemical sensor 1L, a PN junction (not illustrated) is formed between the P-well region 121L and the N+ region, similarly to the first embodiment. Further, in the second chemical sensor 1L, a PN junction (not illustrated) is formed between the N+ region and the P-type region of the semiconductor substrate where well regions are not formed, similarly to the first embodiment. Further, an external terminal (not illustrated) is connected to the N+ region of the second chemical sensor 1L, similarly to the first embodiment.

As illustrated in FIG. 28, the detection apparatus 6 provides a constant current source 64L connected to the drain D of the transistor 12L provided in the second chemical sensor 1L. The constant current source 64L has an input terminal to which a voltage Vdd is input, and an output terminal connected to the drain D of the transistor 12L. Hereby, the constant current source 64L can supply a constant current at a predetermined level to the transistor 12L.

The detection apparatus 6 provides a resistance element 65L connected to the source S of the transistor 12L. The resistance element 65L has a first terminal connected to the source S of the transistor 12L, and a second terminal connected to a region having a reference potential Vss. The first terminal of the resistance element 65L is connected to the differential amplification circuit 61. The transistor 12L adjusts a current supplied from the constant current source 64L in accordance with the potential of the floating gate 123L and outputs the current to the resistance element 65L. A detection result of the test sample in the sensitive portion 15L is reflected on the voltage of the floating gate 123L. Accordingly, a voltage drop in the resistance element 65L is a voltage on which the detection result of the test sample in the sensitive portion 15L is reflected. The second chemical sensor 1L outputs the voltage drop caused in the resistance element 65L to the differential amplification circuit 61 as an output voltage Vout2. Hereby, the second chemical sensor 1L can input the output voltage Vout2 on which the detection result of the test sample in the sensitive portion 15L is reflected to the differential amplification circuit 61.

The detection apparatus 6 provides a switch 62 connected to the pseudo-reference electrode 631 of the electrode structure 63. The switch 62 has a first terminal into which the voltage Vdd is input, and a second terminal connected to the pseudo-reference electrode 631. The detection apparatus 6 is configured to appropriately change the switch 62 between an ON state and an OFF state such that the voltage Vdd is input or not input into the pseudo-reference electrode 631 via the switch 62.

In the meantime, generally, an Ag/AgCl electrode the potential of which is stable to liquid is used, though its size is large for the reference electrode. In this case, the reference electrode has a structure in which the Ag/AgCl electrode is immersed in an inner liquid KCl. A metal electrode made of gold, platinum, or the like can be deposited on a semiconductor substrate by a method such as vapor deposition, and therefore, the first chemical sensor 1H and the second chemical sensor 1L can be reduced in size. However, the potential of the metal electrode made of gold, platinum, or the like is unstable to liquid, and therefore, the metal electrode is unsuitable for a reference electrode of a chemical sensor. Although details are described later, the detection apparatus 6 according to the present embodiment calculates, for example, an ion concentration of a test sample by the differential amplification circuit 61 based on the difference between the output voltage Vout1 of the first chemical sensor 1H and the output voltage Vout2 of the second chemical sensor 1L. On this account, the detection apparatus 6 can be hardly affected by instability of the potential of the pseudo-reference electrode 631 to liquid. Accordingly, the detection apparatus 6 can use the pseudo-reference electrode 631 made of metal such as gold or platinum. Hereby, the detection apparatus 6 can be reduced in size and does not have a problem of elution in the inner liquid, the problem being seen in the Ag/AgCl electrode.

The sensitive portion 15H is formed to have a sensitivity higher than that of the sensitive portion 15L. In the detection apparatus 6, for example, the sensitive membrane 152H and the sensitive membrane 152L are formed by use of different materials or by changing the composition ratio of a material, and therefore, the sensitive portion 15H and the sensitive portion 15L have different sensitivities. In the present embodiment, the sensitive membrane 152H provided in the sensitive portion 15H is made of Ta₂O₅, for example, and the sensitive membrane 152L provided in the sensitive portion 15L is made of Al₂O₃, for example.

The sensitive portion 15H provided in the first chemical sensor 1H, the sensitive portion 15L provided in the second chemical sensor 1L, and the pseudo-reference electrode 631 are provided to be immersible in a test sample (not shown) at the same time. Because of this, the same voltage is applied to the sensitive portion 15H and the sensitive portion 15L via the test sample from the pseudo-reference electrode 631. Since the sensitive portion 15H is formed to have a sensitivity higher than that of the sensitive portion 15L, even if the same voltage is applied to the sensitive portion 15H and the sensitive portion 15L, a voltage higher than a voltage to the first potential controlling portion 11L is applied to the first potential controlling portion 11H. Hereby, a voltage higher than a voltage to the floating gate 123L of the transistor 12L is applied to the floating gate 123H of the transistor 12H. As a result, the output voltage Vout1 and the output voltage Vout2 having a voltage level lower than that of the output voltage Vout1 are input into the differential amplification circuit 61.

The output voltage Vout1 includes variations by temperature characteristics in various parts such as the sensitive portion 15H and the transistor 12H of the first chemical sensor 1H, noise such as drift, and so on, as well as information on a measurement target of the test sample. Similarly, the output voltage Vout2 includes variations by temperature characteristics in various parts such as the sensitive portion 15L and the transistor 12L of the second chemical sensor 1L, noise such as drift, and so on, as well as the information on the measurement target of the test sample. The differential amplification circuit 61 calculates the measurement target (e.g., the ion concentration) of the test sample by subtracting the output voltage Vout2 from the output voltage Vout1. On this account, respective noises included in the output voltage Vout1 and the output voltage Vout2 are offset or decreased. Hereby, the detection apparatus 6 can improve the measurement accuracy of the test sample.

<Operation of Detection Apparatus>

Next will be described the operation of the detection apparatus 6 according to the present embodiment by taking, as an example, a case where the first chemical sensor 1H and the second chemical sensor 1L are hydrogen-ion concentration sensors, with reference to FIG. 29 as well as FIG. 28. FIG. 29 is a flowchart illustrating an example of the operation of the detection apparatus 6. Here, a reference electrode is used in each of steps S11 to S16 (details will be described later) of the operation of the detection apparatus 6, and adjustment of the threshold voltage to a standard solution is performed highly precisely. As an example, an Ag/AgCl electrode is used as the reference electrode. Further, in step S17 (details will be described later) of the operation of the detection apparatus 6, a pseudo-reference electrode is used.

(Step S11)

When the operation of the detection apparatus 6 is started, the detection apparatus 6 adjusts the threshold voltage of the transistor 12H in step S11 by injecting electric charges into the floating gate 123H of the first chemical sensor 1H or discharging electric charges from the floating gate 123H, and the detection apparatus 6 shifts to the process of step S12. The adjustment operation on the threshold voltage of the transistor 12H provided in the first chemical sensor 1H is similar to the adjustment operation on the threshold voltage of the transistor 12 provided in the chemical sensor 1 according to the first embodiment, and therefore, descriptions of the adjustment operation on the threshold voltage of the transistor 12H are omitted.

(Step S12)

In step S12, the detection apparatus 6 detects an output voltage Vout1 to a reference sample placed on the sensitive portion 15H and shifts to the process of step S13. The detection operation to detect the output voltage Vout1 to the reference sample placed on the sensitive portion 15H is similar to the detection operation to detect an output in the chemical sensor 1 according to the first embodiment, and therefore, descriptions of the detection operation to detect the output voltage Vout1 are omitted.

(Step S13)

In step S13, the detection apparatus 6 determines whether the value of the output voltage Vout1 is a desired output value or not. When the value of the output voltage Vout1 is the desired output value (Yes), the detection apparatus 6 shifts to the process of step S14. In the meantime, when the value of the output voltage Vout1 is not the desired output value (No), the detection apparatus 6 returns to the process of step S11.

(Step S14)

In step S14, the detection apparatus 6 adjusts the threshold voltage of the transistor 12L by injecting electric charges into the floating gate 123L of the second chemical sensor 1L or discharging electric charges from the floating gate 123L, and the detection apparatus 6 shifts to the process of step S15. The adjustment operation on the threshold voltage of the transistor 12L provided in the second chemical sensor 1L is similar to the adjustment operation on the threshold voltage of the transistor 12 provided in the chemical sensor 1 according to the first embodiment, and therefore, descriptions of the adjustment operation on the threshold voltage of the transistor 12L are omitted. In the present embodiment, the threshold voltage of the transistor 12H provided in the first chemical sensor 1H and the threshold voltage of the transistor 12L provided in the second chemical sensor 1L are adjusted to the same value. Hereby, the detection apparatus 6 can prevent an offset voltage from occurring in a difference voltage between the output voltage Vout1 of the first chemical sensor 1H and the output voltage Vout2 of the second chemical sensor 1L. The offset voltage is caused due to a difference between the threshold voltages of the transistor 12H and the threshold voltages of the transistor 12L.

(Step S15)

In step S15, the detection apparatus 6 detects an output voltage Vout2 to a reference sample placed on the sensitive portion 15L and shifts to the process of step S16. The detection operation to detect the output voltage Vout1 to the reference sample placed on the sensitive portion 15L is similar to the detection operation to detect an output in the chemical sensor 1 according to the first embodiment, and therefore, descriptions of the detection operation to detect the output voltage Vout2 are omitted.

(Step S16)

In step S16, the detection apparatus 6 determines whether the value of the output voltage Vout2 is a desired output value or not. When the value of the output voltage Vout2 is the desired output value (Yes), the detection apparatus 6 shifts to the process of step S17. In the meantime, when the value of the output voltage Vout2 is not the desired output value (No), the detection apparatus 6 returns to the process of step S14.

(Step S17)

In step S17, the sensitive portion 15H, the sensitive portion 15L, and the pseudo-reference electrode 631 are immersed in a test sample, and the detection apparatus 6 measures the hydrogen-ion concentration of the test sample by the differential amplification circuit 61 and finishes the operation. At the time when the hydrogen-ion concentration of the test sample is to be measured, the switch 62 is brought into an ON state, and a voltage Vdd is applied to the test sample via the switch 62 and the pseudo-reference electrode 631. Further, at the time when the hydrogen-ion concentration of the test sample is to be measured, a constant current at a predetermined level is input into the drain D of the transistor 12H from the constant current source 64H, and a constant current at a predetermined level (the same level as the current output from the constant current source 64H) is input into the drain D of the transistor 12L from the constant current source 64L.

As described above, with the detection apparatus according to the present embodiment, it is possible to control the threshold voltages of respective transistors provided in the first chemical sensor and the second chemical sensor, and it is possible to achieve improvement in the electric-charge retention characteristic. Hereby, effects similar to those of the chemical sensors according to the first embodiment to the fifth embodiment can be achieved. Further, the detection apparatus according to the present embodiment can use a pseudo-reference electrode made of metal such as gold or platinum, and thus, it is possible to achieve a reduction in size.

The present invention is not limited to the above embodiments, and various modifications can be made.

In the chemical sensors according to the first embodiment to the fifth embodiment and their modifications and the first chemical sensor and the second chemical sensor provided in the detection apparatus according to the sixth embodiment, the sensitive portion and the floating gate are placed on the first surface side, that is, the same side of the semiconductor substrate 19. However, the present invention is not limited to this. The chemical sensors may be configured such that the sensitive portion is placed on a second surface of the semiconductor substrate, that is, a back-surface side that is a side opposite to the first surface of the semiconductor substrate. That is, the sensitive portion and the floating gate may be placed across the semiconductor substrate. In this case, the sensitive portion is electrically connected to the first potential controlling portion from the second surface side (the back-surface side) of the semiconductor substrate. The chemical sensors can have various connection modes to connect the sensitive portion to the first potential controlling portion. For example, the sensitive portion placed on the second surface side (the back-surface side) of the semiconductor substrate 19 may be electrically connected to a predetermined well region formed in the semiconductor substrate via a plug embedded in a hole formed in the semiconductor substrate or an intermediate wiring line connected to the plug. Further, for example, the sensitive portion placed on the second surface side (the back-surface side) of the semiconductor substrate 19 may be placed in a hole formed in the semiconductor substrate and directly electrically connected to a predetermined well region exposed in the hole.

The chemical sensors 4, 5 according to the fourth embodiment and the fifth embodiment provide the first electric-charge flow portion 13 as an electric-charge flow portion. However, the present invention is not limited to this. For example, similarly to the chemical sensor 3 according to the third embodiment, the chemical sensors 4, 5 may provide the second electric-charge flow portion 14. The chemical sensors 4, 5 having this configuration can achieve the same effect as the chemical sensor 3.

The conductivity types of various regions such as the well regions and the semiconductor substrates in the chemical sensors according to the first embodiment to the fifth embodiment and their modifications and in the first chemical sensor and the second chemical sensor provided in the detection apparatus according to the sixth embodiment are just examples. The P-type and the N-type may be reversed, or different combinations of the P-type and the N-type can be employed appropriately.

The technical scope of the present invention is not limited to the exemplary embodiments illustrated and described herein and covers all embodiments that provide effects equivalent to those intended by the present invention. Further, the technical scope of the present invention is not limited to combinations of features of the invention defined by Claims but can be defined by any desired combination of specific features among the features disclosed herein.

### REFERENCE SIGNS LIST

1, 1a, 2, 2a, 3, 3a, 3b, 3c, 3d, 3e, 3f, 3g, 4, 5 . . . chemical sensor
1H . . . first chemical sensor
1L . . . second chemical sensor
6 . . . detection apparatus
11, 11H, 11L, 41 . . . first potential controlling portion
12, 12H, 12L, 32 . . . transistor
13, 13H, 13L . . . first electric-charge flow portion
14 . . . second electric-charge flow portion
15, 15H, 15L . . . sensitive portion
16, 162, 162H, 162L . . . gate insulating film
17a . . . first connecting portion
17b . . . second connecting portion
17c . . . third connecting portion
18 . . . interlayer insulating film
19 . . . semiconductor substrate
21a, 21b, 21c, 21d, 21e, 21f, 22a, 22b, 22c, 22d, 22e, 22f, 22g, 22h, 22i, 23a, 23b, 23c, 23e, 23f, 24a, 24b, 24c, 24e, 24f . . . plug
25a, 25b, 25c, 25d, 26a, 26b, 26c, 26d, 26e, 26f, 26g, 26h, 27a, 27b, 27c, 27d, 28a, 28b, 28c, 28d . . . intermediate wiring line
31 . . . second potential controlling portion
61 . . . differential amplification circuit
62 . . . switch
63 . . . electrode structure
64H, 64L . . . constant current source
65H, 65L . . . resistance element
66H, 66L . . . wiring line
81 . . . reference electrode
91 . . . test sample
111, 111H, 111L, 121, 121a, 121H, 121L, 131, 141, 195, 196, 197 . . . P-well region
112, 112H, 112L, 132, 132H, 132L, 142 . . . highly-concentrated impurity diffused region
112a, 122, 122H, 122L, 132a, 142a . . . P+ region
112b, 116, 126, 132b, 136, 142b, 146 . . . N+ region
113, 113H, 113L . . . control floating portion
114, 124, 134, 144, 190a, 190b, 199a, 199b, 199c . . . deep N-well region
115, 125, 131a, 135, 141a, 145, 198a, 198b, 198c . . . N-well region
123, 123H, 123L . . . floating gate
133, 133H, 133L . . . first floating portion
143 . . . second floating portion
151 . . . conductive portion
152 . . . sensitive membrane
161, 161H, 161L . . . control insulating film
163, 163H, 163L . . . first insulating film
164 . . . second insulating film
191a, 191b, 191c, 191d, 192a, 192b, 192c, 193a, 193b, 193c, 194b, 194c . . . element isolation layer
pn11, pn12, pn21, pn22, pn31, pn32, pn41, pn42 . . . PN junction
D . . . drain
S . . . source
Tb1, Tb2, Tb3, Tb4, Tc6, Tc2, Tc3, Td, Ts . . . external terminal
Tc . . . input terminal

What is claimed is:

1. A chemical sensor comprising:
a sensitive portion placed on a semiconductor substrate and having a sensitive membrane sensitive to a chemical substance;
a transistor having a floating gate and a gate insulating film formed to make contact with the floating gate; and
a first potential controlling portion configured to control a potential of the floating gate in accordance with a voltage applied to the sensitive membrane, wherein:
the first potential controlling portion has
a first impurity diffused region formed in the semiconductor substrate and connected to the sensitive portion via a wiring line,
a control insulating film placed on a first surface side of the semiconductor substrate and formed in the semiconductor substrate to make contact with the first impurity diffused region, and
a control floating portion placed on the first surface side and placed at a position where the control floating portion faces the first impurity diffused region across the control insulating film, the control floating portion being conductive with the floating gate; and
a capacitance of the sensitive membrane is larger than a series combined capacitance of respective capacitances of the gate insulating film and the control insulating film.

2. The chemical sensor according to claim 1, comprising a first electric-charge flow portion through which electric charges are flowable to and from the floating gate in accordance with an applied voltage, the first electric-charge flow portion having at least part formed in the semiconductor substrate.

3. The chemical sensor according to claim 2, wherein the first electric-charge flow portion has:
a second impurity diffused region formed in the semiconductor substrate and having a first conductivity type;
a highly-concentrated impurity diffused region formed in the second impurity diffused region and containing impurities at a concentration higher than a concentration in the second impurity diffused region and to which a voltage is applied;
a first insulating film formed to make contact with the second impurity diffused region; and
a first floating portion making contact with the first insulating film and formed on the first surface side in an electrically floating state, the first floating portion being connected to the floating gate.

4. The chemical sensor according to claim 3, wherein the first insulating film at least partially has a region with a film thickness of not less than 6 nm but less than 15 nm.

5. The chemical sensor according to claim 2, comprising a second electric-charge flow portion through which electric charges are flowable to and from the floating gate in accordance with an applied voltage, the second electric-charge flow portion having at least part formed in the semiconductor substrate.

6. The chemical sensor according to claim 5, wherein the second electric-charge flow portion includes:
a third impurity diffused region formed in the semiconductor substrate;
a highly-concentrated impurity diffused region to which a voltage is applied, the highly-concentrated impurity diffused region being formed in the third impurity diffused region and containing impurities at a concentration higher than a concentration in the third impurity diffused region;
a second insulating film formed to make contact with the third impurity diffused region; and
a second floating portion making contact with the second insulating film and formed on the first surface side in an electrically floating state, the second floating portion being connected to the floating gate.

7. The chemical sensor according to claim 6, wherein the third impurity diffused region has a first conductivity type or a second conductivity type different from the first conductivity type.

8. The chemical sensor according to claim 6, wherein the second insulating film at least partially has a region with a film thickness of not less than 6 nm but less than 15 nm.

9. The chemical sensor according to claim 1, wherein:
the transistor has
a fourth impurity diffused region formed in the semiconductor substrate and having a first conductivity type,
a gate insulating film placed to be sandwiched between the fourth impurity diffused region and the floating gate and formed to make contact with the fourth impurity diffused region and the floating gate,
a source formed in the fourth impurity diffused region on one of both sides of the floating gate, the source having a second conductivity type, and
a drain formed in the fourth impurity diffused region on the other of the both sides of the floating gate, the drain having the second conductivity type; and
the gate insulating film at least partially has a region with a film thickness of not less than 6 nm but less than 15 nm.

10. The chemical sensor according to claim 2, wherein the transistor has:
a fourth impurity diffused region formed in the semiconductor substrate and having a first conductivity type;
a gate insulating film placed to be sandwiched between the fourth impurity diffused region and the floating gate and formed to make contact with the fourth impurity diffused region and the floating gate;
a source formed in the fourth impurity diffused region on one of both sides of the floating gate, the source having a second conductivity type; and
a drain formed in the fourth impurity diffused region on the other of the both sides of the floating gate, the drain having the second conductivity type.

11. The chemical sensor according to claim 9, wherein the gate insulating film is a thermal oxide film.

12. The chemical sensor according to claim 9, wherein the transistor includes a highly-concentrated impurity diffused region to which a voltage is applicable, the highly-concentrated impurity diffused region having the first conductivity type and containing impurities at a concentration higher than a concentration in the fourth impurity diffused region, the highly-concentrated impurity diffused region being formed in the fourth impurity diffused region.

13. The chemical sensor according to claim 1, wherein a ratio of a capacitance in the control floating portion to a sum of a capacitance in the floating gate and the capacitance in the control floating portion is equal to 0.7 or more.

14. The chemical sensor according to claim 1, wherein:
the sensitive portion further has a conductive portion connected to the first potential controlling portion; and
the sensitive membrane is formed on a first surface side of the conductive portion.

15. The chemical sensor according to claim 14, wherein a ratio of the capacitance on the sensitive membrane to a sum of the capacitance on the sensitive membrane and a series combined capacitance on a capacitance of the floating gate and a capacitance on the control floating portion is equal to 0.7 or more.

16. The chemical sensor according to claim 1, comprising a fifth impurity diffused region formed in the semiconductor substrate to surround the first impurity diffused region at a position deeper than the first impurity diffused region and having a second conductivity type.

17. The chemical sensor according to claim 10, wherein the first potential controlling portion has the first conductivity type and contains impurities at a concentration higher than a concentration in the fourth impurity diffused region, the first potential controlling portion being formed in the fourth impurity diffused region.

18. The chemical sensor according to claim 1, comprising a second potential controlling portion having at least part formed in the semiconductor substrate and configured to control a potential of the floating gate.

19. The chemical sensor according to claim 18, wherein the second potential controlling portion has
a sixth impurity diffused region formed in the semiconductor substrate and having a first conductivity type,
a highly-concentrated impurity diffused region containing impurities at a concentration higher than a concentration in the sixth impurity diffused region and formed in the sixth impurity diffused region, and
a control floating portion insulated from the sixth impurity diffused region and formed on the first surface side in an electrically floating state, the control floating portion being connected to the floating gate.

20. A detection apparatus comprising:
two chemical sensors according to claim 1;
an electrode structure having a metal electrode as a pseudo-reference electrode; and
a detecting circuit configured to detect an output difference between the two chemical sensors with respect to the pseudo-reference electrode, wherein:
the sensitive portion provided in one of the two chemical sensors has a first sensibility;
the sensitive portion provided in the other of the two chemical sensors has a second sensibility; and
the sensitive portion provided in the one of the two chemical sensors, the sensitive portion provided in the other of the two chemical sensors, and the pseudo-reference electrode are provided to be immersible in a test sample at the same time.
